(19) United States
(12) Patent Application Publication
(10) Pub. No.: US 2026/0047202 A1
(43) Pub. Date: Feb. 12, 2026

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Fei Fang, Beijing (CN); Zhongman Zhao, Beijing (CN); Ling Shi, Beijing (CN); Haoyu Li, Beijing (CN); Yu Wu, Beijing (CN); Yuxiao Li, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/689,421

(22) PCT Filed: May 25, 2023
(86) PCT No.: PCT/CN2023/096283

§ 371 Date: Mar. 5, 2024

(51) Int. Cl. H10D 86/40; H10D 86/60

(52) U.S. Cl. CPC H10D 86/441; H10D 86/60

(57) ABSTRACT

An array substrate includes a plurality of signal lines. A respective signal line includes a plurality of first signal line portions, a plurality of second signal line portions, and a plurality of third signal line portions. The plurality of first signal line portions and the plurality of second signal line portions are in two different layers. The plurality of first signal line portions and the plurality of third signal line portions are in two different layers. Two individual first signal line portions, an individual second signal line portion, and an individual third signal line portion form a loop substantially surrounding a region having transistors and capacitors of a pixel driving circuit of a subpixel. The two individual first signal line portions are connected by the individual second signal line portion, and connected by the individual third signal line portion.

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate signal line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a plurality of signal lines; wherein a respective signal line of the plurality of signal lines comprises a plurality of first signal line portions, a plurality of second signal line portions, and a plurality of third signal line portions; the plurality of first signal line portions and the plurality of second signal line portions are in two different layers; the plurality of first signal line portions and the plurality of third signal line portions are in two different layers; a respective second signal line portion of the plurality of second signal line portions is connected to two adjacent first signal line portions of the plurality of first signal line portions, respectively; a respective third signal line portion of the plurality of third signal line portions is connected to two adjacent first signal line portions of the plurality of first signal line portions, respectively; two individual first signal line portions of the plurality of first signal line portions, an individual second signal line portion of the plurality of second signal line portions, and an individual third signal line portion of the plurality of third signal line portions form a loop substantially surrounding a region having transistors and capacitors of a pixel driving circuit of a subpixel; and the two individual first signal line portions are connected by the individual second signal line portion, and connected by the individual third signal line portion.

Optionally, the array substrate comprises a plurality of loops sequentially arranged in a row; wherein the plurality of loops substantially surround regions of pixel driving circuits of subpixels of a same color, respectively; and a respective loop of the plurality of loops substantially surrounds a region of a pixel driving circuit of a subpixel of the same color.

Optionally, the array substrate comprising a plurality of loops sequentially arranged in a row; wherein the plurality of loops substantially surround regions having anodes of subpixels of a same color, respectively; and a respective loop of the plurality of loops substantially surrounds a region having an anode of a subpixel of the same color.

Optionally, subpixels are arranged in rows and columns; in an m-th row of subpixels, the array substrate comprises a row of first subpixels of a first color; in a (m+1)-th row of subpixels, the array substrate comprises a row of third subpixels of a third color; in a (m+2)-th row of subpixels, the array substrate comprises a row of second subpixels of a second color; in an n-th column of subpixels, the array substrate comprises a column of third subpixels of the third color; in a (n−1)-th column of subpixels, the array substrate comprises a column of first subpixels of the first color and second subpixels of the second color alternately arranged; in a (n+1)-th column of subpixels, the array substrate comprises a column of first subpixels of the first color and second subpixels of the second color alternately arranged; a first signal line portion of the plurality of first signal line portions is connected to one or more transistors in a pixel driving circuit in a third subpixel in the n-th column of subpixels and the (m+1)-th row of subpixels, is connected to one or more transistors in a pixel driving circuit in a first subpixel in the (n−1)-th column of subpixels and the m-th row of subpixels, and is connected to one or more transistors in a pixel driving circuit in a second subpixel in the (n+1)-th column of subpixels and the (m+2)-th row of subpixels.

Optionally, a second signal line portion of the plurality of second signal line portions connects the first signal line portion with a first adjacent first signal line portion, the first adjacent first signal line portion is connected to one or more transistors in a pixel driving circuit in a second subpixel in the (n−1)-th column of subpixels and the (m+2)-th row of subpixels.

Optionally, a third signal line portion of the plurality of third signal line portions connects the first signal line portion with a second adjacent first signal line portion, the second adjacent first signal line portion is connected to one or more transistors in a pixel driving circuit in a first subpixel in the (n+1)-th column of subpixels and the m-th row of subpixels.

Optionally, the array substrate further comprises a plurality of light transmissive regions; wherein, in the n-th column of subpixels, a respective light transmissive region of the plurality of light transmissive regions spaces apart two adjacent third subpixels.

Optionally, the plurality of signal lines comprise a plurality of initialization signal lines; the plurality of first signal line portions comprise a plurality of first initialization signal line portions; the plurality of second signal line portions comprise a plurality of second initialization signal line portions; and the plurality of third signal line portions comprise a plurality of third initialization signal line portions.

Optionally, the plurality of signal lines comprise a plurality of gate signal lines; the plurality of first signal line portions comprise a plurality of first gate signal line portions; the plurality of second signal line portions comprise a plurality of second gate signal line portions; and the plurality of third signal line portions comprise a plurality of third gate signal line portions.

Optionally, the plurality of signal lines comprise a plurality of reset control signal lines; the plurality of first signal line portions comprise a plurality of first reset control signal line portions; the plurality of second signal line portions comprise a plurality of second reset control signal line portions; and the plurality of third signal line portions comprise a plurality of third reset control signal line portions.

Optionally, the plurality of signal lines comprise a plurality of light emitting control signal lines; the plurality of first signal line portions comprise a plurality of first light emitting control signal line portions; the plurality of second signal line portions comprise a plurality of second light emitting control signal line portions; and the plurality of third signal line portions comprise a plurality of third light emitting control signal line portions.

Optionally, the array substrate further comprises a plurality of light transmissive regions; wherein the array substrate comprises a first conductive layer, a second conductive layer, a first signal line layer, a third signal line layer, and an anode layer; signal lines and electrodes of the first conductive layer, the second conductive layer, the first signal line layer, the third signal line layer, and the anode layer are absent in the plurality of light transmissive regions.

Optionally, the array substrate further comprises a second signal line layer; wherein signal lines in the second signal line layer comprise a substantially transparent conductive material; and the signal lines of the second signal line layer are present in the plurality of light transmissive regions.

Optionally, the plurality of second signal line portions and the plurality of third signal line portions are in the second signal line layer; and the plurality of first signal line portions are in the first conductive layer or in the second conductive layer.

Optionally, the array substrate further comprises a plurality of voltage supply lines and a plurality of voltage connecting bridges in two different layers; the plurality of voltage connecting bridges are arranged in an array of rows and columns; two adjacent voltage connecting bridges of the plurality of voltage connecting bridges in a same pixel row are connected to a same voltage supply line of the plurality of voltage supply lines; and voltage connecting bridges of the plurality of voltage connecting bridges in a same pixel column are connected to same adjacent voltage supply lines of the plurality of voltage supply lines.

Optionally, the plurality of voltage supply lines comprise a first adjacent voltage supply line, a second adjacent voltage supply line, and a third adjacent voltage supply line; the first adjacent voltage supply line is configured to provide a voltage supply signal to a first pixel driving circuit in a respective first subpixel, the second adjacent voltage supply line is configured to provide a voltage supply signal to a second pixel driving circuit in a respective second subpixel, and the third adjacent voltage supply line is configured to provide a voltage supply signal to a third pixel driving circuit in a respective third subpixel; and a respective voltage connecting bridge of the plurality of voltage connecting bridges is connected to the first adjacent voltage supply line, the second adjacent voltage supply line, and the third adjacent voltage supply line, respectively.

Optionally, each of the first adjacent voltage supply line, the second adjacent voltage supply line, and the third adjacent voltage supply line comprises a plurality of first voltage supply line portions and a plurality of second voltage supply line portions alternately arranged; a respective voltage connecting bridge of the plurality of voltage connecting bridges is connected to a first adjacent voltage supply line portion and a second adjacent voltage supply line portion of the first adjacent voltage supply line, respectively, is connected to a first adjacent voltage supply line portion and a second adjacent voltage supply line portion of the second adjacent voltage supply line, respectively, and is connected to a first adjacent voltage supply line portion and a second adjacent voltage supply line portion of the third adjacent voltage supply line, respectively.

Optionally, the plurality of voltage supply lines comprise a first adjacent voltage supply line and a second adjacent voltage supply line; a respective voltage supply line of the plurality of voltage supply lines is connected to two adjacent columns of voltage connecting bridges of the plurality of voltage connecting bridges; and a respective voltage connecting bridge of the plurality of voltage connecting bridges is connected to the first adjacent voltage supply line and is connected to the second adjacent voltage supply line.

Optionally, a respective voltage connecting bridge of the plurality of voltage connecting bridges comprises second capacitor electrodes of multiple pixel driving circuits.

In another aspect, the present disclosure provides a display apparatus, comprising the array substrate described herein, and one or more integrated circuits connected to the array substrate.

In another aspect, the present disclosure provides an array substrate, comprising a plurality of voltage supply lines and a plurality of voltage connecting bridges in two different layers; wherein the plurality of voltage connecting bridges are arranged in an array of rows and columns; two adjacent voltage connecting bridges of the plurality of voltage connecting bridges in a same pixel row are connected to a same voltage supply line of the plurality of voltage supply lines; and voltage connecting bridges of the plurality of voltage connecting bridges in a same pixel column are connected to same adjacent voltage supply lines of the plurality of voltage supply lines.

Optionally, the plurality of voltage supply lines comprise a first adjacent voltage supply line, a second adjacent voltage supply line, and a third adjacent voltage supply line; the first adjacent voltage supply line is configured to provide a voltage supply signal to a first pixel driving circuit in a respective first subpixel, the second adjacent voltage supply line is configured to provide a voltage supply signal to a second pixel driving circuit in a respective second subpixel, and the third adjacent voltage supply line is configured to provide a voltage supply signal to a third pixel driving circuit in a respective third subpixel; and a respective voltage connecting bridge of the plurality of voltage connecting bridges is connected to the first adjacent voltage supply line, the second adjacent voltage supply line, and the third adjacent voltage supply line, respectively.

Optionally, each of the first adjacent voltage supply line, the second adjacent voltage supply line, and the third adjacent voltage supply line comprises a plurality of first voltage supply line portions and a plurality of second voltage supply line portions alternately arranged; a respective voltage connecting bridge of the plurality of voltage connecting bridges is connected to a first adjacent voltage supply line portion and a second adjacent voltage supply line portion of the first adjacent voltage supply line, respectively, is connected to a first adjacent voltage supply line portion and a second adjacent voltage supply line portion of the second adjacent voltage supply line, respectively, and is connected to a first adjacent voltage supply line portion and a second adjacent voltage supply line portion of the third adjacent voltage supply line, respectively.

Optionally, the plurality of voltage supply lines comprise a first adjacent voltage supply line and a second adjacent voltage supply line; a respective voltage supply line of the plurality of voltage supply lines is connected to two adjacent columns of voltage connecting bridges of the plurality of voltage connecting bridges; and a respective voltage connecting bridge of the plurality of voltage connecting bridges is connected to the first adjacent voltage supply line and is connected to the second adjacent voltage supply line.

Optionally, a respective voltage connecting bridge of the plurality of voltage connecting bridges comprises second capacitor electrodes of multiple pixel driving circuits.

Optionally, the array substrate further comprises a plurality of signal lines: wherein a respective signal line of the plurality of signal lines comprises a plurality of first signal line portions, a plurality of second signal line portions, and a plurality of third signal line portions: the plurality of first signal line portions and the plurality of second signal line portions are in two different layers; the plurality of first signal line portions and the plurality of third signal line portions are in two different layers; a respective second signal line portion of the plurality of second signal line portions is connected to two adjacent first signal line portions of the plurality of first signal line portions, respectively; a respective third signal line portion of the plurality of third signal line portions is connected to two adjacent first signal line portions of the plurality of first signal line portions, respectively; two individual first signal line portions of the plurality of first signal line portions, an individual second signal line portion of the plurality of second signal line portions, and an individual third signal line portion of the plurality of third signal line portions form a loop substantially surrounding a region having transistors and capacitors of a pixel driving circuit of a subpixel; and the two individual first signal line portions are connected by the individual second signal line portion, and connected by the individual third signal line portion.

Optionally, the array substrate comprises a plurality of loops sequentially arranged in a row; wherein the plurality of loops substantially surround regions of pixel driving circuits of subpixels of a same color, respectively; and a respective loop of the plurality of loops substantially surrounds a region of a pixel driving circuit of a subpixel of the same color.

Optionally, the array substrate comprises a plurality of loops sequentially arranged in a row; wherein the plurality of loops substantially surround regions having anodes of subpixels of a same color, respectively; and a respective loop of the plurality of loops substantially surrounds a region having an anode of a subpixel of the same color.

Optionally, subpixels are arranged in rows and columns; in an m-th row of subpixels, the array substrate comprises a row of first subpixels of a first color; in a (m+1)-th row of subpixels, the array substrate comprises a row of third subpixels of a third color; in a (m+2)-th row of subpixels, the array substrate comprises a row of second subpixels of a second color; in an n-th column of subpixels, the array substrate comprises a column of third subpixels of the third color; in a (n−1)-th column of subpixels, the array substrate comprises a column of first subpixels of the first color and second subpixels of the second color alternately arranged; in a (n+1)-th column of subpixels, the array substrate comprises a column of first subpixels of the first color and second subpixels of the second color alternately arranged; a first signal line portion of the plurality of first signal line portions is connected to one or more transistors in a pixel driving circuit in a third subpixel in the n-th column of subpixels and the (m+1)-th row of subpixels, is connected to one or more transistors in a pixel driving circuit in a first subpixel in the (n−1)-th column of subpixels and the m-th row of subpixels, and is connected to one or more transistors in a pixel driving circuit in a second subpixel in the (n+1)-th column of subpixels and the (m+2)-th row of subpixels.

Optionally, a second signal line portion of the plurality of second signal line portions connects the first signal line portion with a first adjacent first signal line portion, the first adjacent first signal line portion is connected to one or more transistors in a pixel driving circuit in a second subpixel in the (n−1)-th column of subpixels and the (m+2)-th row of subpixels.

Optionally, a third signal line portion of the plurality of third signal line portions connects the first signal line portion with a second adjacent first signal line portion, the second adjacent first signal line portion is connected to one or more transistors in a pixel driving circuit in a first subpixel in the (n+1)-th column of subpixels and the m-th row of subpixels.

Optionally, the array substrate further comprises a plurality of light transmissive regions; wherein, in the n-th column of subpixels, a respective light transmissive region of the plurality of light transmissive regions spaces apart two adjacent third subpixels.

Optionally, the plurality of signal lines comprise a plurality of initialization signal lines; the plurality of first signal line portions comprise a plurality of first initialization signal line portions; the plurality of second signal line portions comprise a plurality of second initialization signal line portions; and the plurality of third signal line portions comprise a plurality of third initialization signal line portions.

Optionally, the plurality of signal lines comprise a plurality of gate signal lines; the plurality of first signal line portions comprise a plurality of first gate signal line portions; the plurality of second signal line portions comprise a plurality of second gate signal line portions; and the plurality of third signal line portions comprise a plurality of third gate signal line portions.

Optionally, the plurality of signal lines comprise a plurality of reset control signal lines; the plurality of first signal line portions comprise a plurality of first reset control signal line portions; the plurality of second signal line portions comprise a plurality of second reset control signal line portions; and the plurality of third signal line portions comprise a plurality of third reset control signal line portions.

Optionally, the plurality of signal lines comprise a plurality of light emitting control signal lines; the plurality of first signal line portions comprise a plurality of first light emitting control signal line portions; the plurality of second signal line portions comprise a plurality of second light emitting control signal line portions; and the plurality of third signal line portions comprise a plurality of third light emitting control signal line portions.

Optionally, the array substrate further comprises a plurality of light transmissive regions; wherein the array substrate comprises a first conductive layer, a second conductive layer, a first signal line layer, a third signal line layer, and an anode layer; signal lines and electrodes of the first conductive layer, the second conductive layer, the first signal line layer, the third signal line layer, and the anode layer are absent in the plurality of light transmissive regions.

Optionally, the array substrate further comprises a second signal line layer; wherein signal lines in the second signal line layer comprise a substantially transparent conductive material; and the signal lines of the second signal line layer are present in the plurality of light transmissive regions.

Optionally, the plurality of second signal line portions and the plurality of third signal line portions are in the second signal line layer; and the plurality of first signal line portions are in the first conductive layer or in the second conductive layer.

In another aspect, the present disclosure provides a display apparatus, comprising the array substrate described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a circuit diagram illustrating the structure of a pixel driving circuit in some embodiments according to the present disclosure.

FIG. 2C is a timing diagram illustrating the operation of a pixel driving circuit in some embodiments according to the present disclosure.

FIG. 3A is a diagram illustrating the structure of a portion of an array substrate in some embodiments according to the present disclosure.

FIG. 3B is a diagram illustrating the structure of a semiconductor material layer in the portion of the array substrate depicted in FIG. 3A.

FIG. 3C is a diagram illustrating the structure of a first conductive layer in the portion of the array substrate depicted in FIG. 3A.

FIG. 3D is a diagram illustrating the structure of a second conductive layer in the portion of the array substrate depicted in FIG. 3A.

FIG. 3E is a diagram illustrating the structure of an inter-layer dielectric layer in the portion of the array substrate depicted in FIG. 3A.

FIG. 3F is a diagram illustrating the structure of a first signal line layer in the portion of the array substrate depicted in FIG. 3A.

FIG. 3G is a diagram illustrating the structure of a passivation layer in the portion of the array substrate depicted in FIG. 3A.

FIG. 3H is a diagram illustrating the structure of a second signal line layer in the portion of the array substrate depicted in FIG. 3A.

FIG. 3I is a diagram illustrating the structure of a first planarization layer in the portion of the array substrate depicted in FIG. 3A.

FIG. 3J is a diagram illustrating the structure of a third signal line layer in the portion of the array substrate depicted in FIG. 3A.

FIG. 3K is a diagram illustrating the structure of a second planarization layer in the portion of the array substrate depicted in FIG. 3A.

FIG. 3L is a diagram illustrating the structure of an anode layer in the portion of the array substrate depicted in FIG. 3A.

FIG. 3M is a diagram illustrating the structure of a pixel definition layer in the portion of the array substrate depicted in FIG. 3A.

FIG. 4 is a cross-sectional view along an A-A′ line in FIG. 3A.

FIG. 5A is a diagram illustrating the structure of a portion of an array substrate in some embodiments according to the present disclosure.

FIG. 5B is a diagram illustrating the structure of a semiconductor material layer in the portion of the array substrate depicted in FIG. 5A.

FIG. 5C is a diagram illustrating the structure of a first conductive layer in the portion of the array substrate depicted in FIG. 5A.

FIG. 5D is a diagram illustrating the structure of a second conductive layer in the portion of the array substrate depicted in FIG. 5A.

FIG. 5E is a diagram illustrating the structure of an inter-layer dielectric layer in the portion of the array substrate depicted in FIG. 5A.

FIG. 5F is a diagram illustrating the structure of a first signal line layer in the portion of the array substrate depicted in FIG. 5A.

FIG. 5G is a diagram illustrating the structure of a passivation layer in the portion of the array substrate depicted in FIG. 5A.

FIG. 5H is a diagram illustrating the structure of a second signal line layer in the portion of the array substrate depicted in FIG. 5A.

FIG. 5I is a diagram illustrating the structure of a first planarization layer in the portion of the array substrate depicted in FIG. 5A.

FIG. 5J is a diagram illustrating the structure of a third signal line layer in the portion of the array substrate depicted in FIG. 5A.

FIG. 5K is a diagram illustrating the structure of a second planarization layer in the portion of the array substrate depicted in FIG. 5A.

FIG. 5L is a diagram illustrating the structure of an anode layer in the portion of the array substrate depicted in FIG. 5A.

FIG. 5M is a diagram illustrating the structure of a pixel definition layer in the portion of the array substrate depicted in FIG. 5A.

FIG. 6 is a diagram illustrating a voltage supply network in a portion of an array substrate in some embodiments according to the present disclosure.

FIG. 7 is a diagram illustrating the structure of a portion of an array substrate in some embodiments according to the present disclosure.

FIG. 8 is a diagram illustrating a reset signal network in a portion of an array substrate in some embodiments according to the present disclosure.

FIG. 9 is a diagram illustrating a reset signal network in a portion of an array substrate in some embodiments according to the present disclosure,

FIG. 10 is a diagram illustrating a gate scanning signal network in a portion of an array substrate in some embodiments according to the present disclosure.

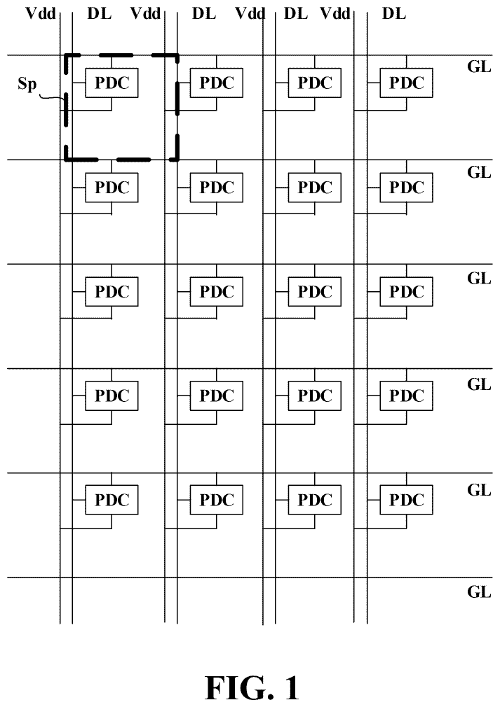

FIG. 1I is a diagram illustrating a gate scanning signal network in a portion of an array substrate in some embodiments according to the present disclosure.

FIG. 12 is a diagram illustrating a reset control signal network in a portion of an array substrate in some embodiments according to the present disclosure.

FIG. 13 is a diagram illustrating a reset control signal network in a portion of an array substrate in some embodiments according to the present disclosure.

FIG. 14 is a diagram illustrating a light emitting control signal network in a portion of an array substrate in some embodiments according to the present disclosure.

FIG. 15 is a diagram illustrating a light emitting control signal network in a portion of an array substrate in some embodiments according to the present disclosure.

FIG. 16A is a diagram illustrating the structure of a portion of an array substrate in some embodiments according to the present disclosure.

FIG. 16B is a diagram illustrating the structure of a semiconductor material layer in the portion of the array substrate depicted in FIG. 16A.

FIG. 16C is a diagram illustrating the structure of a first conductive layer in the portion of the array substrate depicted in FIG. 16A.

FIG. 16D is a diagram illustrating the structure of a second conductive layer in the portion of the array substrate depicted in FIG. 16A.

FIG. 16E is a diagram illustrating the structure of an inter-layer dielectric layer in the portion of the array substrate depicted in FIG. 16A.

FIG. 16F is a diagram illustrating the structure of a first signal line layer in the portion of the array substrate depicted in FIG. 16A.

FIG. 16G is a diagram illustrating the structure of a passivation layer in the portion of the array substrate depicted in FIG. 16A.

FIG. 16H is a diagram illustrating the structure of a second signal line layer in the portion of the array substrate depicted in FIG. 16A.

FIG. 16I is a diagram illustrating the structure of a first planarization layer in the portion of the array substrate depicted in FIG. 16A.

FIG. 16J is a diagram illustrating the structure of a third signal line layer in the portion of the array substrate depicted in FIG. 16A.

FIG. 16K is a diagram illustrating the structure of a second planarization layer in the portion of the array substrate depicted in FIG. 16A.

FIG. 16L is a diagram illustrating the structure of an anode layer in the portion of the array substrate depicted in FIG. 16A,

FIG. 16M is a diagram illustrating the structure of a pixel definition layer in the portion of the array substrate depicted in FIG. 16A.

FIG. 17A is a diagram illustrating the structure of a portion of an array substrate in some embodiments according to the present disclosure.

FIG. 17B is a diagram illustrating the structure of a semiconductor material layer in the portion of the array substrate depicted in FIG. 17A.

FIG. 17C is a diagram illustrating the structure of a first conductive layer in the portion of the array substrate depicted in FIG. 17A.

FIG. 17D is a diagram illustrating the structure of a second conductive layer in the portion of the array substrate depicted in FIG. 17A.

FIG. 17E is a diagram illustrating the structure of an inter-layer dielectric layer in the portion of the array substrate depicted in FIG. 17A.

FIG. 17F is a diagram illustrating the structure of a first signal line layer in the portion of the array substrate depicted in FIG. 17A.

FIG. 17G is a diagram illustrating the structure of a passivation layer in the portion of the array substrate depicted in FIG. 17A.

FIG. 171I is a diagram illustrating the structure of a second signal line layer in the portion of the array substrate depicted in FIG. 17A.

FIG. 17I is a diagram illustrating the structure of a first planarization layer in the portion of the array substrate depicted in FIG. 17A.

FIG. 17J is a diagram illustrating the structure of a third signal line layer in the portion of the array substrate depicted in FIG. 17A.

FIG. 17K is a diagram illustrating the structure of a second planarization layer in the portion of the array substrate depicted in FIG. 17A.

FIG. 17L is a diagram illustrating the structure of an anode layer in the portion of the array substrate depicted in FIG. 17A.

FIG. 17M is a diagram illustrating the structure of a pixel definition layer in the portion of the array substrate depicted in FIG. 17A.

FIG. 18 is a diagram illustrating a voltage supply network in a portion of an array substrate in some embodiments according to the present disclosure.

FIG. 19 is a diagram illustrating the structure of a portion of an array substrate in some embodiments according to the present disclosure.

FIG. 20 is a diagram illustrating a reset signal network in a portion of an array substrate in some embodiments according to the present disclosure.

FIG. 21 is a diagram illustrating a reset signal network in a portion of an array substrate in some embodiments according to the present disclosure.

FIG. 22 is a diagram illustrating agate scanning signal network in a portion of an array substrate in some embodiments according to the present disclosure.

FIG. 23 is a diagram illustrating a gate scanning signal network in a portion of an array substrate in some embodiments according to the present disclosure.

FIG. 24 is a diagram illustrating a reset control signal network in a portion of an array substrate in some embodiments according to the present disclosure.

FIG. 25 is a diagram illustrating a reset control signal network in a portion of an array substrate in some embodiments according to the present disclosure.

FIG. 26 is a diagram illustrating a light emitting control signal network in a portion of an array substrate in some embodiments according to the present disclosure.

FIG. 27 is a diagram illustrating alight emitting control signal network in a portion of an array substrate in some embodiments according to the present disclosure.

FIG. 28A is a diagram illustrating the structure of a portion of an array substrate in some embodiments according to the present disclosure.

FIG. 28B is a diagram illustrating the structure of a semiconductor material layer in the portion of the array substrate depicted in FIG. 28A.

FIG. 28C is a diagram illustrating the structure of a first conductive layer in the portion of the array substrate depicted in FIG. 28A.

FIG. 28D is a diagram illustrating the structure of a second conductive layer in the portion of the array substrate depicted in FIG. 28A.

FIG. 28E is a diagram illustrating the structure of an inter-layer dielectric layer in the portion of the array substrate depicted in FIG. 28A.

FIG. 28F is a diagram illustrating the structure of a first signal line layer in the portion of the array substrate depicted in FIG. 28A,

FIG. 28G is a diagram illustrating the structure of a passivation layer in the portion of the array substrate depicted in FIG. 28A.

FIG. 28H is a diagram illustrating the structure of a first planarization layer in the portion of the array substrate depicted in FIG. 28A.

FIG. 28I is a diagram illustrating the structure of a third signal line layer in the portion of the array substrate depicted in FIG. 28A.

FIG. 28J is a diagram illustrating the structure of a second planarization layer in the portion of the array substrate depicted in FIG. 28A.

FIG. 28K is a diagram illustrating the structure of an anode layer in the portion of the array substrate depicted in FIG. 28A.

FIG. 28L is a diagram illustrating the structure of a pixel definition layer in the portion of the array substrate depicted in FIG. 28A.

FIG. 29 is a cross-sectional view along a B-B′ line in FIG. 28A.

FIG. 30A is a diagram illustrating the structure of a portion of an array substrate in some embodiments according to the present disclosure.

FIG. 30B is a diagram illustrating the structure of a semiconductor material layer in the portion of the array substrate depicted in FIG. 30A.

FIG. 30C is a diagram illustrating the structure of a first conductive layer in the portion of the array substrate depicted in FIG. 30A.

FIG. 30D is a diagram illustrating the structure of a second conductive layer in the portion of the array substrate depicted in FIG. 30A.

FIG. 30E is a diagram illustrating the structure of an inter-layer dielectric layer in the portion of the array substrate depicted in FIG. 30A.

FIG. 30F is a diagram illustrating the structure of a first signal line layer in the portion of the array substrate depicted in FIG. 30A.

FIG. 30G is a diagram illustrating the structure of a passivation layer in the portion of the array substrate depicted in FIG. 30A.

FIG. 30H is a diagram illustrating the structure of a first planarization layer in the portion of the array substrate depicted in FIG. 30A.

FIG. 30I is a diagram illustrating the structure of a third signal line layer in the portion of the array substrate depicted in FIG. 30A.

FIG. 30J is a diagram illustrating the structure of a second planarization layer in the portion of the array substrate depicted in FIG. 30A.

FIG. 30K is a diagram illustrating the structure of an anode layer in the portion of the array substrate depicted in FIG. 30A.

FIG. 30L is a diagram illustrating the structure of a pixel definition layer in the portion of the array substrate depicted in FIG. 30A.

FIG. 31 is a diagram illustrating a voltage supply network in a portion of an array substrate in some embodiments according to the present disclosure.

FIG. 32 is a diagram illustrating the structure of a portion of an array substrate in some embodiments according to the present disclosure.

FIG. 33 is a diagram illustrating a reset signal network in a portion of an array substrate in some embodiments according to the present disclosure.

FIG. 34 is a diagram illustrating a reset signal network in a portion of an array substrate in some embodiments according to the present disclosure.

FIG. 35 is a diagram illustrating a gate scanning signal network in a portion of an array substrate in some embodiments according to the present disclosure.

FIG. 36 is a diagram illustrating a gate scanning signal network in a portion of an array substrate in some embodiments according to the present disclosure.

FIG. 37 is a diagram illustrating a reset control signal network in a portion of an array substrate in some embodiments according to the present disclosure.

FIG. 38 is a diagram illustrating a reset control signal network in a portion of an array substrate in some embodiments according to the present disclosure.

FIG. 39 is a diagram illustrating a light emitting control signal network in a portion of an array substrate in some embodiments according to the present disclosure.

FIG. 40 is a diagram illustrating a light emitting control signal network in a portion of an array substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a plurality of signal lines. Optionally, a respective signal line of the plurality of signal lines comprises a plurality of first signal line portions, a plurality of second signal line portions, and a plurality of third signal line portions. Optionally, the plurality of first signal line portions and the plurality of second signal line portions are in two different layers. Optionally, the plurality of first signal line portions and the plurality of third signal line portions are in two different layers. Optionally, a respective second signal line portion of the plurality of second signal line portions is connected to two adjacent first signal line portions of the plurality of first signal line portions, respectively. Optionally, a respective third signal line portion of the plurality of third signal line portions is connected to two adjacent first signal line portions of the plurality of first signal line portions, respectively. Optionally, two individual first signal line portions of the plurality of first signal line portions, an individual second signal line portion of the plurality of second signal line portions, and an individual third signal line portion of the plurality of third signal line portions form a loop substantially surrounding a region having transistors and capacitors of a pixel driving circuit of a subpixel. Optionally, the two individual first signal line portions are connected by the individual second signal line portion, and connected by the individual third signal line portion.

Various appropriate pixel driving circuits may be used in the present array substrate. Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is a 7T1C driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

FIG. 1 is a plan view of an array substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of gate signal lines GL, a plurality of data lines DL, a plurality of voltage supply lines Vdd (e.g., a plurality of first voltage supply lines and/or a plurality of second voltage supply lines). Light emission in a respective subpixel Sp is driven by a respective pixel driving circuit PDC. In one example, a high voltage signal (e.g., a VDD signal) is input, through a respective voltage supply line of the plurality of voltage supply line Vdd, to the respective pixel driving circuit PDC connected to an anode of the light emitting element; a low voltage signal (e.g., a VSS signal) is input, through a low voltage supply line, to a cathode of the light emitting element. A voltage difference between the high voltage signal (e.g., the VDD signal) and the low voltage signal (e.g., the VSS signal) is a driving voltage ΔV that drives light emission in the light emitting element.

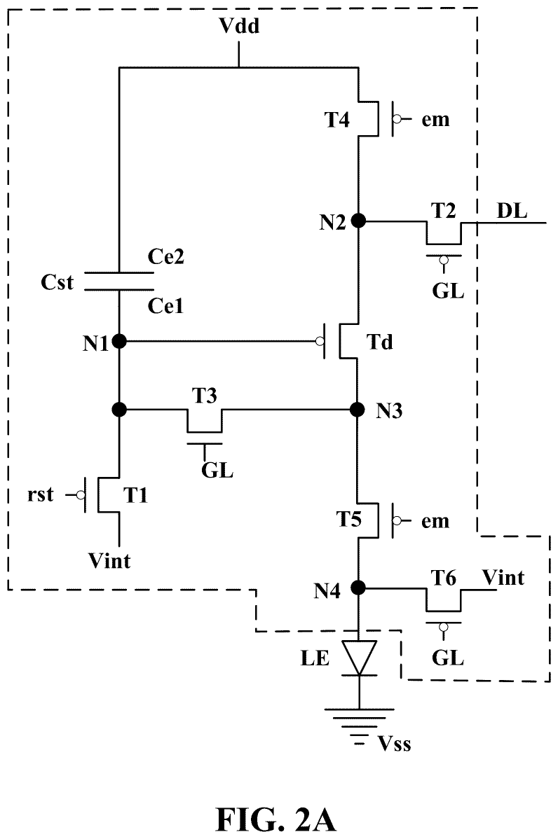

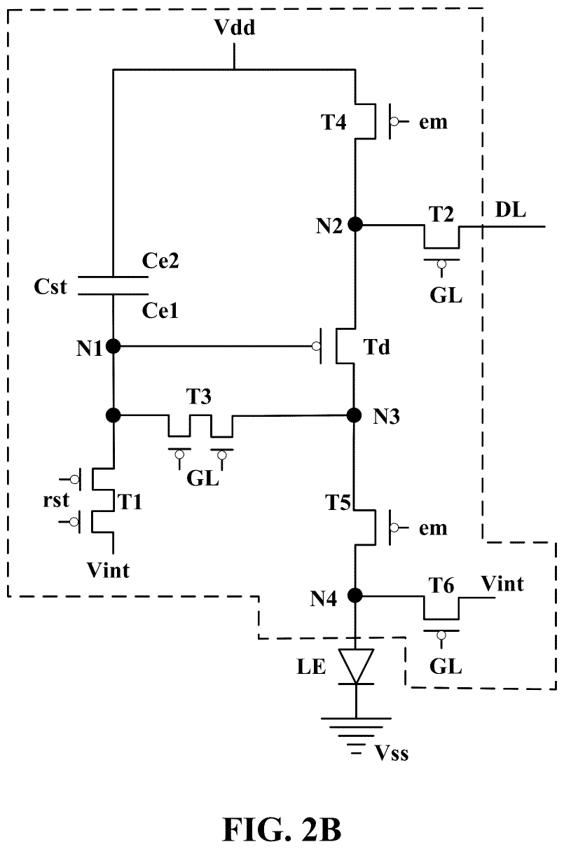

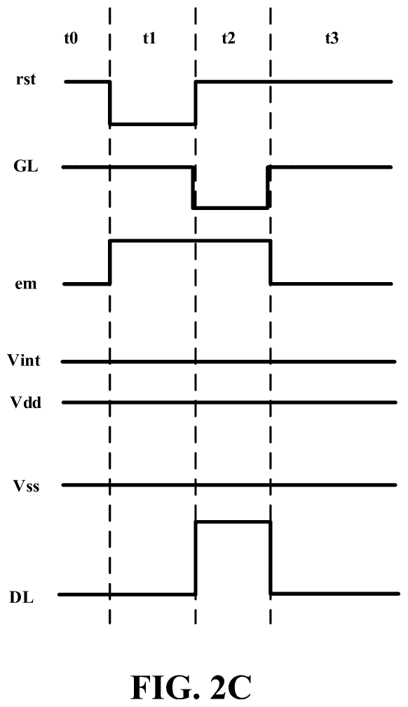

FIG. 2A is a circuit diagram illustrating the structure of a pixel driving circuit in some embodiments according to the present disclosure. Referring to FIG. 2A, in some embodiments, the pixel driving circuit includes a driving transistor Td; a storage capacitor Cst having a first capacitor electrode Ce1 and a second capacitor electrode Ce2; a first transistor T1 having a gate electrode connected to a respective reset control signal line of a plurality of reset control signal lines rst, a first electrode connected to a respective initialization signal line of a plurality of initialization signal lines Vint, and a second electrode connected to a first capacitor electrode Ce1 of the storage capacitor Cst and a gate electrode of the driving transistor Td; a second transistor 12 having a gate electrode connected to a respective gate signal line of a plurality of gate signal lines GL a first electrode connected to a respective data line of a plurality of data lines DL, and a second electrode connected to a first electrode of the driving transistor Td; a third transistor T3 having a gate electrode connected to the respective gate signal line, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective voltage supply line of a plurality of voltage supply lines Vdd, and a second electrode connected to the first electrode of the driving transistor Td and the second electrode of the second transistor T2; a fifth transistor T5 having a gate electrode connected to the respective light emitting control signal line, a first electrode connected to second electrodes of the driving transistor Td and the third transistor T3, and a second electrode connected to an anode of a light emitting element LE; and a sixth transistor T6 having a gate electrode connected to the respective gate signal line of the plurality of gate signal lines GL, a first electrode connected to the respective initialization signal line of the plurality of initialization signal lines Vint, and a second electrode connected to the second electrode of the fifth transistor and the anode of the light emitting element LE. The second capacitor electrode Ce2 is connected to the respective voltage supply line and the first electrode of the fourth transistor T4.

In some embodiments, the pixel driving circuit includes a driving transistor Td, a data write transistor (e.g., the second transistor T2), a compensating transistor (e.g., the third transistor T3), two light emitting control transistors (e.g., the fourth transistor T4 and the fifth transistor T5), and two reset transistors (e.g., the first transistor T1 and the sixth transistor T6).

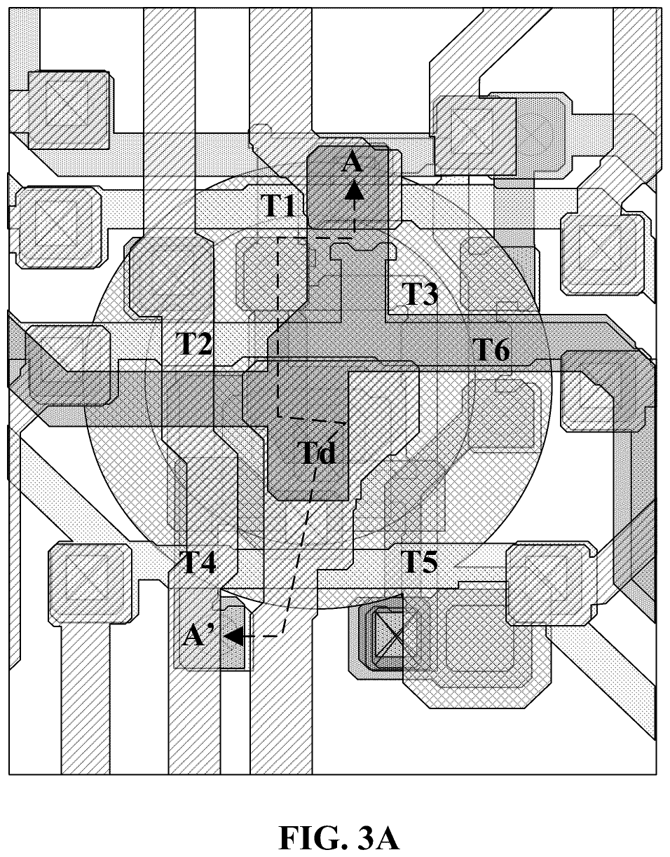

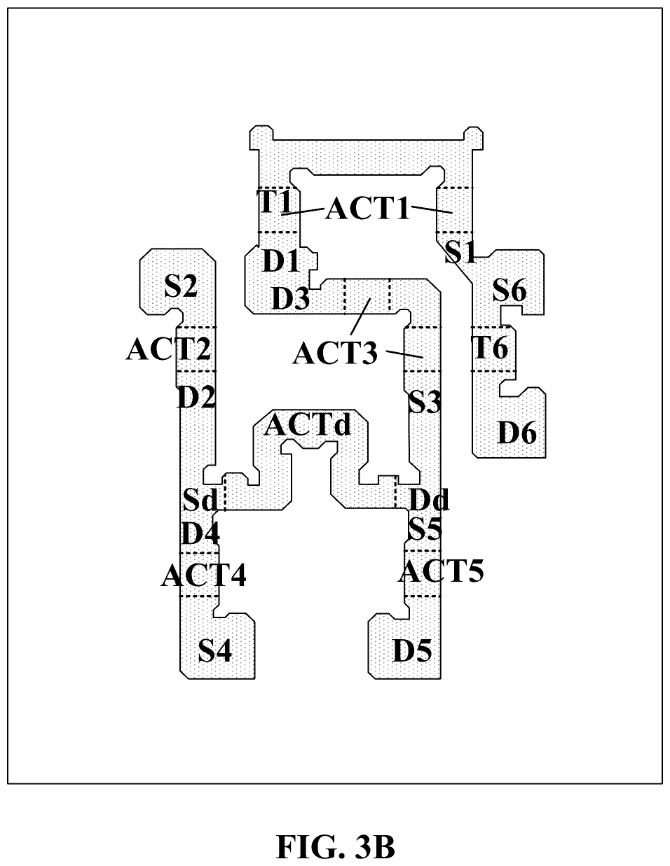

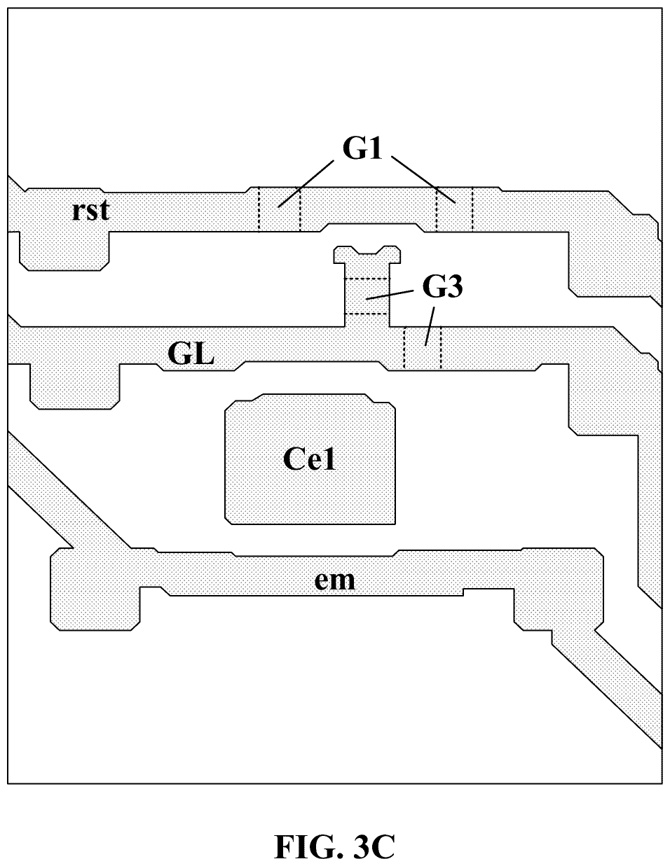

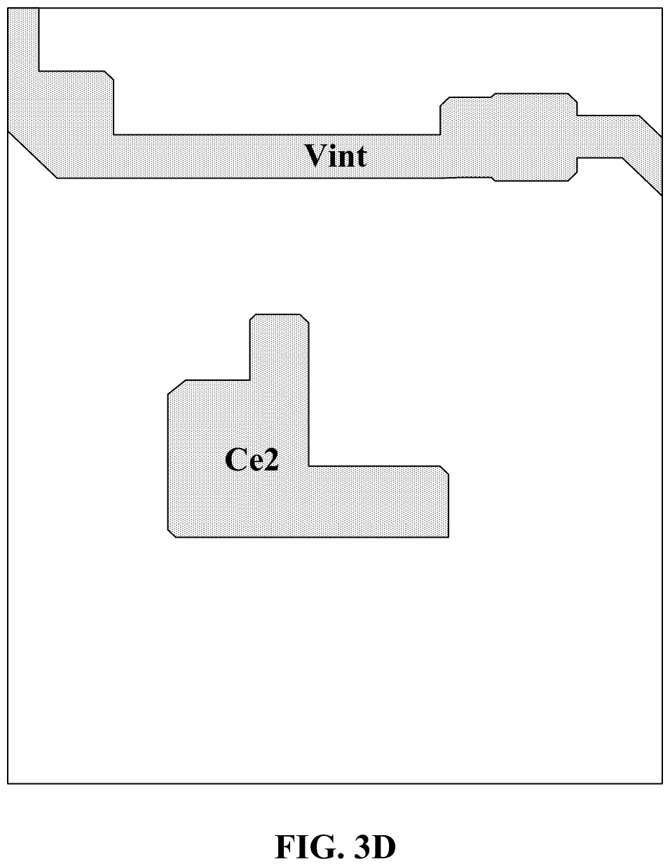

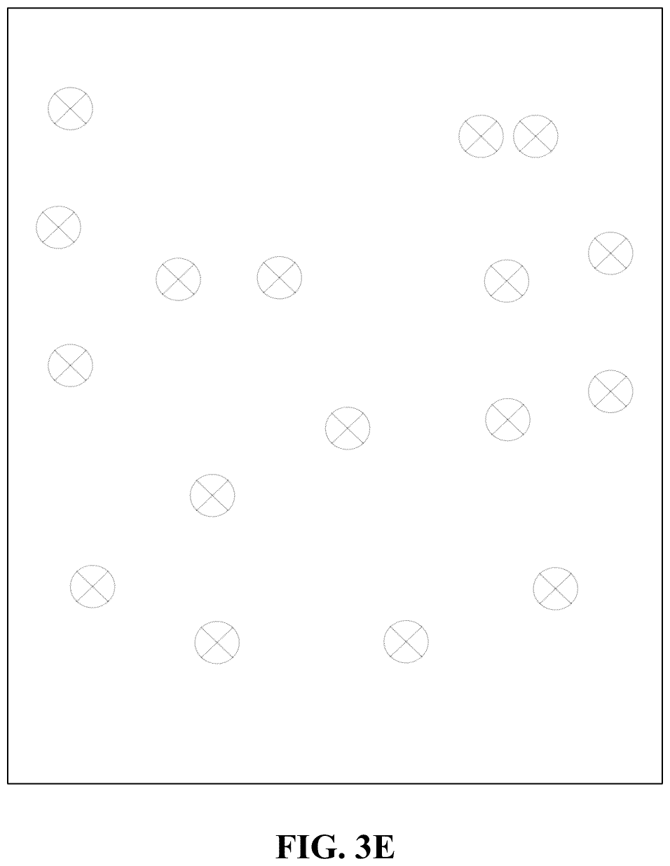

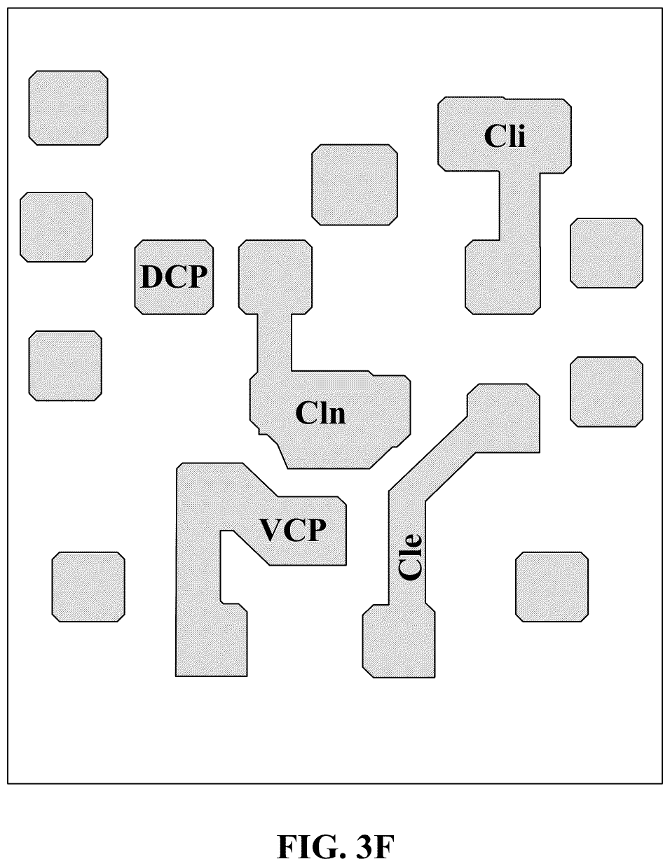

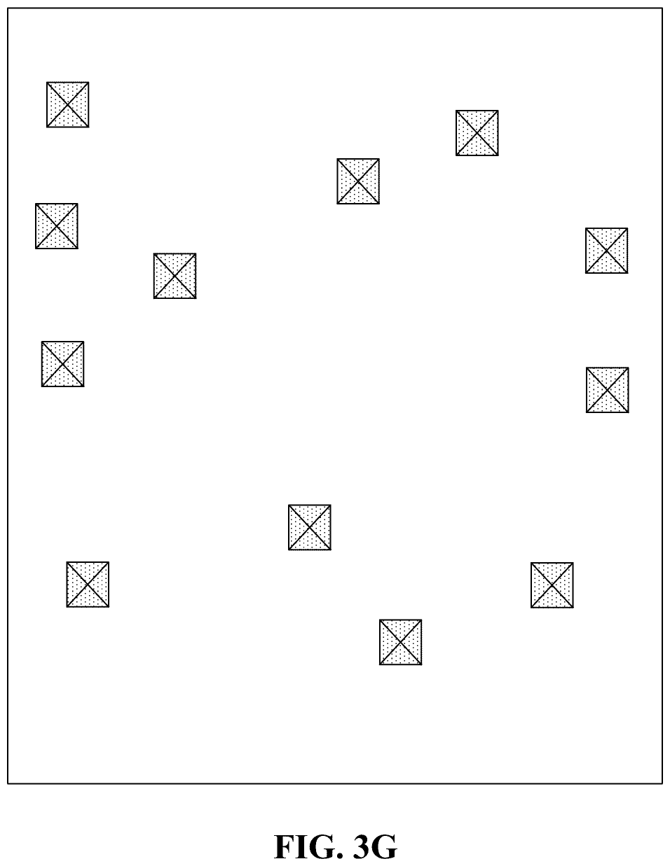

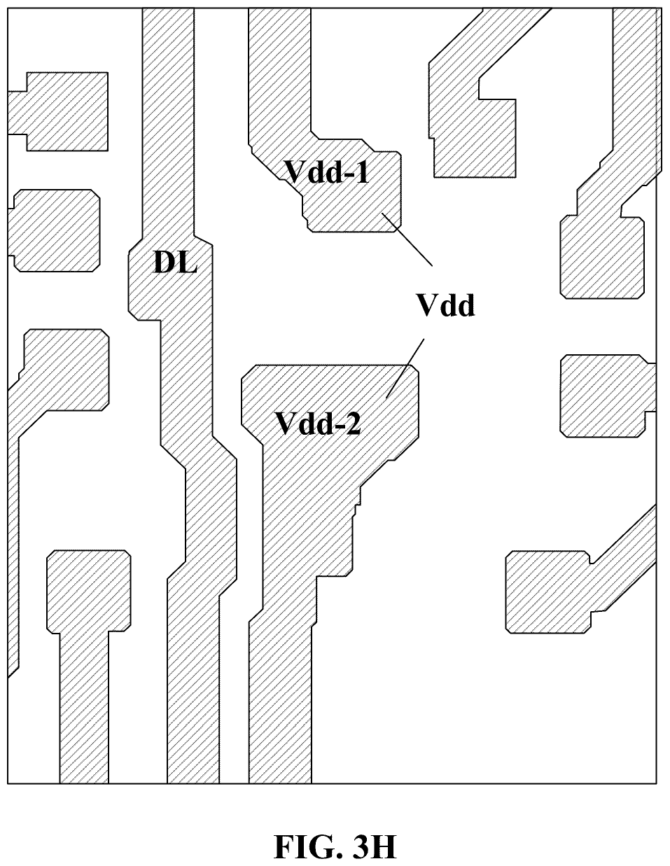

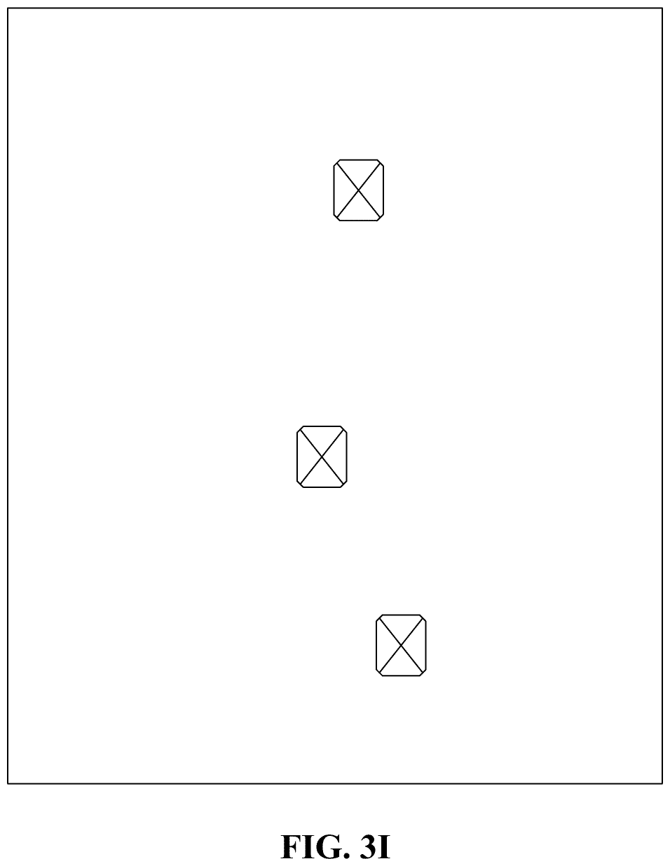

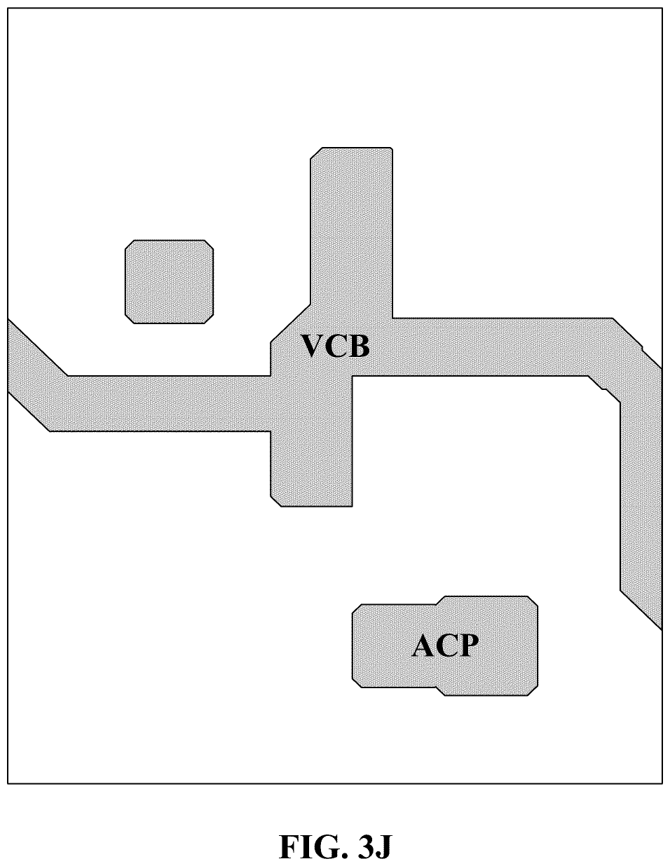

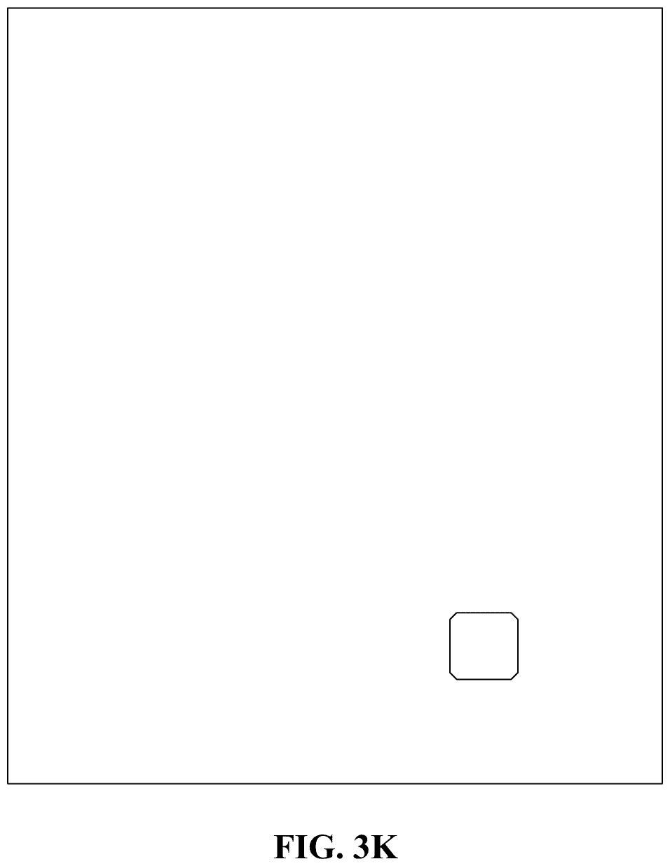

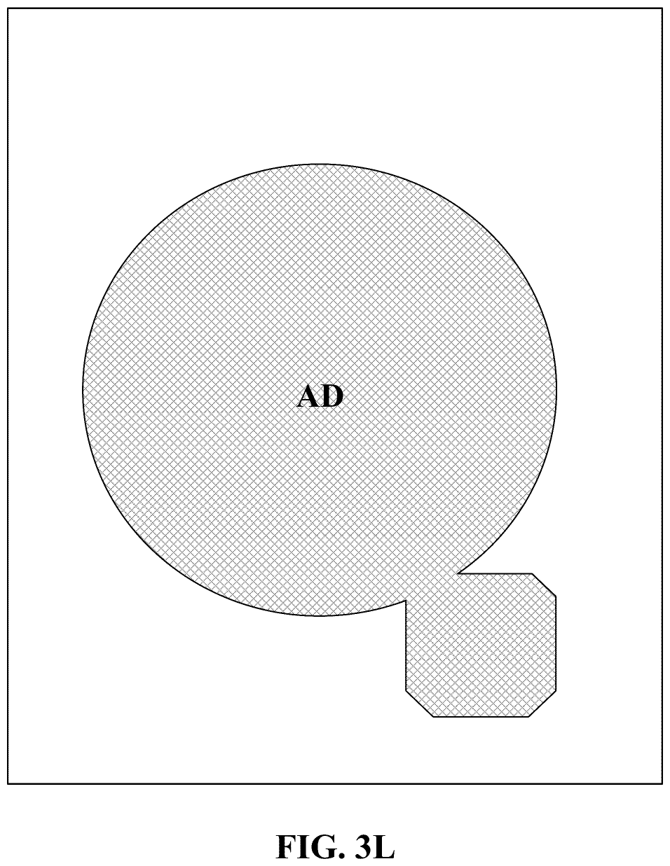

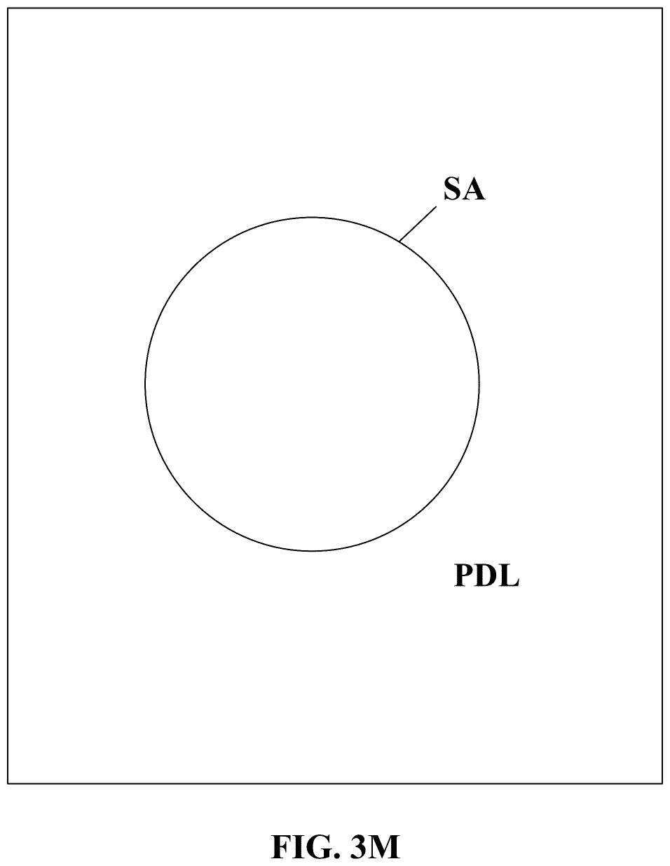

FIG. 2B is a circuit diagram illustrating the structure of a pixel driving circuit in some embodiments according to the present disclosure. Referring to FIG. 2B, in some embodiments, the third transistor T3 is a “double gate” transistor, and the first transistor T1 is a “double gate” transistor. Optionally, in a “double gate” first transistor, the active layer of the first transistor crosses over a respective reset control signal lines twice (alternatively, the respective reset control signal line crosses over the active layer of the first transistor T1 twice). Similarly, in a “double gate” third transistor, the active layer of the third transistor T3 crosses over a respective first gate signal line of the plurality of first gate signal lines GL1 twice (alternatively, the respective gate signal line crosses over the active layer of the third transistor T3 twice). The gate electrode of the first transistor T1 is denoted as “G1” in FIG. 3C, in which the first transistor T1 is a “double gate” transistor. The gate electrode of the third transistor T3 is denoted as “G3” in FIG. 3C, in which the third transistor T3 is a “double gate” transistor.

The pixel driving circuit further include a first node N1, a second node N2, a third node N3, and a fourth node N4. The first node N1 is connected to the gate electrode of the driving transistor Td, the first capacitor electrode Ce1, and the first electrode of the third transistor T3. The second node N2 is connected to the second electrode of the fourth transistor T4, the second electrode of the second transistor T2, and the first electrode of the driving transistor Td. The third node N3 is connected to the second electrode of the driving transistor Td, the second electrode of the third transistor T3, and the first electrode of the fifth transistor T5. The fourth node N4 is connected to the second electrode of the fifth transistor T5, the second electrode of the sixth transistor T6, and the anode of the light emitting element LE.

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor. In one example, the first electrode is configured to receive an input signal and the second electrode is configured to output an output signal; in another example, the second electrode is configured to receive an input signal and the first electrode is configured to output an output signal.

FIG. 2C is a timing diagram illustrating the operation of a pixel driving circuit in some embodiments according to the present disclosure. Referring to FIG. 2A to FIG. 2C, during one frame of image, the operation of the pixel driving circuit includes a reset sub-phase t1, a data write sub-phase t2, and a light emitting sub-phase 3. In the initial sub-phase t0, a turning-off reset control signal is provided through the respective reset control signal line of the plurality of reset control signal lines rst to the gate electrode of the first transistor T1 to turn off the first transistor T1. In the initial sub-phase to, the respective gate signal line of the plurality of gate signal lines GL is provided with a turning-off signal, thus the second transistor T2 and the third transistor T3 are turned off.

In the reset sub-phase t1, a turning-on reset control signal is provided through the respective reset control signal line of the plurality of reset control signal lines rst to the gate electrode of the first transistor T1 to turn on the first transistor T1; allowing an initialization voltage signal from the respective initialization signal line of the plurality of initialization signal lines Vint to pass from a first electrode of the first transistor T1 to a second electrode of the first transistor T1, and in turn to the first capacitor electrode Ce1 and the gate electrode of the driving transistor Td. The gate electrode of the driving transistor Td is initialized. The second capacitor electrode Ce2 receives a high voltage signal from the respective second voltage supply line of the plurality of second voltage supply lines Vdd2. The first capacitor electrode Ce1 is charged in the reset sub-phase t1 due to an increasing voltage difference between the first capacitor electrode Ce1 and the second capacitor electrode Ce2. In the reset sub-phase t1, the respective gate signal line of the plurality of gate signal lines GL is provided with a turning-off signal, thus the second transistor T2 and the third transistor T3 are turned off. The respective light emitting control signal line of the plurality of light emitting control signal lines em is provided with a high voltage signal to turn off the fourth transistor T4 and the fifth transistor T5.

in the data write sub-phase t2, the turning-off reset control signal is again provided through the respective reset control signal line of the plurality of reset control signal lines rst to the gate electrode of the first transistor T1 to turn off the first transistor T1. The respective gate signal line of the plurality of gate signal lines GL is provided with a turning-on signal, thus the second transistor T2 and the third transistor T3 are turned on. A second electrode of the driving transistor Td is connected with the second electrode of the third transistor T3. A gate electrode of the driving transistor Td is electrically connected with the first electrode of the third transistor T3. Because the third transistor T3 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The second transistor T2 is turned on in the data write sub-phase t2. The data voltage signal transmitted through the respective data line of a plurality of data lines DL is received by a first electrode of the second transistor T2, and in turn transmitted to the first electrode of the driving transistor Td, which is connected to the second electrode of the second transistor T2. A node N2 connecting to the first electrode of the driving transistor Td has a voltage level of the data voltage signal. Because only the PN junction between the gate electrode and a first electrode of the driving transistor Td is effective, the voltage level at the node N1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line of the plurality of light emitting control signal lines em is provided with a high voltage signal to turn off the fourth transistor T4 and the fifth transistor T5.

In the data write sub-phase t2, a turning-on reset control signal is provided through the respective gate signal line of the plurality of gate signal lines GL to the gate electrode of the sixth transistor T6 to turn on the sixth transistor T6; allowing an initialization voltage signal from the respective initialization signal line of the plurality of initialization signal lines Vint to pass from a first electrode of the sixth transistor T6 to a second electrode of the sixth transistor T6; and in turn to the node N4. The anode of the light emitting element LE is initialized.

In the light emitting sub-phase t3, the turning-off reset control signal is again provided through the respective reset control signal line of the plurality of reset control signal lines rst to the gate electrode of the first transistor T1 to turn off the first transistor T1. The respective gate signal line of the plurality of gate signal lines GL is provided with a turning-off signal, the second transistor T2 and the third transistor T3 are turned off. The respective light emitting control signal line of the plurality of light emitting control signal lines em is provided with a low voltage signal to turn on the fourth transistor T4 and the fifth transistor T5. The voltage level at the node N1 in the light emitting sub-phase 3 is maintained at (Vdata+Vth), the driving transistor Td is turned on by the voltage level, and working in the saturation area. A path is formed through the fourth transistor T4, the driving transistor Td, the fifth transistor T5, to the light emitting element LE. The driving transistor Td generates a driving current for driving the light emitting element LE to emit light. A voltage level at a node N3 connected to the second electrode of the driving transistor Td equals to a light emitting voltage of the light emitting element LE.

The array substrate in some embodiments includes a plurality of subpixels. In some embodiments, the plurality of subpixels includes a respective first subpixel, a respective second subpixel, and a respective third subpixel. Optionally, a respective pixel of the array substrate includes the respective first subpixel, the respective second subpixel, and the respective third subpixel. The plurality of subpixels in the array substrate are arranged in an array. In one example, the array of the plurality of subpixels includes a S1-S2-S3 format repeating array, in which S1 stands for the respective first subpixel, S2 stands for the respective second subpixel, and S3 stands for the respective third subpixel. In another example, the S1-S2-S3 format is a C1-C2-C3 format, in which C1 stands for the respective first subpixel of a first color, C2 stands for the respective second subpixel of a second color, and C3 stands for the respective third subpixel of a third color. In another example, the C1-C2-C3 format is an R-G-B format, in which the respective first subpixel is a red subpixel, the respective second subpixel is a green subpixel, and the respective third subpixel is a blue subpixel.

In another example, the array of the plurality of subpixels includes a S1-S2-S3-S4 format repeating array, in which S1 stands for the respective first subpixel, S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is a R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes a respective first subpixel, a respective second subpixel, and a respective third subpixel. Optionally, each of the respective first subpixel, the respective second subpixel, and the respective third subpixel, includes the first transistor T1, the second transistor T2, the third transistor T3, the fourth transistor T4, the fifth transistor T5, the sixth transistor T6, the driving transistor Td, and the storage capacitor Cst.

In alternative embodiments, a minimum repeating unit of the plurality of subpixels of the array substrate includes a respective first subpixel, a respective second subpixel, a respective third subpixel, and a respective fourth subpixel. Optionally, each of the respective first subpixel, the respective second subpixel, the respective third subpixel, and the respective fourth subpixel, includes the first transistor T1, the second transistor T2, the third transistor T3, the fourth transistor T4, the fifth transistor T5, the sixth transistor T6, the driving transistor Td, and the storage capacitor Cst.

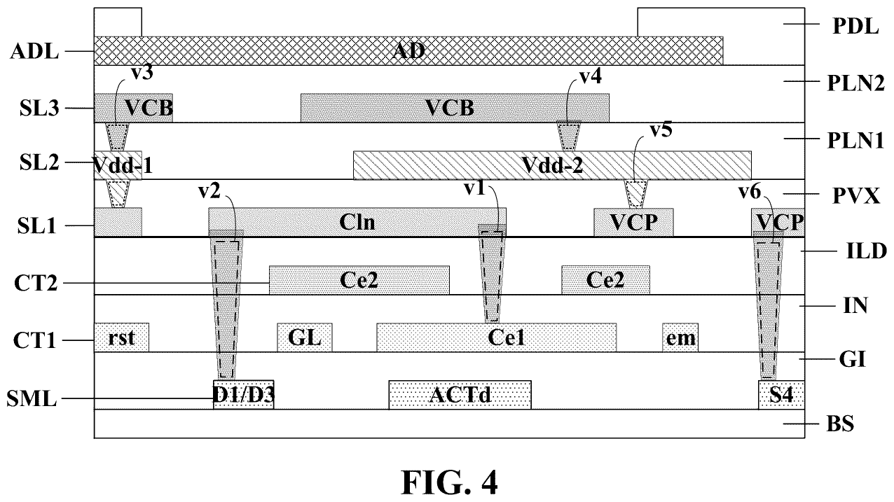

FIG. 3A is a diagram illustrating the structure of a portion of an array substrate in some embodiments according to the present disclosure. FIG. 3B is a diagram illustrating the structure of a semiconductor material layer in the portion of the array substrate depicted in FIG. 3A. FIG. 3C is a diagram illustrating the structure of a first conductive layer in the portion of the array substrate depicted in FIG. 3A. FIG. 3D is a diagram illustrating the structure of a second conductive layer in the portion of the array substrate depicted in FIG. 3A. FIG. 3E is a diagram illustrating the structure of an inter-layer dielectric layer in the portion of the array substrate depicted in FIG. 3A. FIG. 3F is a diagram illustrating the structure of a first signal line layer in the portion of the array substrate depicted in FIG. 3A. FIG. 3G is a diagram illustrating the structure of a passivation layer in the portion of the array substrate depicted in FIG. 3A. FIG. 3H is a diagram illustrating the structure of a second signal line layer in the portion of the array substrate depicted in FIG. 3A. FIG. 31 is a diagram illustrating the structure of a first planarization layer in the portion of the army substrate depicted in FIG. 3A. FIG. 3J is a diagram illustrating the structure of a third signal line layer in the portion of the array substrate depicted in FIG. 3A. FIG. 3K is a diagram illustrating the structure of a second planarization layer in the portion of the array substrate depicted in FIG. 3A. FIG. 3L is a diagram illustrating the structure of an anode layer in the portion of the array substrate depicted in FIG. 3A. FIG. 3M is a diagram illustrating the structure of a pixel definition layer in the portion of the array substrate depicted in FIG. 3A. FIG. 4 is a cross-sectional view along an A-A′ line in FIG. 3A.

Referring to FIG. 3A to FIG. 3M, and FIG. 4, in some embodiments, the array substrate includes a base substrate BS, a semiconductor material layer SML on the base substrate BS, a gate insulating layer G1 on a side of the semiconductor material layer SML away from the base substrate BS, a first conductive layer CT1 on a side of the gate insulating layer G1 away from the semiconductor material layer SML, an insulating layer IN on a side of the first conductive layer CT1 away from the gate insulating layer G1, a second conductive layer CT2 on a side of the insulating layer IN away from the first conductive layer CT1, an inter-layer dielectric layer ILD on a side of the second conductive layer CT2 away from the insulating layer IN, a first signal line layer SL1 on a side of the inter-layer dielectric layer ILD away from the second conductive layer CT2, a passivation layer PVX on a side of the first signal line layer SL1 away from the inter-layer dielectric layer ILD, a second signal line layer SL2 on a side of the passivation layer PVX away from the first signal line layer SL1, a first planarization layer PLN1 on a side of the second signal line layer SL2 away from the passivation layer PVX, a third signal line layer SL3 on a side of the first planarization layer PLN1 away from the second signal line layer SL2, a second planarization layer PLN2 on a side of the third signal line layer SL3 away from the first planarization layer PLN1, an anode layer ADL on a side of the second planarization layer PLN2 away from the third signal line layer SL3, and a pixel definition layer PDL on a side of the anode layer ADL away from the second planarization layer PLN2.

Referring to FIG. 2A, FIG. 21, FIG. 3A, and FIG. 3B, a respective pixel driving circuit is annotated with labels indicating regions corresponding to the plurality of transistors in the respective pixel driving circuit, including the first transistor T1, the second transistor T2, the third transistor T3, the fourth transistor T4, the fifth transistor T5, the sixth transistor T6, and the driving transistor Td. The respective pixel driving circuit is further annotated with labels indicating components of each of the plurality of transistors in the pixel driving circuit. For example, the first transistor T1 includes an active layer ACT1, a first electrode S1, and a second electrode D1. The second transistor T2 includes an active layer ACT2, a first electrode S2, and a second electrode D2. The third transistor T3 includes an active layer ACT3, a first electrode S3, and a second electrode D3. The fourth transistor T4 includes an active layer ACT4, a first electrode S4, and a second electrode D4. The fifth transistor T5 includes an active layer ACT5, a first electrode S5, and a second electrode D5. The sixth transistor T6 includes an active layer ACT6, a first electrode S6, and a second electrode D6. The driving transistor Td includes an active layer ACTd, a first electrode Sd, and a second electrode Dd. In one example, the active layers (ACT1, ACT2, ACT3, ACT4, ACT5, ACT6, and ACTd) of the transistors (T1, T2, T3, T4, T5, T6, and Td) in the respective pixel driving circuit are parts of a unitary structure. In another example, the active layers (ACT1, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) in the respective pixel driving circuit are parts of a unitary structure. In another example, the active layers (ACT1, ACT2, ACT3, ACT4, ACT5, ACT6, and ACTd) of the transistors (T1, T2, T3, T4, T5, T6, and Td) are in a same layer. In another example, the active layers (ACTT, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) are in a same layer.

As used herein, the active layer refers to a component of the transistor comprising at least a portion of the semiconductor material layer whose orthographic projection on the base substrate overlaps with an orthographic projection of a gate electrode on the base substrate. A first electrode refers to a component of the transistor connected to one side of the active layer, and a second electrode refers to a component of the transistor connected to another side of the active layer. In the context of a double-gate type transistor (for example, the third transistor T3), the active layer refers to a component of the transistor comprising a first portion of the semiconductor material layer whose orthographic projection on the base substrate overlaps with an orthographic projection of a first gate on the base substrate, a second portion of the semiconductor material layer whose orthographic projection on the base substrate overlaps with an orthographic projection of a second gate on the base substrate, and a third portion between the first portion and the second portion. In the context of a double-gate type transistor, a first electrode refers to a component of the transistor connected to a side of the first portion distal to the third portion, and a second electrode refers to a component of the transistor connected to a side of the second portion distal to the third portion.

Referring to FIG. 2A, FIG. 2B, FIG. 3A, and FIG. 3C, the first conductive layer in some embodiments includes a plurality of reset control signal lines rst, a plurality of light emitting control signal lines em, a plurality of gate signal lines GL, and a first capacitor electrode Ce1 of the storage capacitor Cst. Various appropriate electrode materials and various appropriate fabricating methods may be used to make the first conductive layer. For example, a conductive material may be deposited on the substrate by a plasma-enhanced chemical vapor deposition (PECVD) process and patterned. Examples of appropriate conductive materials for making the first conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of reset control signal lines rst, the plurality of light emitting control signal lines em, the plurality of gate signal lines GL, and the first capacitor electrode Ce1 of the storage capacitor Cst are in a same layer.

As used herein, the term “same layer” refers to the relationship between the layers simultaneously formed in the same step. In one example, the plurality of gate signal lines GL and the first capacitor electrode Ce1 are in a same layer when they are formed as a result of one or more steps of a same patterning process performed in a same layer of material. In another example, the plurality of gate signal lines GL and the first capacitor electrode Ce1 can be formed in a same layer by simultaneously performing the step of forming the plurality of gate signal lines GL, and the step of forming the first capacitor electrode Ce1. The term “same layer” does not always mean that the thickness of the layer or the height of the layer in a cross-sectional view is the same.

Referring to FIG. 2A, FIG. 28, FIG. 3A, and FIG. 3D, the second conductive layer in some embodiments includes a plurality of initialization signal lines Vint and a second capacitor electrode Ce2 of the storage capacitor Cst. Various appropriate conductive materials and various appropriate fabricating methods may be used to make the second conductive layer. For example, a conductive material may be deposited on the substrate by a plasma-enhanced chemical vapor deposition (PECVD) process and patterned. Examples of appropriate conductive materials for making the second conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of initialization signal lines Vim and the second capacitor electrode Ce2 of the storage capacitor Cst are in a same layer.

Vias extending through the inter-layer dielectric layer ILD are depicted in FIG. 3E.

Referring to FIG. 2A, FIG. 2B, FIG. 3A, and FIG. 3F, the first signal line layer in some embodiments includes a node connecting line C1n, a voltage connecting pad VCP, a data signal connecting pad DCP, an electrode connecting line Cle, and a reset signal connecting line Cli. Various appropriate conductive materials and various appropriate fabricating methods may be used to make the first signal line layer. For example, a conductive material may be deposited on the substrate by a plasma-enhanced chemical vapor deposition (PECVD) process and patterned. Examples of appropriate conductive materials for making the first signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first signal line layer includes a plurality of sub-layers stacked together. In one example, the first signal line layer includes a stacked titanium/aluminum/titanium multi-layer structure. In another example, the first signal line layer includes a stacked molybdenum/aluminum/molybdenum multi-layer structure. Optionally, the node connecting line C1n, the voltage connecting pad VCP, the data signal connecting pad DCP, the electrode connecting line Cle, and the reset signal connecting line Cli are in a same layer.

The node connecting line C1n is connected to the first capacitor electrode Ce1, and is connected to the second electrode of the third transistor T3 and/or the second electrode of the first transistor T1 in a respective pixel driving circuit. The data signal connecting pad DCP connects a respective data line of the plurality of data lines with a first electrode of the second transistor T2. The reset signal connecting line Cli connects a respective initialization signal line of the plurality of initialization signal lines with first electrodes of the first transistor T1 and the sixth transistor T6. The voltage connecting pad VCP connects a respective voltage supply line of the plurality of voltage supply lines with a first electrode of the fourth transistor T4, and connects the respective voltage supply line of the plurality of voltage supply lines with the second capacitor electrode of the storage capacitor. The electrode connecting line Cle is connected to second electrodes of the fifth transistor T5 and the sixth transistor T6, respectively.

Vias extending through the passivation layer PVX are depicted in FIG. 3G.

Referring to FIG. 2A, FIG. 21, FIG. 3A, and FIG. 3H, the second signal line layer in some embodiments includes a plurality of voltage supply lines Vdd and a plurality of data line DL. A respective voltage supply line of the plurality of voltage supply lines Vdd includes a plurality of first voltage supply line portions Vdd-1 and a plurality of second voltage supply line portions Vdd-2 alternately arranged. A respective first voltage supply line portion of the plurality of first voltage supply line portions Vdd-1 and a respective second voltage supply line portion of the plurality of second voltage supply line portions Vdd-2 are connected by a voltage connecting bridge in the third signal line layer. A respective data line of the plurality of data lines is electrically connected to a first electrode of the second transistor T2 through a data signal connecting pad in the first signal line layer.

Various appropriate conductive materials and various appropriate fabricating methods may be used to make the second signal line layer. For example, a conductive material may be deposited on the substrate by a plasma-enhanced chemical vapor deposition (PECVD) process and patterned. Examples of appropriate conductive materials for making the second signal line layer include, but are not limited to, substantially transparent conductive materials such as metal oxide conductive materials. In one example, the second signal line layer includes indium tin oxide. Optionally, the plurality of voltage supply lines Vdd and the plurality of data line DL are in a same layer. As used herein, the term “substantially transparent” means at least 50 percent (e.g., at least 60 percent, at least 70 percent, at least 80 percent, at least 90 percent, and at least 95 percent) of an incident light in the visible wavelength range transmitted therethrough.

Vias extending through the first planarization layer PLN1 are depicted in FIG. 3I.

Referring to FIG. 2A, FIG. 2B, FIG. 3A, and FIG. 3J, the third signal line layer in some embodiments includes a voltage connecting bridge VCB and an anode connecting pad ACP. The voltage connecting bridge VCB connects the first voltage supply line portion in the second signal line layer with the second voltage supply line portion in the second signal line layer. The anode connecting pad ACP is connected to the fourth node N4 and a respective anode in a respective subpixel, respectively. The anode connecting pad ACP is connected to second electrodes of the fifth transistor T5 and the sixth transistor T6, and the respective anode in the respective subpixel is connected to the anode connecting pad ACP.

Various appropriate conductive materials and various appropriate fabricating methods may be used to make the third signal line layer. For example, a conductive material may be deposited on the substrate by a plasma-enhanced chemical vapor deposition (PECVD) process and patterned. Examples of appropriate conductive materials for making the third signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like, in some embodiments, the second signal line layer includes a plurality of sub-layers stacked together. In one example, the second signal line layer includes a stacked titanium/aluminum/titanium multi-layer structure. In another example, the second signal line layer includes a stacked molybdenum/aluminum/molybdenum multi-layer structure. Optionally, the voltage connecting bridge VCB and the anode connecting pad ACP are in a same layer.

Vias extending through the second planarization layer PLN2 are depicted in FIG. 3K.

Referring to FIG. 2A, FIG. 2B, FIG. 3A, and FIG. 3L, the anode layer in some embodiments includes an anode of the respective light emitting elements. The anode connects to the anode connecting pad in the third signal line layer, the anode connecting pad connects to second electrodes of the fifth transistor T5 and the sixth transistor T6.

Vias extending through the pixel definition layer PDL are depicted in FIG. 3M. Referring to FIG. 3M, the array substrate includes a subpixel aperture SA configured to receive a light emitting material.

Referring to FIG. 2A, FIG. 2B, FIG. 3A to FIG. 3M, and FIG. 4, in some embodiments, the first capacitor electrode Ce1 is on a side of the gate insulating layer G1 away from the base substrate BS. In some embodiments, the array substrate further includes a first via v1 and a second via v2. The first via v1 extends through the inter-layer dielectric layer ILD and the insulating layer IN. The second via v2 extends through the inter-layer dielectric layer ILD, the insulating layer IN, and the gate insulating layer G1. Optionally, the node connecting line C1n is connected to the first capacitor electrode Ce1 through the first via v1, and the node connecting line C1n is connected to the semiconductor material layer SML through the second via v2. Optionally, the node connecting line C1n is connected to the second electrode D3 of third transistor and/or the second electrode D1 of the first transistor, as depicted in FIG. 4.

In some embodiments, the array substrate further includes a third via v3 and a fourth via v4. The voltage connecting bridge VCB is connected to the respective first voltage supply line portion of the plurality of first voltage supply line portions Vdd-1 through the third via v3, and is connected to the respective second voltage supply line portion of the plurality of second voltage supply line portions Vdd-2 through the fourth via v4. In one example, the third via v3 extends through the first planarization layer PLN1. In another example, the fourth via v4 extends through the first planarization layer PLN1.

In some embodiments, the array substrate further includes a fifth via v5. The respective voltage supply line (e.g., the respective second voltage supply line portion of the plurality of second voltage supply line portions Vdd-2 of the respective voltage supply line) is connected to the voltage connecting pad VCP through the fifth via v5. In one example, the fifth via v5 extends through the passivation layer PVX.

In some embodiments, the array substrate further includes a sixth via v6. The voltage connecting pad VCP is connected to a first electrode S4 of the fourth transistor T4 through the sixth via v6, thereby providing a voltage supply signal to the first electrode S4 of the fourth transistor T4. In one example, the sixth via v6 extends through the inter-layer dielectric layer ILD, the insulating layer IN, and the gate insulating layer G1.

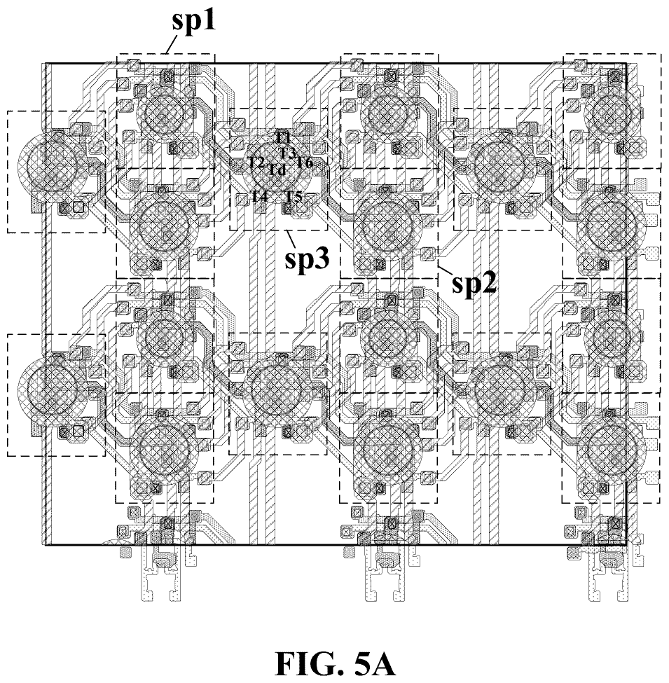

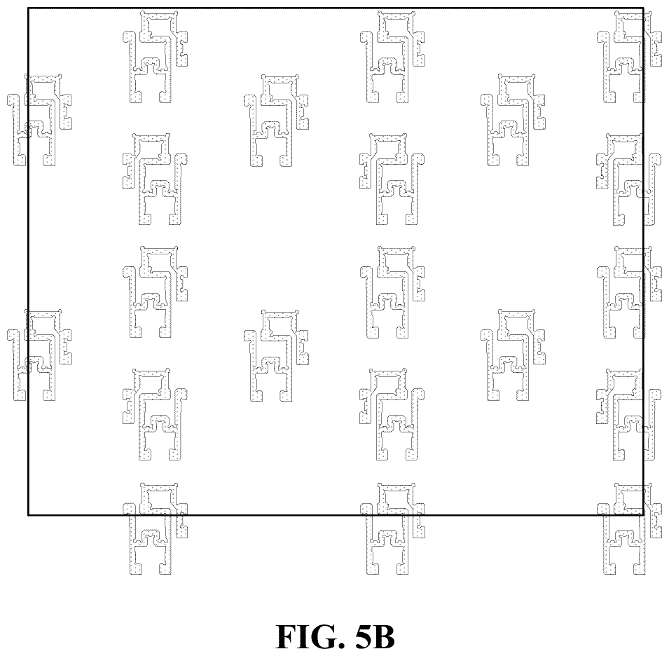

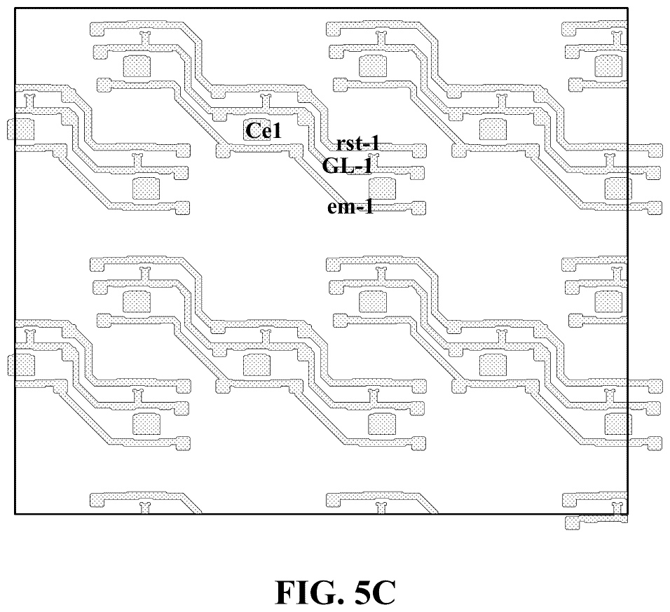

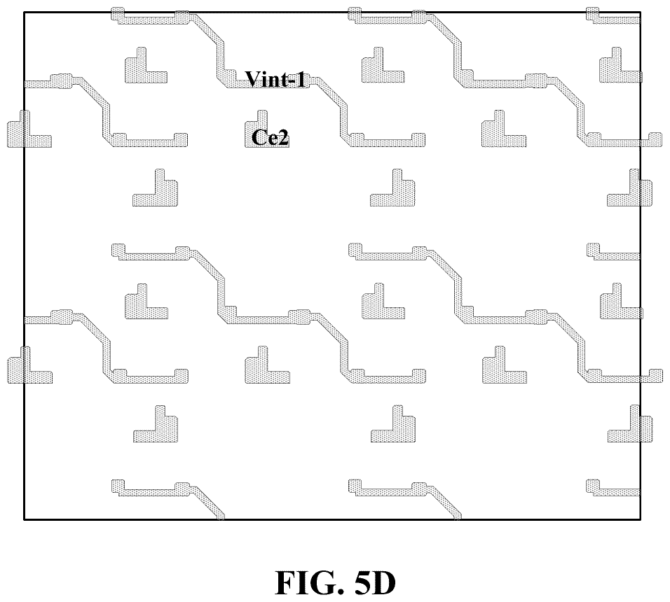

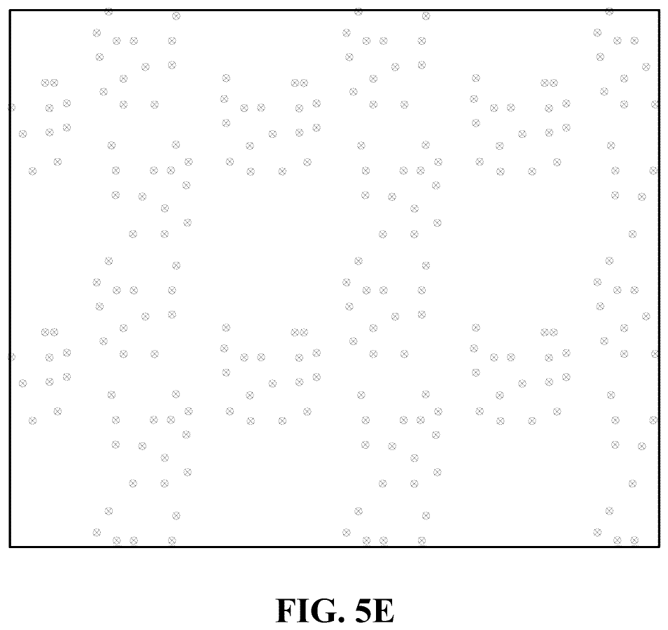

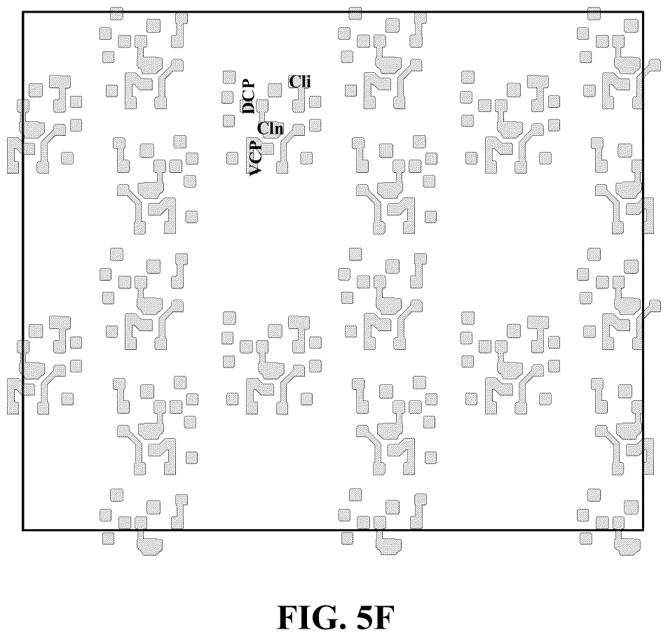

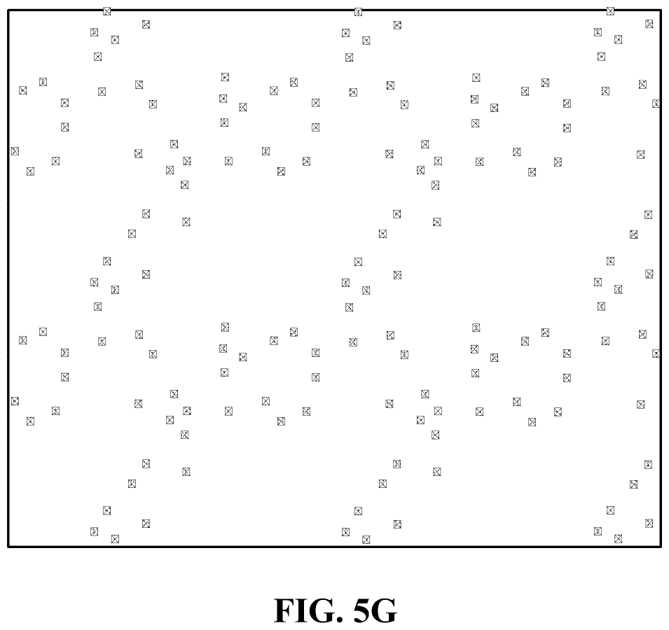

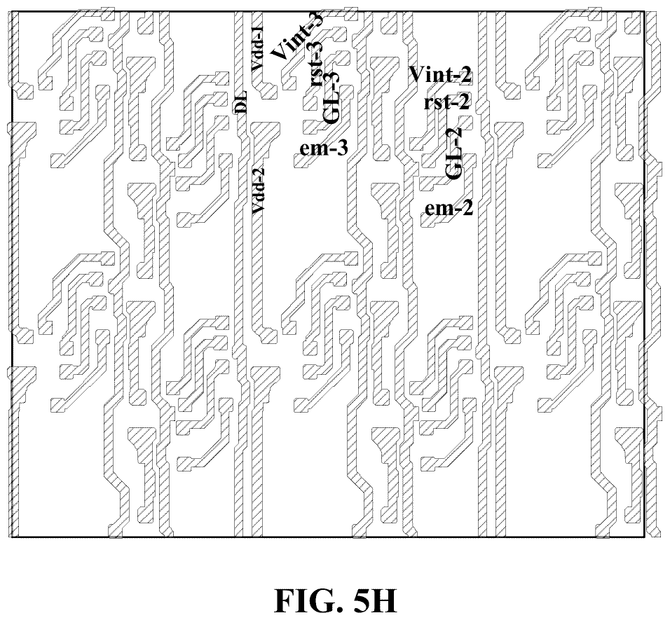

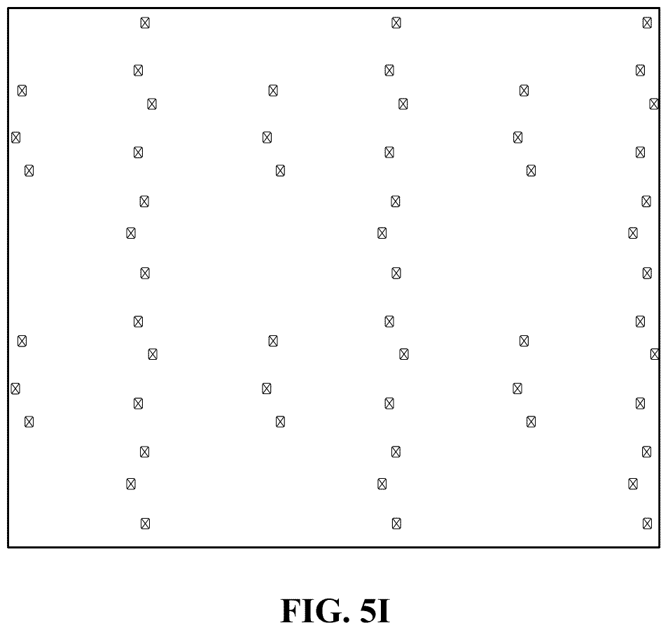

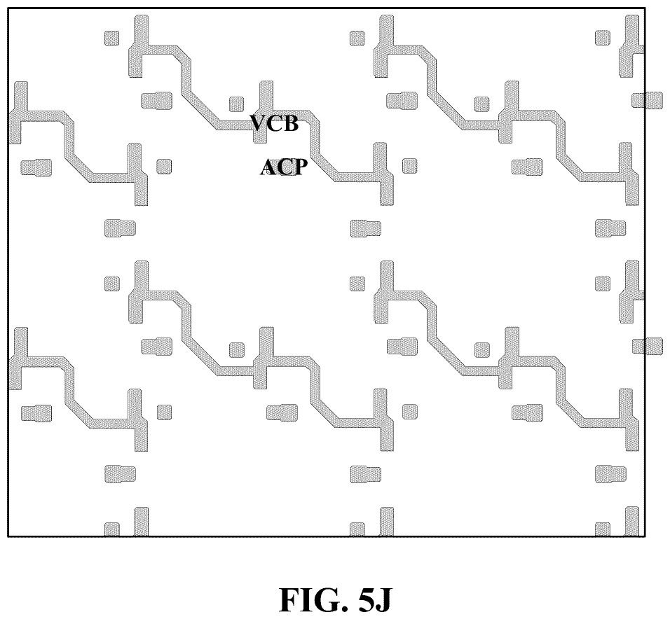

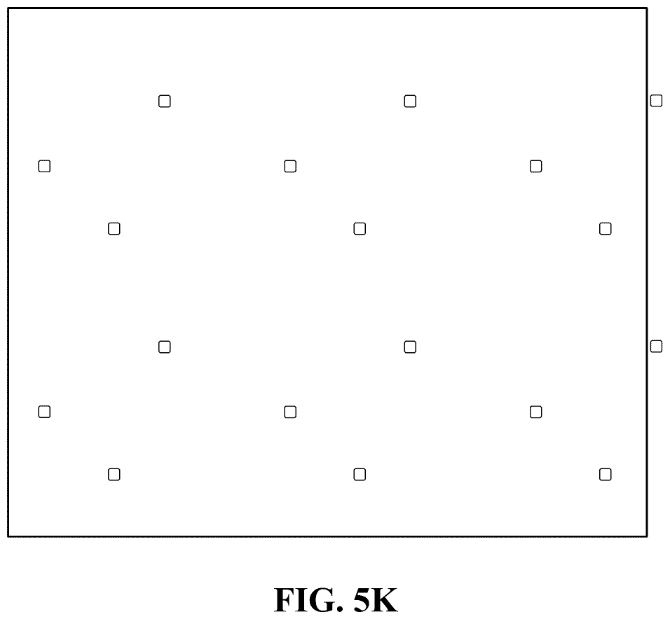

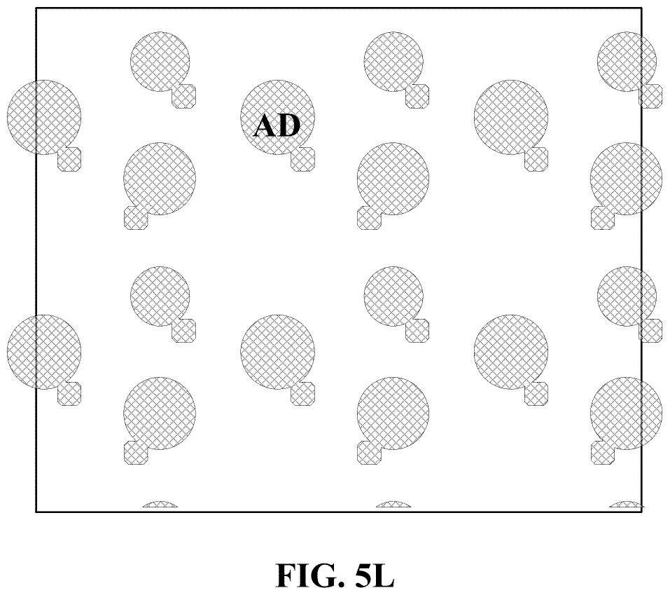

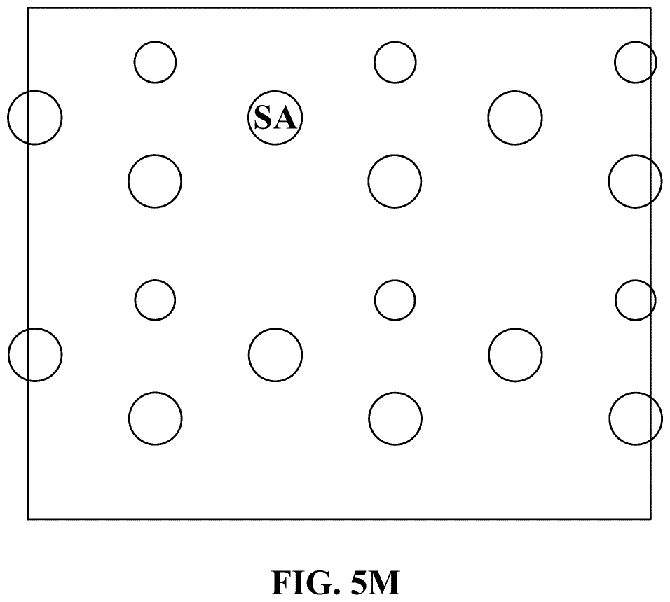

FIG. 5A is a diagram illustrating the structure of a portion of an array substrate in some embodiments according to the present disclosure. FIG. 5B is a diagram illustrating the structure of a semiconductor material layer in the portion of the array substrate depicted in FIG. 5A. FIG. 5C is a diagram illustrating the structure of a first conductive layer in the portion of the array substrate depicted in FIG. 5A. FIG. 5D is a diagram illustrating the structure of a second conductive layer in the portion of the array substrate depicted in FIG. 5A. FIG. 5E is a diagram illustrating the structure of an inter-layer dielectric layer in the portion of the array substrate depicted in FIG. 5A. FIG. 5F is a diagram illustrating the structure of a first signal line layer in the portion of the array substrate depicted in FIG. 3A. FIG. 5G is a diagram illustrating the structure of a passivation layer in the portion of the array substrate depicted in FIG. 5A. FIG. 5H is a diagram illustrating the structure of a second signal line layer in the portion of the array substrate depicted in FIG. 5A. FIG. 5I is a diagram illustrating the structure of a first planarization layer in the portion of the array substrate depicted in FIG. 5A. FIG. 5J is a diagram illustrating the structure of a third signal line layer in the portion of the array substrate depicted in FIG. 5A. FIG. 5K is a diagram illustrating the structure of a second planarization layer in the portion of the array substrate depicted in FIG. 5A. FIG. 5L is a diagram illustrating the structure of an anode layer in the portion of the array substrate depicted in FIG. 5A. FIG. 5M is a diagram illustrating the structure of a pixel definition layer in the portion of the array substrate depicted in FIG. 5A.

In some embodiments, referring to FIG. 5A, a minimum repeating unit of the plurality of subpixels of the array substrate includes a respective first subpixel sp1, a respective second subpixel sp2, and a respective third subpixel sp3. The portion of the array substrate depicted in FIG. 3A corresponds to a portion of the respective third subpixel sp3 depicted in FIG. 5A.

In some embodiments, each of the respective first subpixel sp1, the respective second subpixel sp2, and the respective third subpixel sp3, includes the first transistor T1, the second transistor T2, the third transistor T3, the fourth transistor T4, the fifth transistor T5, the sixth transistor T6, the driving transistor Td, and the storage capacitor Cst.

In some embodiments, the respective first subpixel sp1 is a subpixel of a first color (e.g., a red color), the respective second subpixel sp2 is a subpixel of a second color (e.g., a green color), and the respective third subpixel sp3 is a subpixel of a third color (e.g., a blue color). In some embodiments, the respective first subpixel sp1, the respective second subpixel sp2, and the respective third subpixel sp3 are three subpixels of a pixel in the array substrate.

Referring to FIG. 5A, FIG. 5H, and FIG. 5J, in some embodiments, a respective voltage supply line of the plurality of voltage supply lines Vdd includes a plurality of first voltage supply line portions Vdd-1 and a plurality of second voltage supply line portions Vdd-2 alternately arranged in the second signal line layer. A respective first voltage supply line portion of the plurality of first voltage supply line portions Vdd-1 and a respective second voltage supply line portion of the plurality of second voltage supply line portions Vdd-2 are connected by a voltage connecting bridge VCB in the third signal line layer.

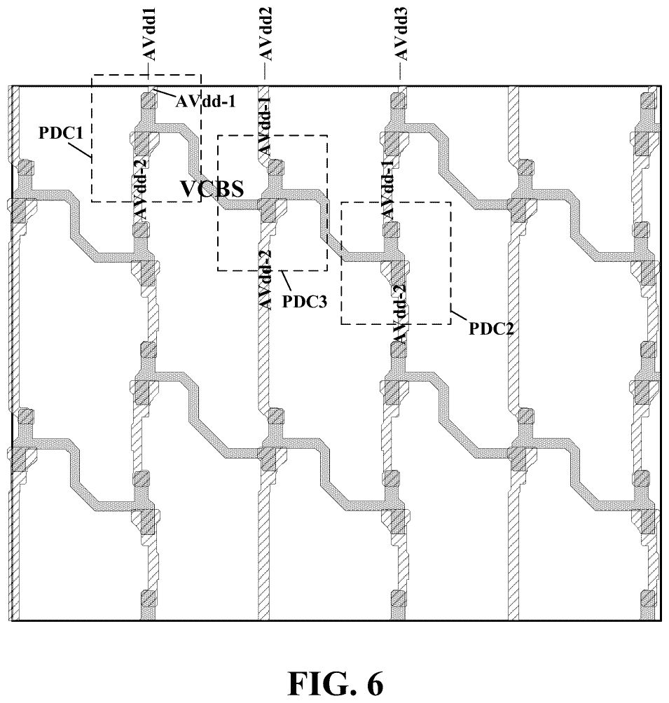

FIG. 6 is a diagram illustrating a voltage supply network in a portion of an array substrate in some embodiments according to the present disclosure. Referring to FIG. 5A, FIG. 511, FIG. 5J, and FIG. 6, the array substrate in some embodiments includes a plurality of voltage connecting bridges VCBS. Optionally, the plurality of voltage connecting bridges VCBS are arranged in an array of rows and columns. The plurality of voltage supply lines Vdd includes a first adjacent voltage supply line AVdd1, a second adjacent voltage supply line AVdd2, and a third adjacent voltage supply line AVdd3. Optionally, the first adjacent voltage supply line AVdd1 is configured to provide a voltage supply signal to a first pixel driving circuit PDC1 in the respective first subpixel Sp1, the second adjacent voltage supply line AVdd2 is configured to provide a voltage supply signal to a second pixel driving circuit PDC2 in the respective second subpixel Sp2, and the third adjacent voltage supply line AVdd3 is configured to provide a voltage supply signal to a third pixel driving circuit PDC3 in the respective third subpixel Sp3.

In some embodiments, a respective voltage connecting bridge of the plurality of voltage connecting bridges VCBS is connected to the first adjacent voltage supply line AVdd1, the second adjacent voltage supply line AVdd2, and the third adjacent voltage supply line AVdd3, respectively.

In some embodiments, each of the first adjacent voltage supply line AVdd1, the second adjacent voltage supply line AVdd2, and the third adjacent voltage supply line AVdd3 includes a plurality of first voltage supply line portions Vdd-1 and a plurality of second voltage supply line portions Vdd-2 alternately arranged in the second signal line layer. In some embodiments, the respective voltage connecting bridge of the plurality of voltage connecting bridges VCBS is connected to a first adjacent voltage supply line portion AVdd-1 and a second adjacent voltage supply line portion AVdd-2 of the first adjacent voltage supply line AVdd1, respectively, is connected to a first adjacent voltage supply line portion AVdd-1 and a second adjacent voltage supply line portion AVdd-2 of the second adjacent voltage supply line AVdd2, respectively, and is connected to a first adjacent voltage supply line portion AVdd-1 and a second adjacent voltage supply line portion AVdd-2 of third adjacent voltage supply line AVdd3, respectively.

In some embodiments, the plurality of voltage supply lines (including the first adjacent voltage supply line AVdd1, the second adjacent voltage supply line AVdd2, and the third adjacent voltage supply line AVdd3) are in the second signal line layer, and the plurality of voltage connecting bridges VCBS are in the third signal line layer.

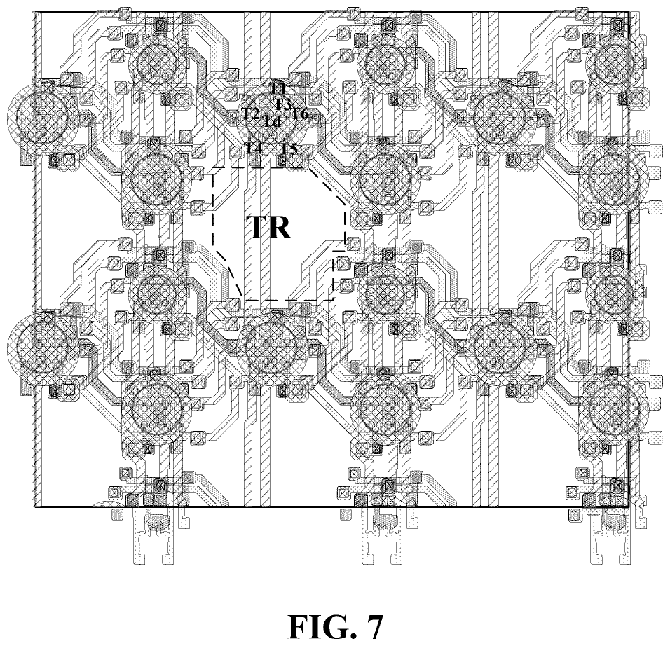

In some embodiments, signal lines in the second signal line layer are made of a substantially transparent conductive material, allowing the presence of a plurality of light transmissive regions in the array substrate. FIG. 7 is a diagram illustrating the structure of a portion of an array substrate in some embodiments according to the present disclosure. Referring to FIG. 7, the array substrate in some embodiments includes a plurality of light transmissive regions TR allowing light transmit therethrough. In the plurality of light transmissive regions TR, signal lines of the second signal line layer (e.g., the plurality of data lines, the plurality of first voltage supply line portions, and the plurality of second voltage supply line portions) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

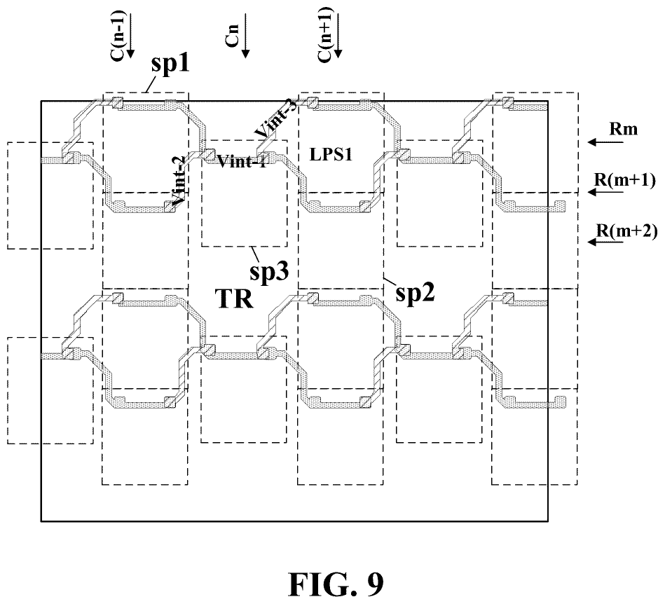

In some embodiments, two adjacent voltage connecting bridges of the plurality of voltage connecting bridges VCBS in a same pixel row are connected to a same voltage supply line of the plurality of voltage supply lines, as shown in FIG. 6. Referring to FIG. 9, a pixel row in some embodiments includes an m-th row of subpixels Rm, a (m+1)-th row of subpixels R(m+1), and a (m+2)-th row of subpixels R(m+2).

In some embodiments, voltage connecting bridges of the plurality of voltage connecting bridges VCBS in a same pixel column are connected to the same three adjacent voltage supply lines of the plurality of voltage supply lines. Referring to FIG. 9, a pixel column in some embodiments includes a (n−1)-th column of subpixels C(n−1), an n-th column of subpixels Cn, and a (n−1)-th column of subpixels C(n+1).

In some embodiments, the array substrate is a full display with camera (FDC) array substrate, wherein the array substrate further includes photosensors in the plurality of light transmissive regions TR configured to detect light.

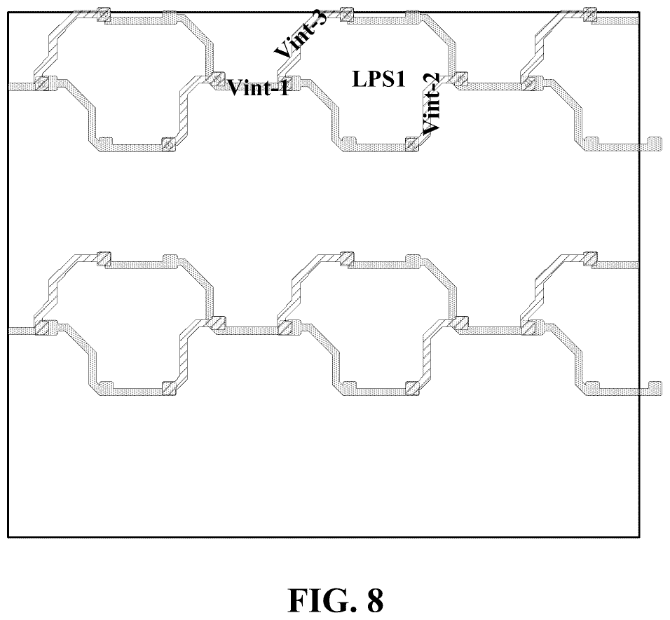

FIG. 8 is a diagram illustrating a reset signal network in a portion of an array substrate in some embodiments according to the present disclosure. Referring to FIG. 5A, FIG. 5D, FIG. 5H, and FIG. 8, a respective initialization signal line of the plurality of initialization signal lines includes a plurality of first initialization signal line portions Vint-1 and a plurality of second initialization signal line portions Vint-2. The plurality of first initialization signal line portions Vint-1 and the plurality of second initialization signal line portions Vint-2 are in two different layers. In one example, the plurality of first initialization signal line portions Vint-1 are in the second conductive layer, and the plurality of second initialization signal line portions Vint-2 are in the second signal line layer. A respective second initialization signal line portion of the plurality of second initialization signal line portions Vint-2 is connected to two adjacent first initialization signal line portions of the plurality of first initialization signal line portions Vint-1, respectively. Two adjacent first initialization signal line portions of the plurality of first initialization signal line portions Vint-1 are connected by an individual second initialization signal line portion of the plurality of second initialization signal line portions Vint-2.

In some embodiments, a respective initialization signal line of the plurality of initialization signal lines includes a plurality of first initialization signal line portions Vint-1 and a plurality of third initialization signal line portions Vint-3. The plurality of first initialization signal line portions Vint-1 and the plurality of third initialization signal line portions Vint-3 are in two different layers. In one example, the plurality of first initialization signal line portions Vint-1 are in the second conductive layer, and the plurality of third initialization signal line portions Vint-3 are in the second signal line layer. A respective third initialization signal line portion of the plurality of third initialization signal line portions Vint-3 is connected to two adjacent first initialization signal line portions of the plurality of first initialization signal line portions Vint-1 in the same row, respectively. Two adjacent first initialization signal line portions of the plurality of first initialization signal line portions Vint-1 are connected by an individual third initialization signal line portion of the plurality of third initialization signal line portions Vint-3.

In some embodiments, a respective initialization signal line of the plurality of initialization signal lines includes a plurality of first initialization signal line portions Vint-1, a plurality of second initialization signal line portions Vint-2, and a plurality of third initialization signal line portions Vint-3. The plurality of first initialization signal line portions Vint-1 and the plurality of second initialization signal line portions Vint-2 are in two different layers; and the plurality of first initialization signal line portions Vint-1 and the plurality of third initialization signal line portions Vint-3 are in two different layers. Optionally, the plurality of second initialization signal line portions Vint-2 and the plurality of third initialization signal line portions Vint-3 are in a same layer. In one example, the plurality of first initialization signal line portions Vint-1 are in the second conductive layer, the plurality of second initialization signal line portions Vint-2 are in the second signal line layer, and the plurality of third initialization signal line portions Vint-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second initialization signal line portions Vint-2, and the plurality of third initialization signal line portions Vint-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second initialization signal line portion of the plurality of second initialization signal line portions Vint-2 is connected to two adjacent first initialization signal line portions of the plurality of first initialization signal line portions Vint-1, respectively. A respective third initialization signal line portion of the plurality of third initialization signal line portions Vint-3 is connected to two adjacent first initialization signal line portions of the plurality of first initialization signal line portions Vint-1, respectively. Two adjacent first initialization signal line portions of the plurality of first initialization signal line portions Vint-1 are connected by an individual second initialization signal line portion of the plurality of second initialization signal line portions Vint-2, and connected by an individual third initialization signal line portion of the plurality of third initialization signal line portions Vint-3. The two adjacent first initialization signal line portions of the plurality of first initialization signal line portions Vint-1, the individual second initialization signal line portion of the plurality of second initialization signal line portions Vint-2, and the individual third initialization signal line portion of the plurality of third initialization signal line portions Vint-3 form a first loop substantially surrounding a region having transistors and capacitors of a pixel driving circuit of a subpixel. In one example, the first loop substantially surrounds a region having transistors and capacitors of a respective first subpixel. In another example, the first loop substantially surrounds a region having transistors and capacitors of a subpixel of a first color. In another example, the first loop substantially surrounds a region having transistors and capacitors of a red subpixel. As used herein, the term “substantially surround” refers to at least 50% surround, e.g., at least 55% surround, at least 60% surround, at least 65% surround, at least 70% surround, at least 75% surround, at least 80% surround, at least 85% surround, at least 90% surround, at least 95% surround, at least 99% surround, or 100% surround.

In some embodiments, the array substrate includes a plurality of first loops LPS1 sequentially arranged in a row. Optionally, the plurality of first loops LPS1 substantially surround regions of pixel driving circuits of subpixels of a same color, respectively. A respective first loop of the plurality of first loops LPS1 substantially surrounds a region of a pixel driving circuit of a subpixel of the same color. In one example, the plurality of first loops LPS1 substantially surround regions of pixel driving circuits of red subpixels.

In some embodiments, the plurality of first loops LPS1 substantially surround regions having anodes of subpixels of a same color, respectively. A respective first loop of the plurality of first loops LPS1 substantially surrounds a region having an anode of a subpixel of the same color. In one example, the plurality of first loops LPS1 substantially surround regions having anodes of red subpixels.

FIG. 9 is a diagram illustrating a reset signal network in a portion of an array substrate in some embodiments according to the present disclosure. In some embodiments, referring to FIG. 9, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 9.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 3A to FIG. 3M, FIG. 5A to FIG. 5M, and FIG. 9, a first initialization signal line portion of the plurality of first initialization signal line portions Vint-1 in some embodiments is connected to first electrodes of one or more reset transistors in a pixel driving circuit in a third subpixel in the n-th column of subpixels Cn and the (m+1)-th row of subpixels R(m+1), is connected to first electrodes of one or more reset transistors in a pixel driving circuit in a first subpixel in the (n−1)-th column of subpixels C(n−1) and the m-th row of subpixels Rm, and is connected to first electrodes of one or more reset transistors in a pixel driving circuit in a second subpixel in the (n+1)-th column of subpixels C(n+1) and the (m+2)-th row of subpixels R(m+2).

In some embodiments, a second initialization signal line portion of the plurality of second initialization signal line portions Vint-2 connects the first initialization signal line portion with a first adjacent first initialization signal line portion, the first adjacent first initialization signal line portion is connected to first electrodes of one or more reset transistors in a pixel driving circuit in a second subpixel in the (n−1)-th column of subpixels C(n−1) and the (m+2)-th row of subpixels R(m+2).

In some embodiments, a third initialization signal line portion of the plurality of third initialization signal line portions Vint-3 connects the first initialization signal line portion with a second adjacent first initialization signal line portion, the second adjacent first initialization signal line portion is connected to first electrodes of one or more reset transistors in a pixel driving circuit in a first subpixel in the (n+1)-th column of subpixels C(n+1) and the m-th row of subpixels Rm.

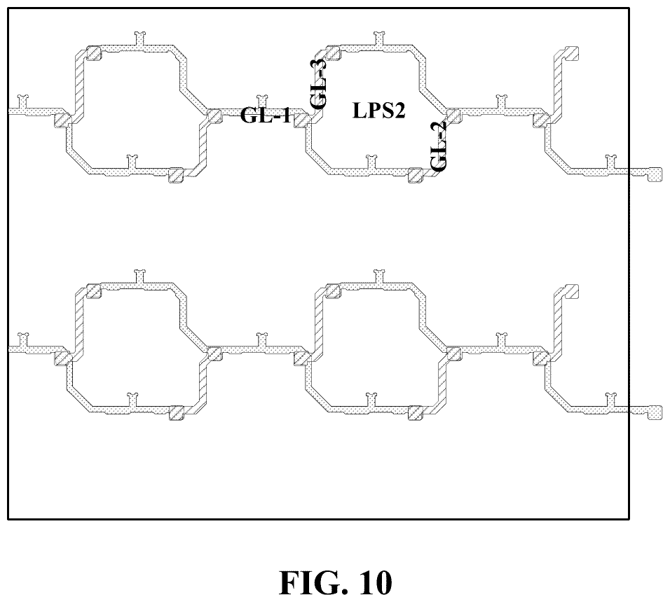

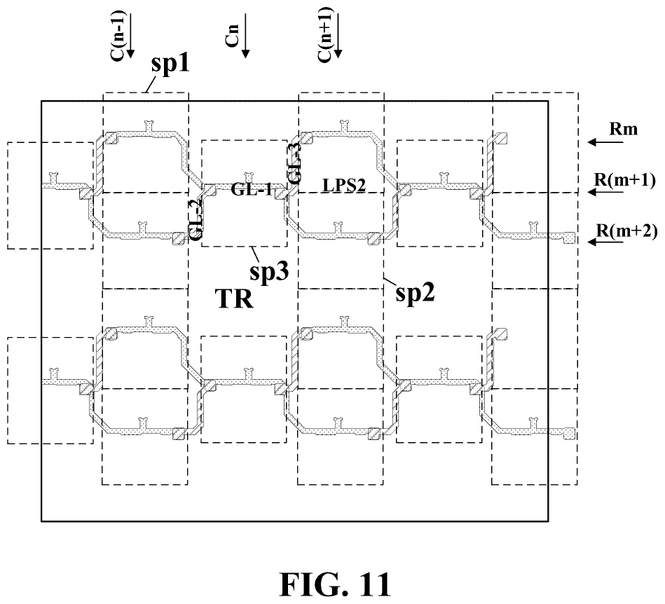

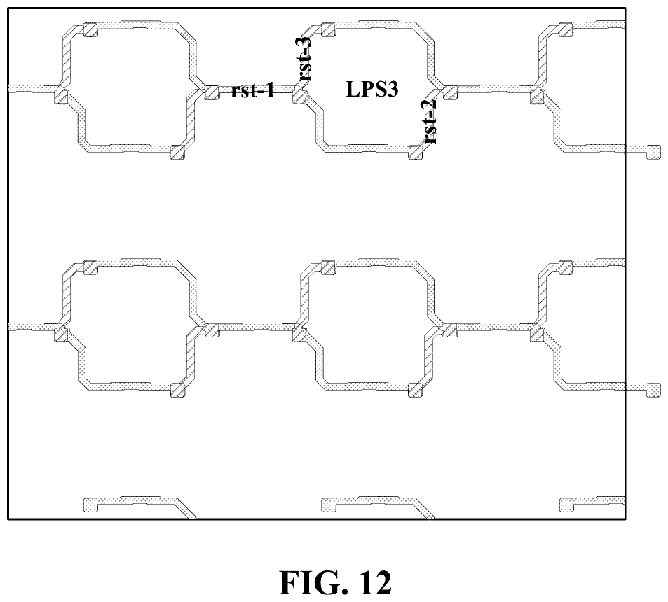

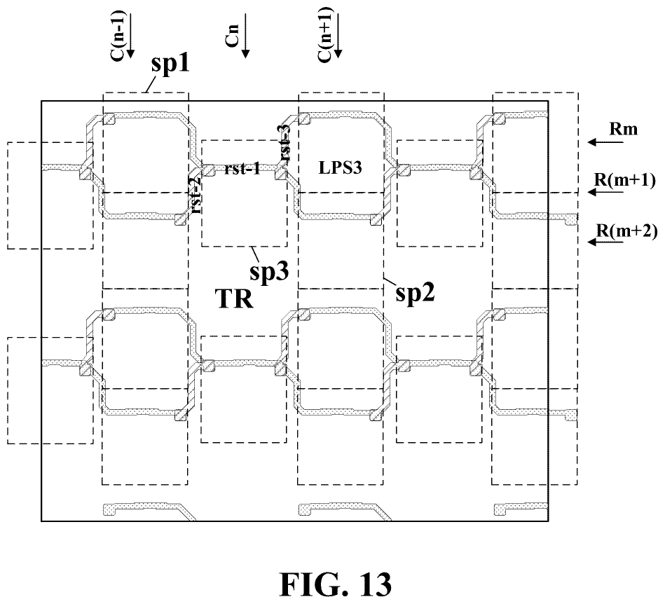

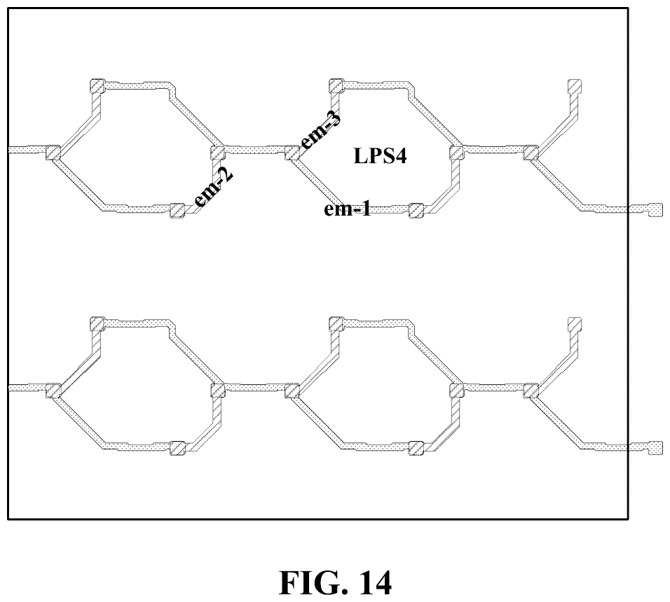

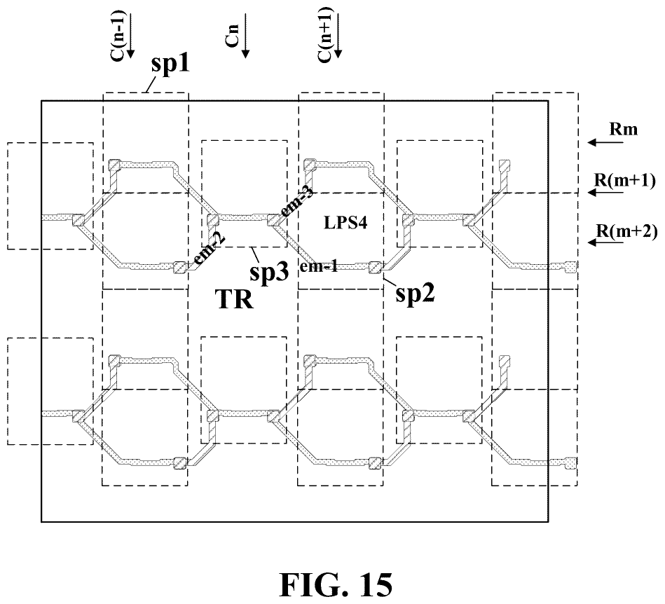

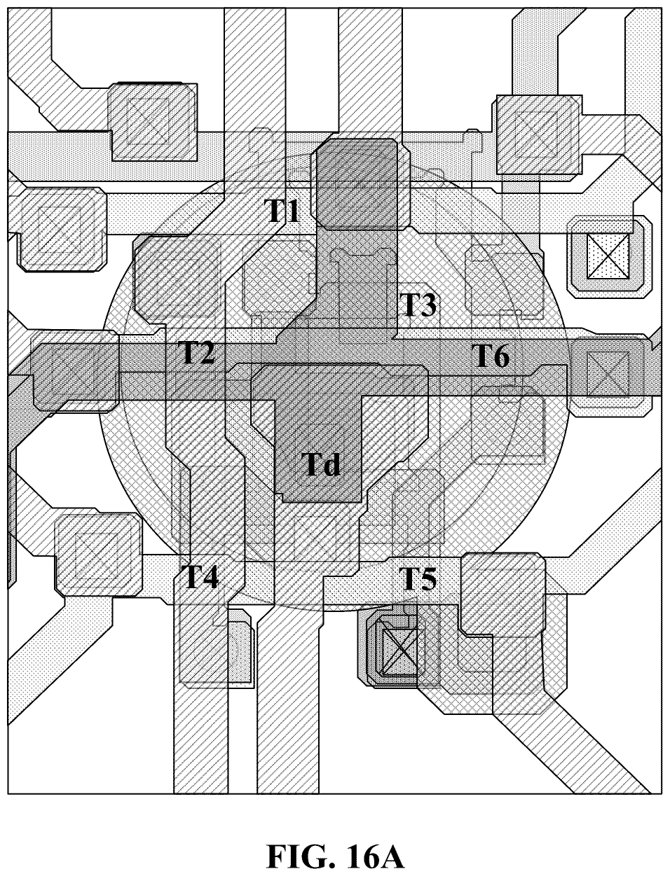

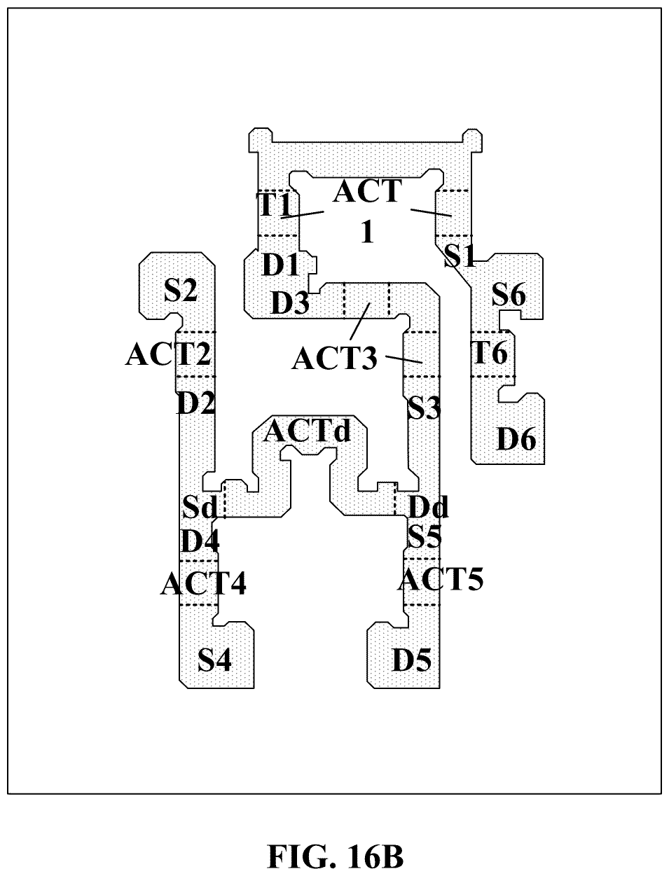

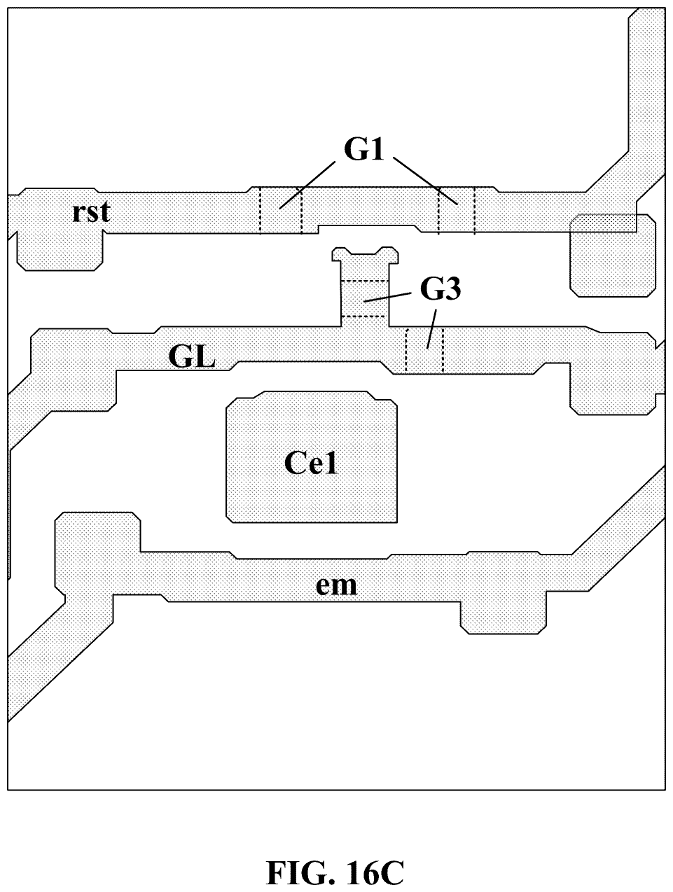

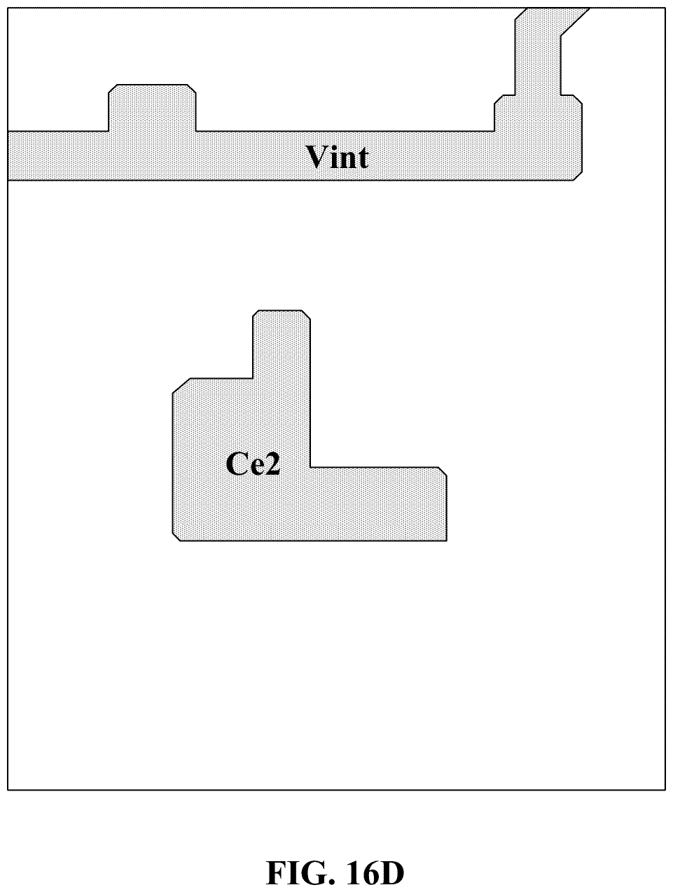

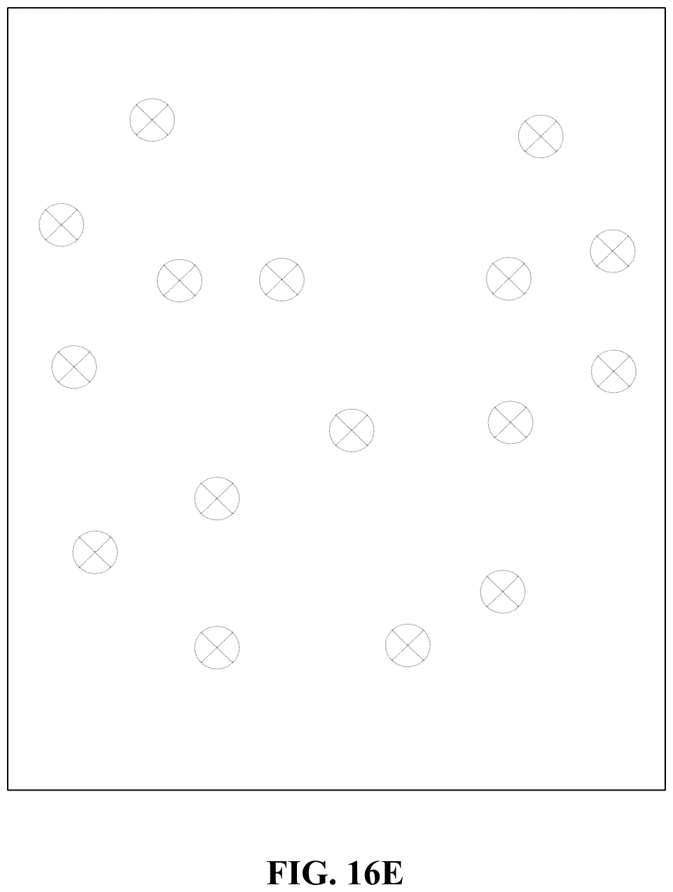

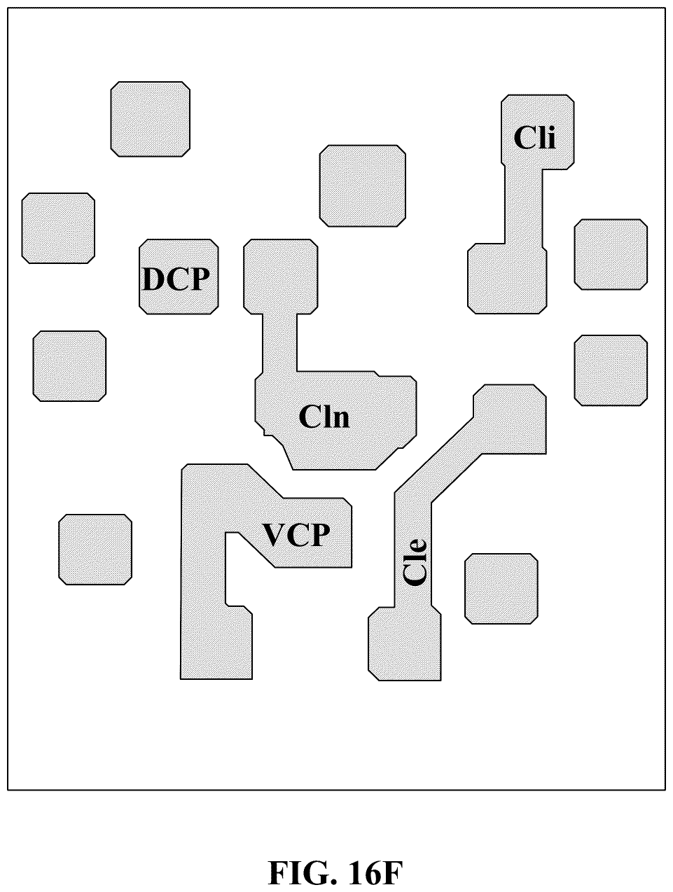

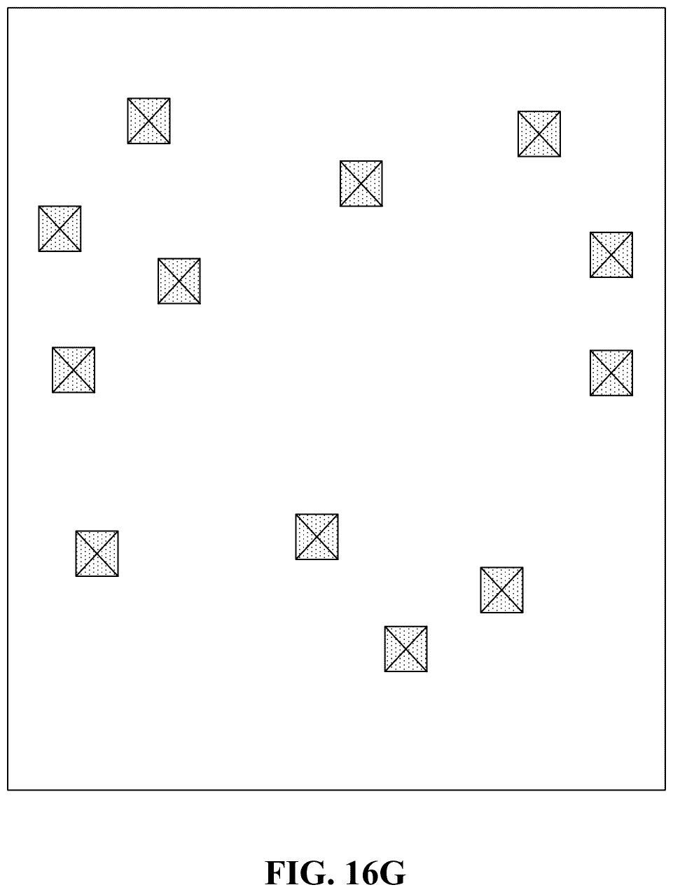

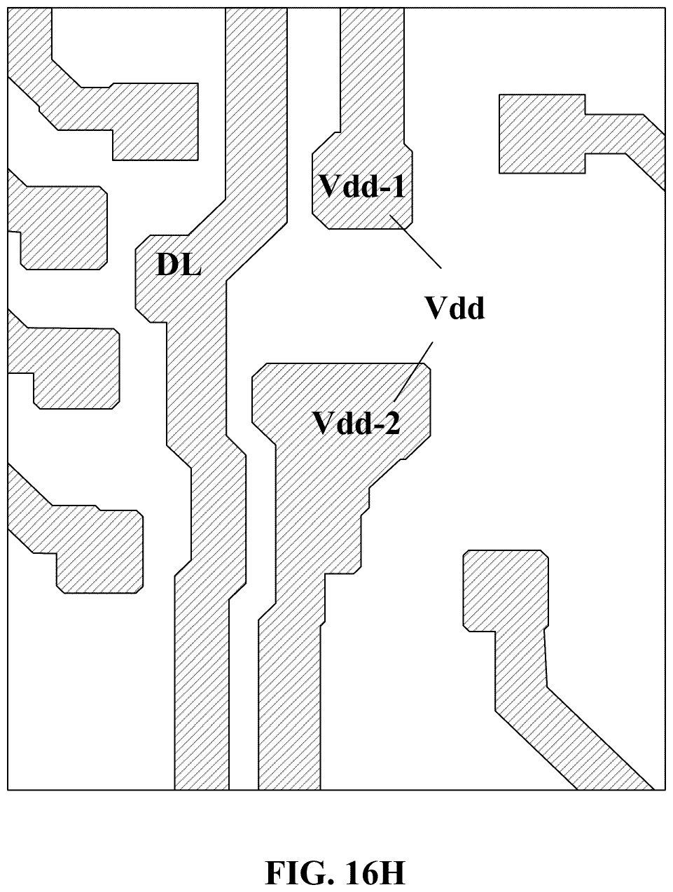

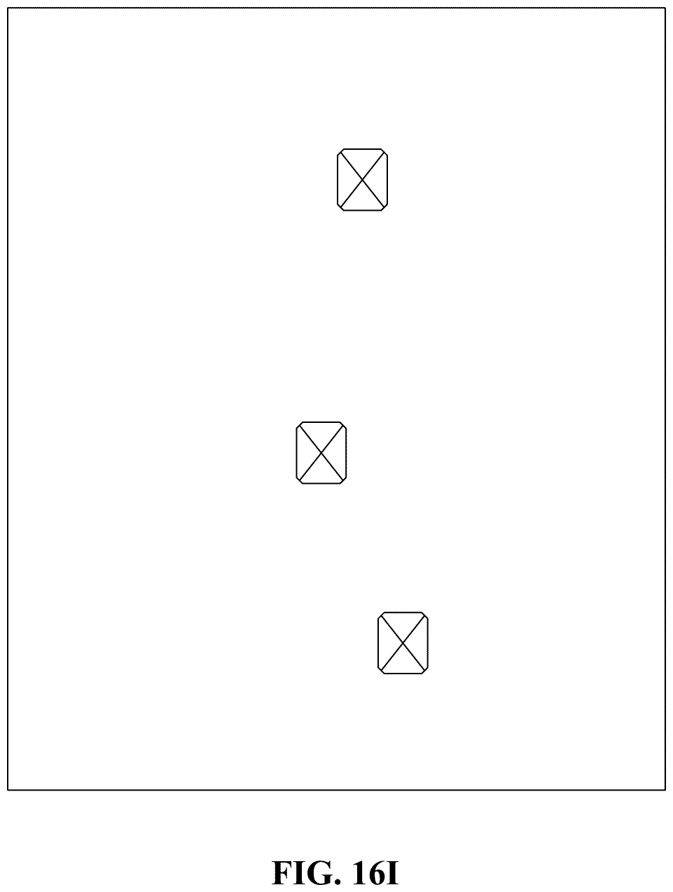

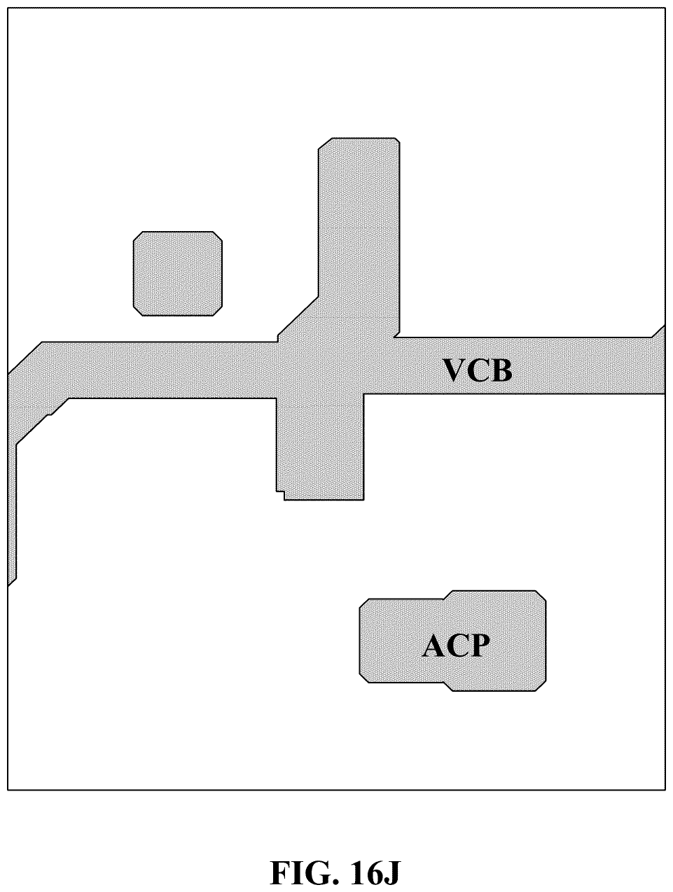

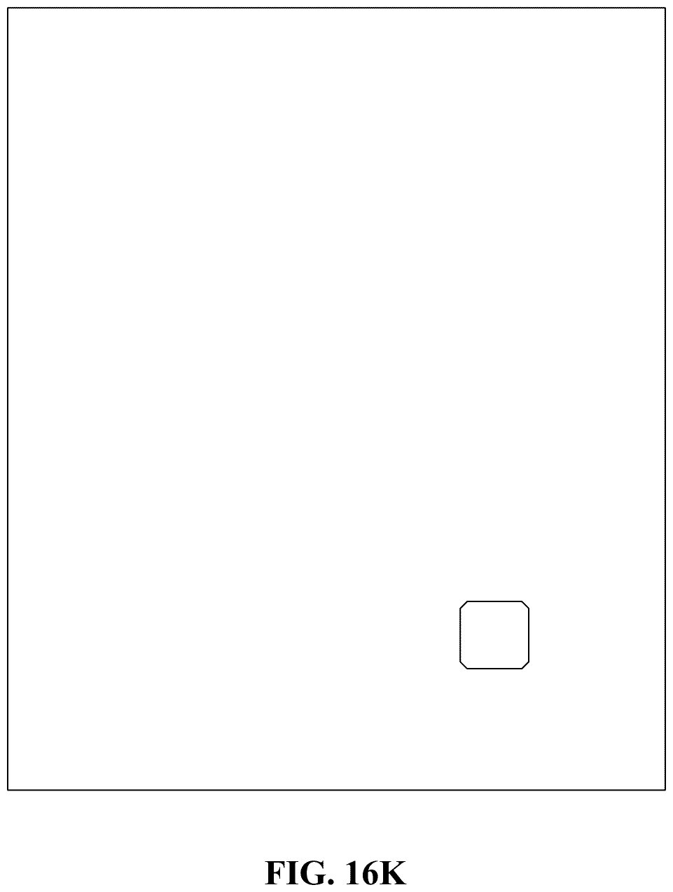

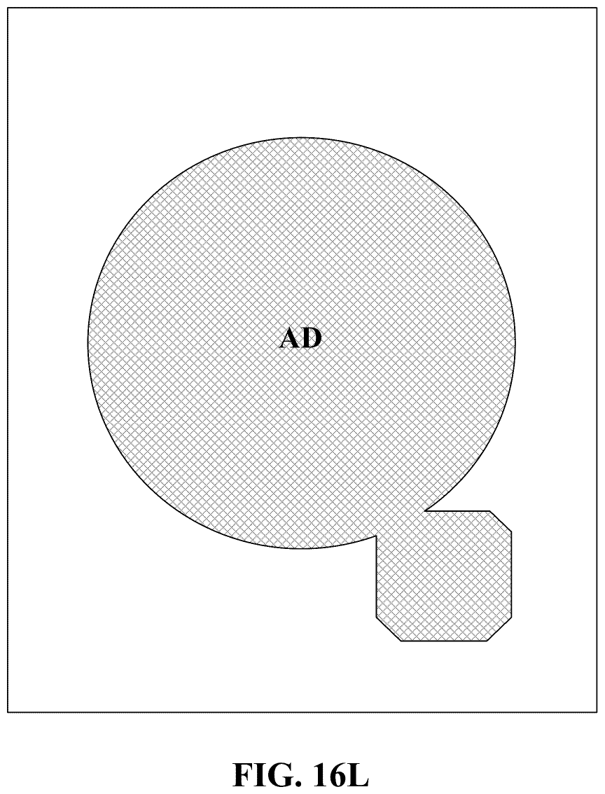

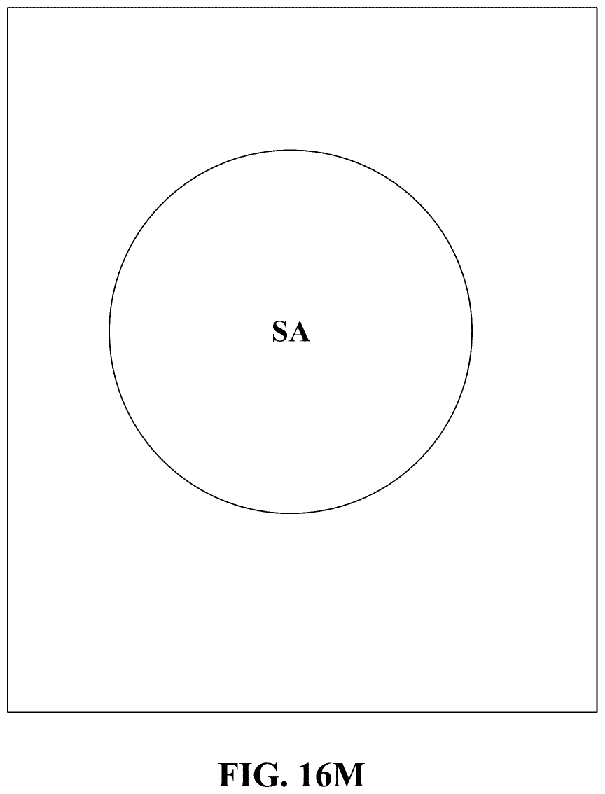

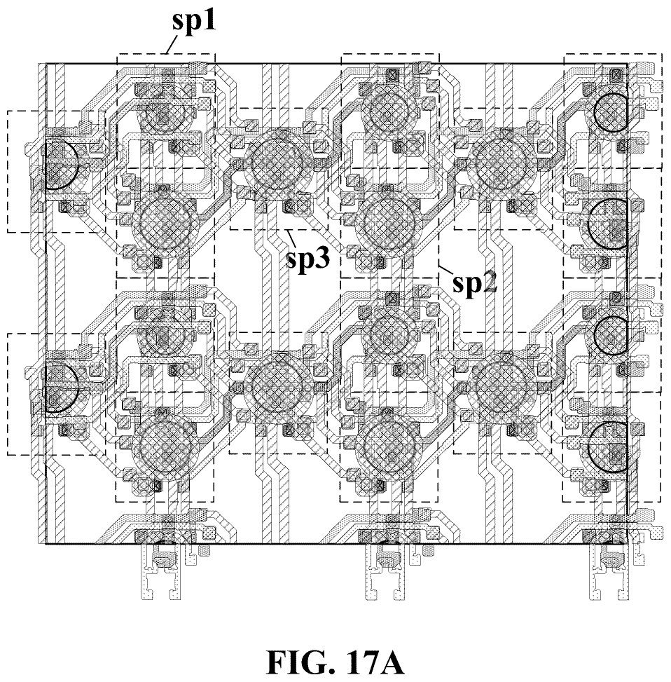

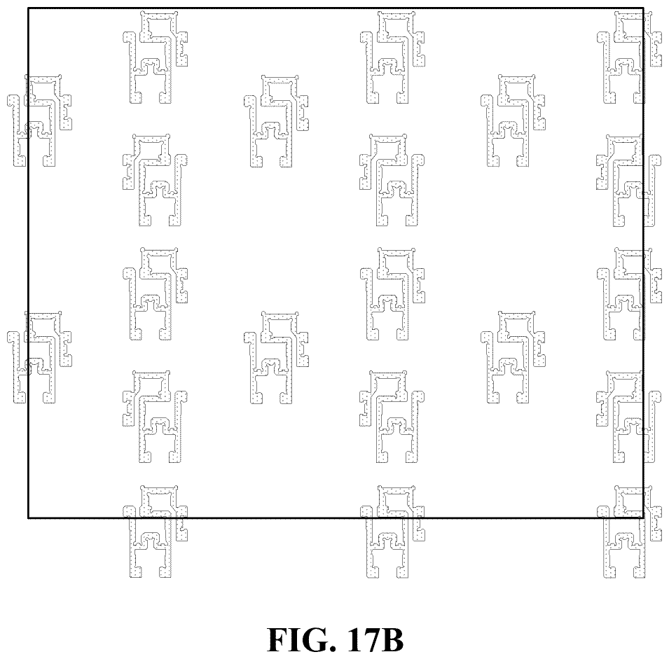

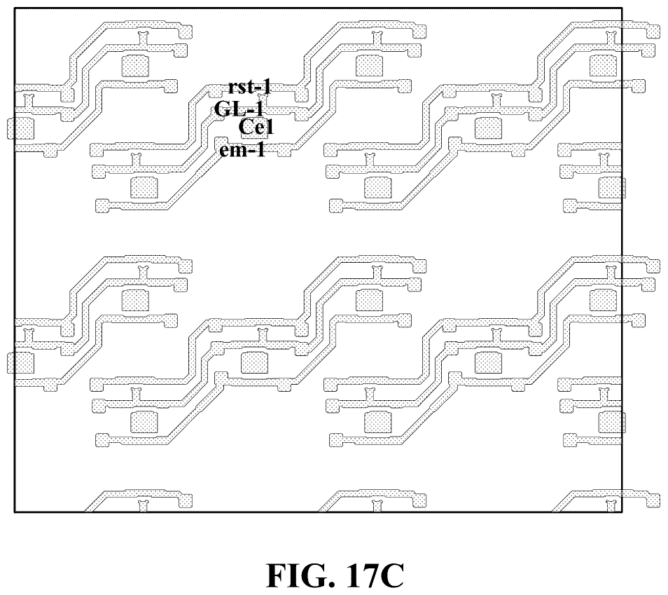

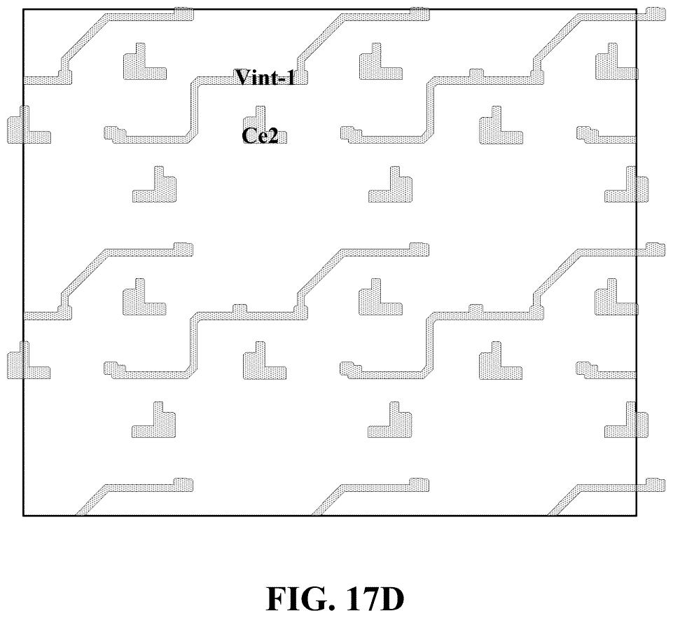

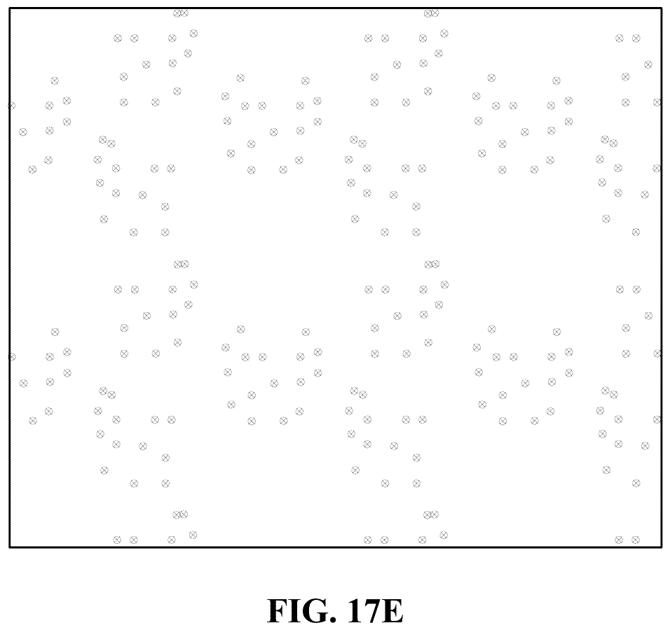

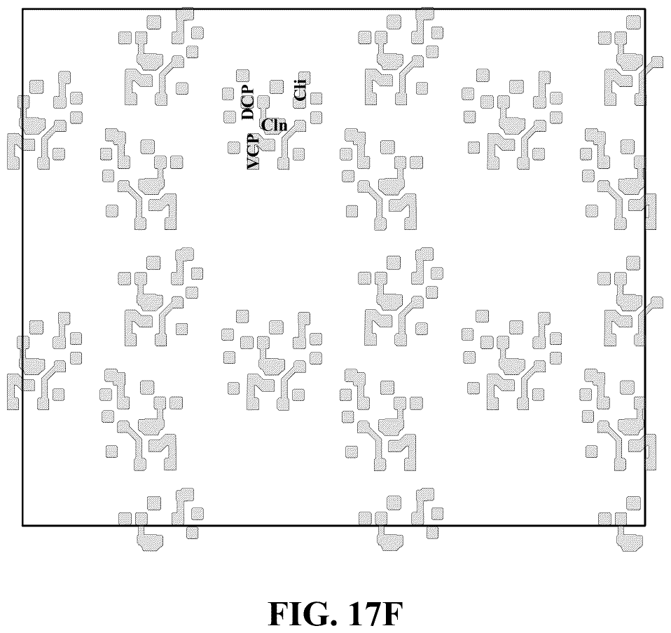

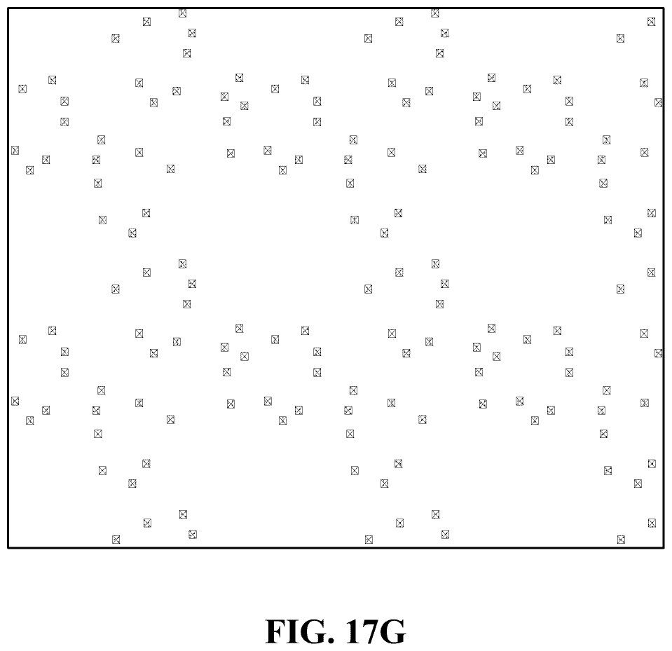

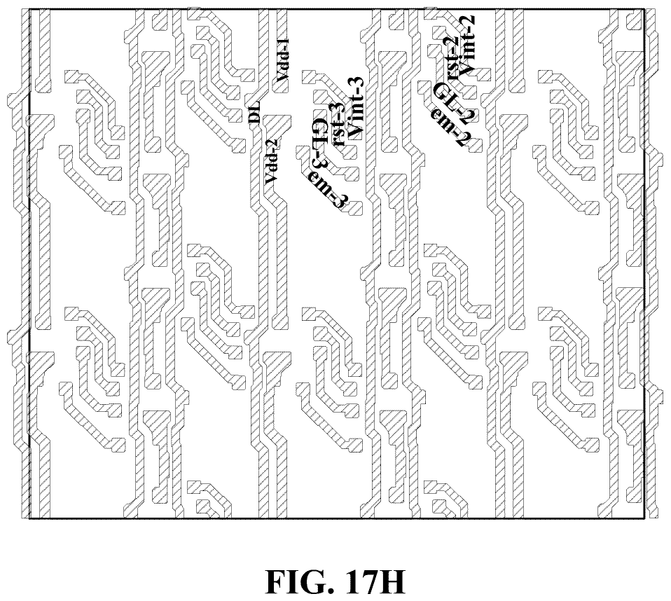

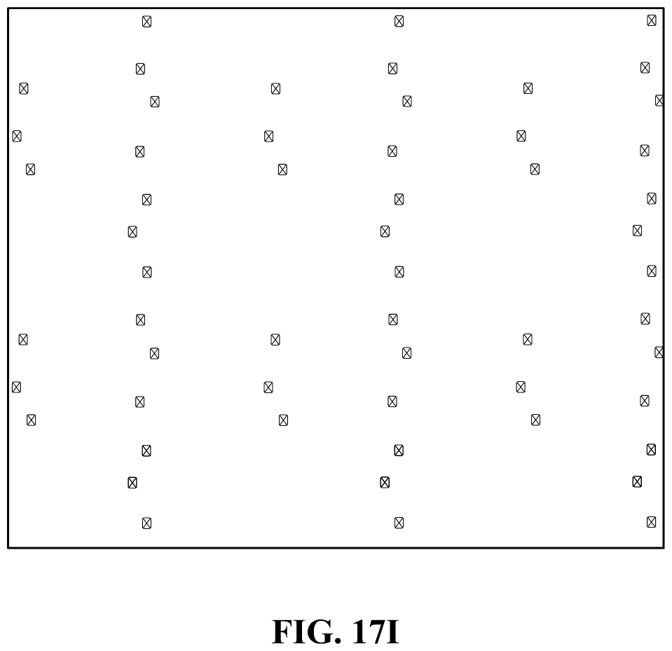

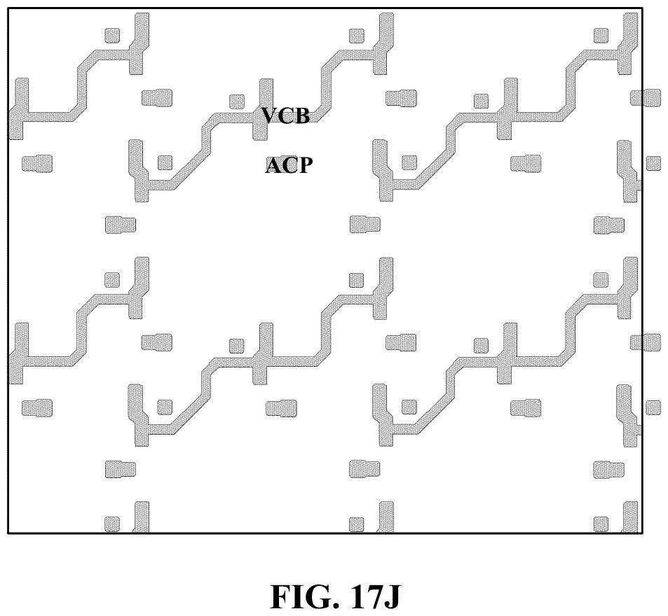

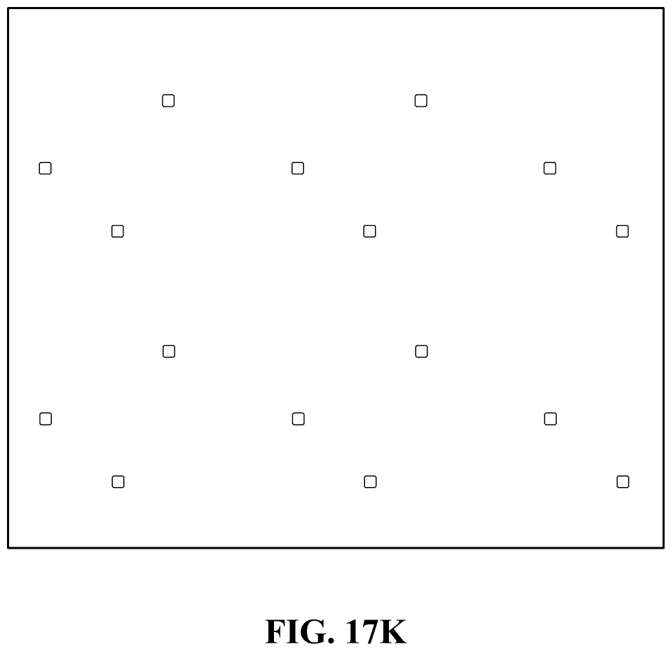

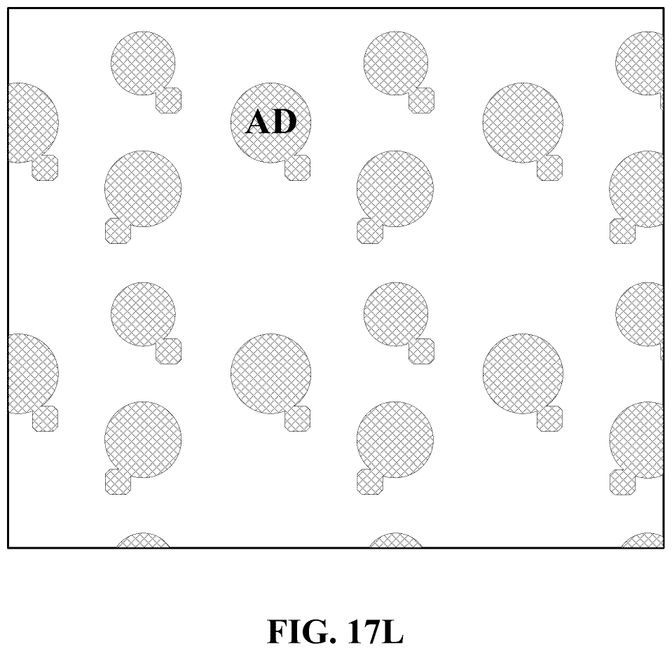

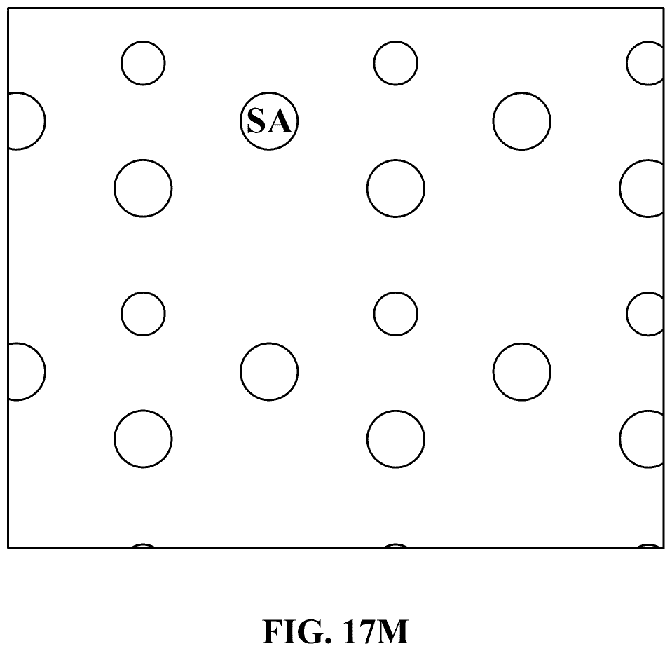

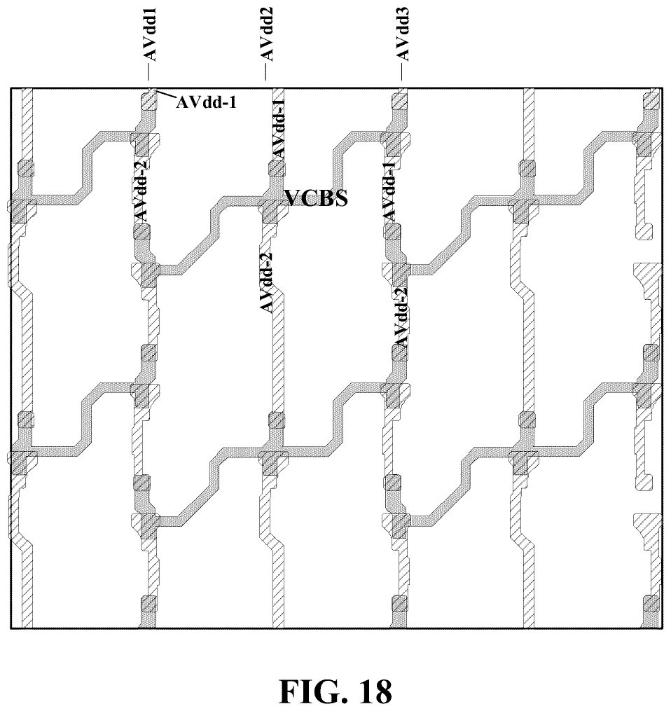

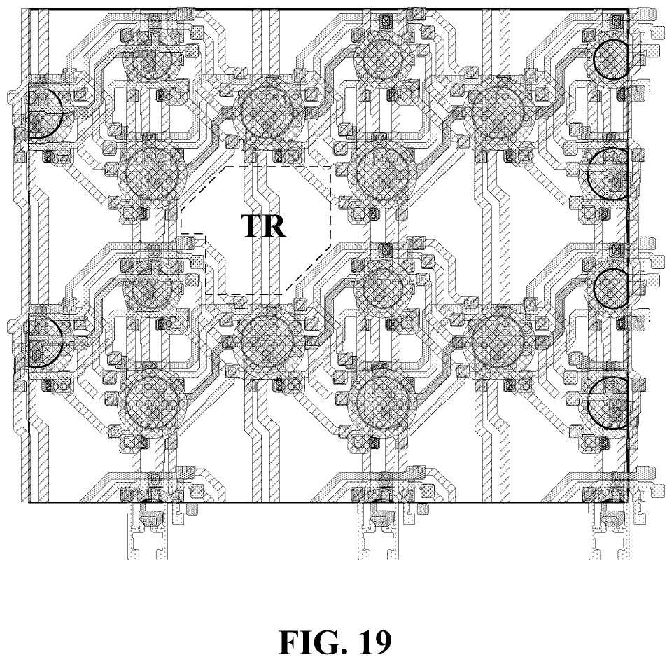

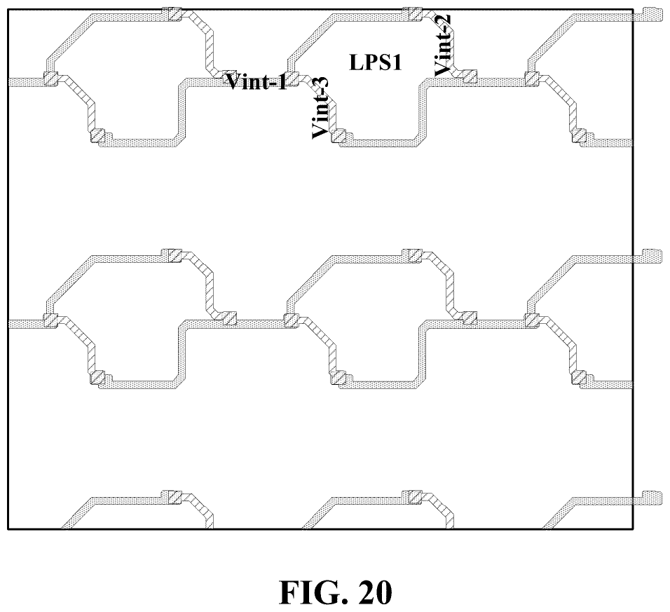

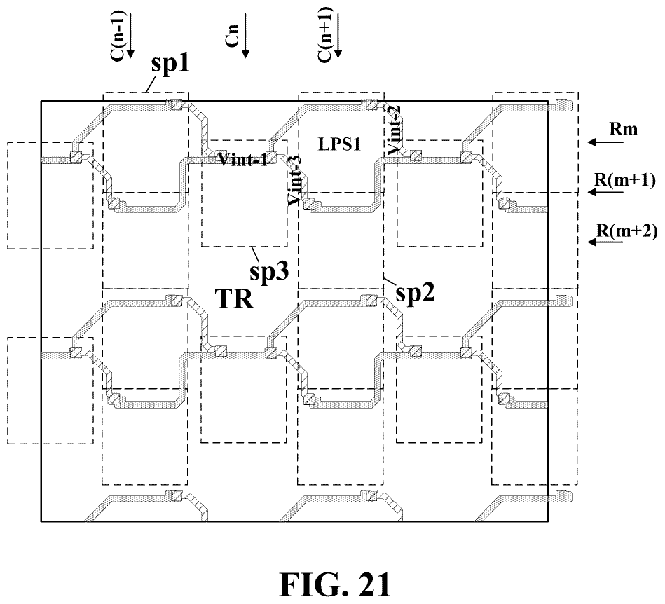

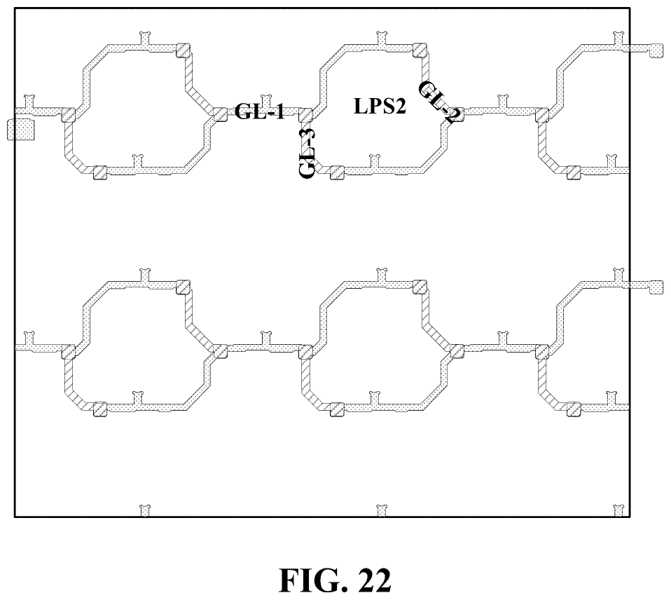

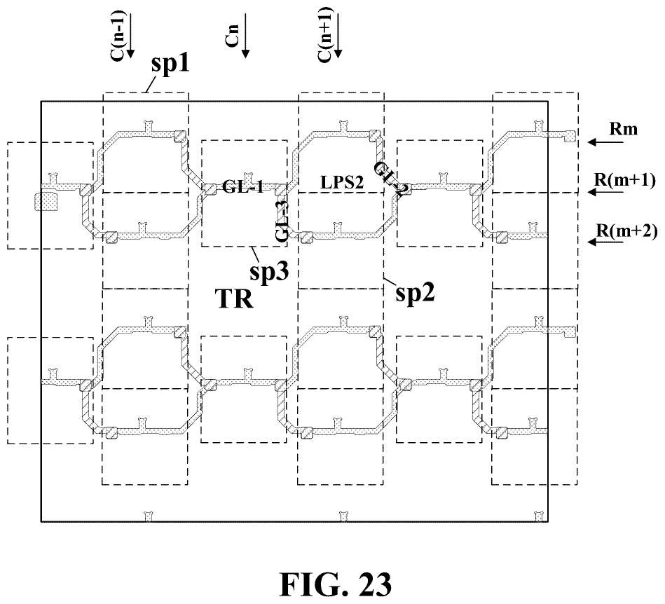

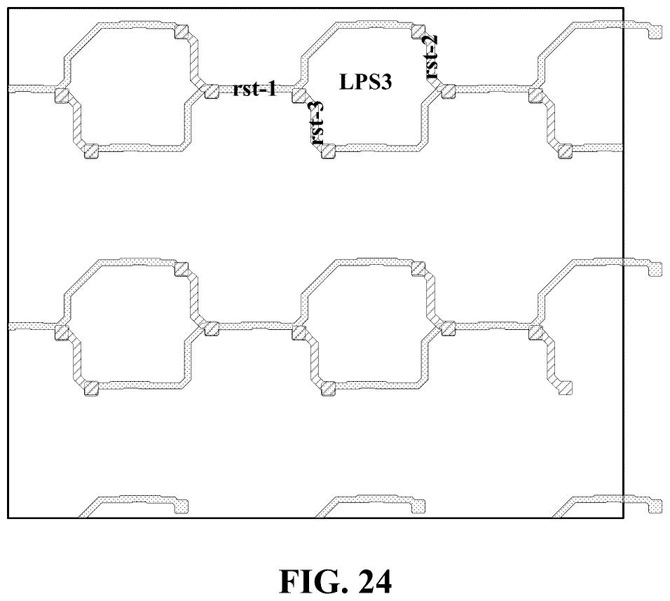

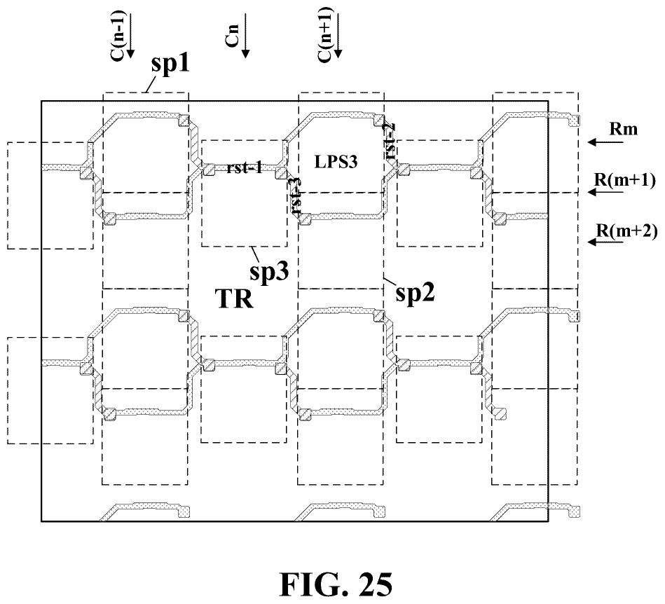

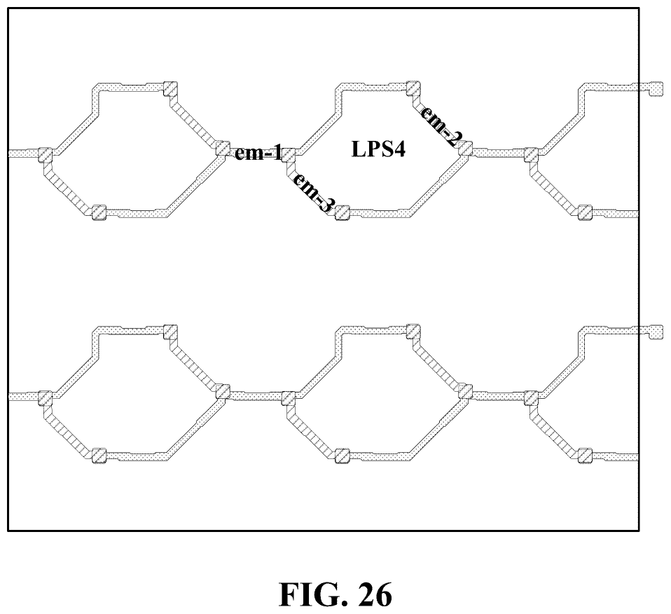

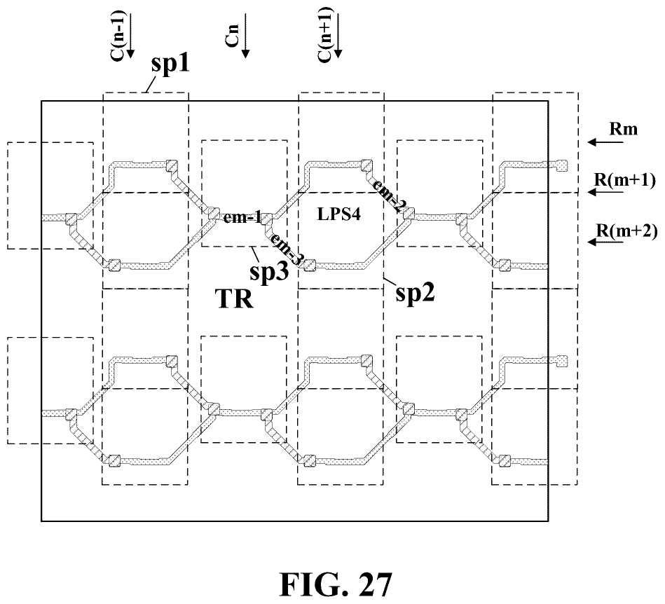

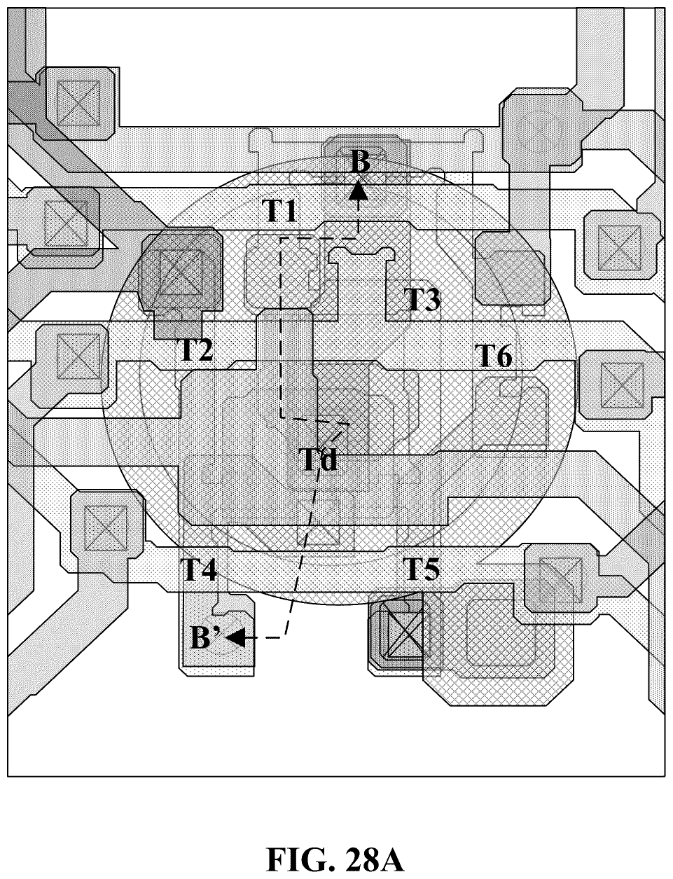

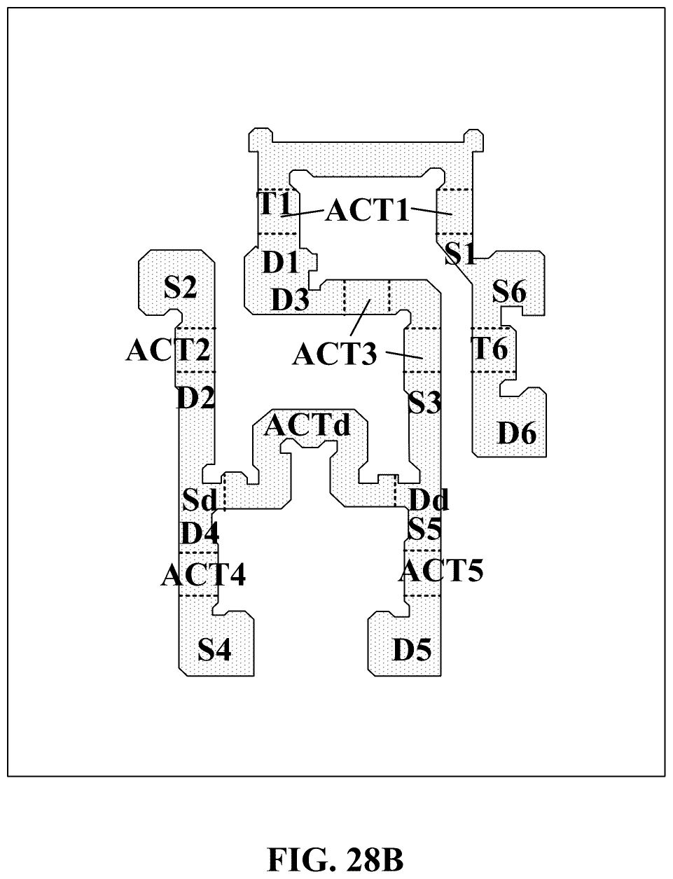

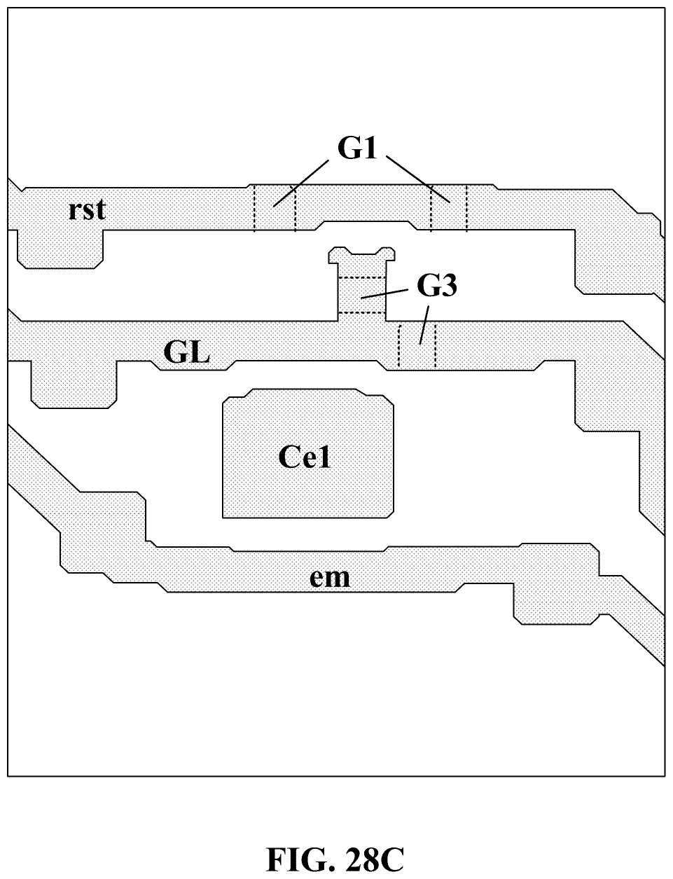

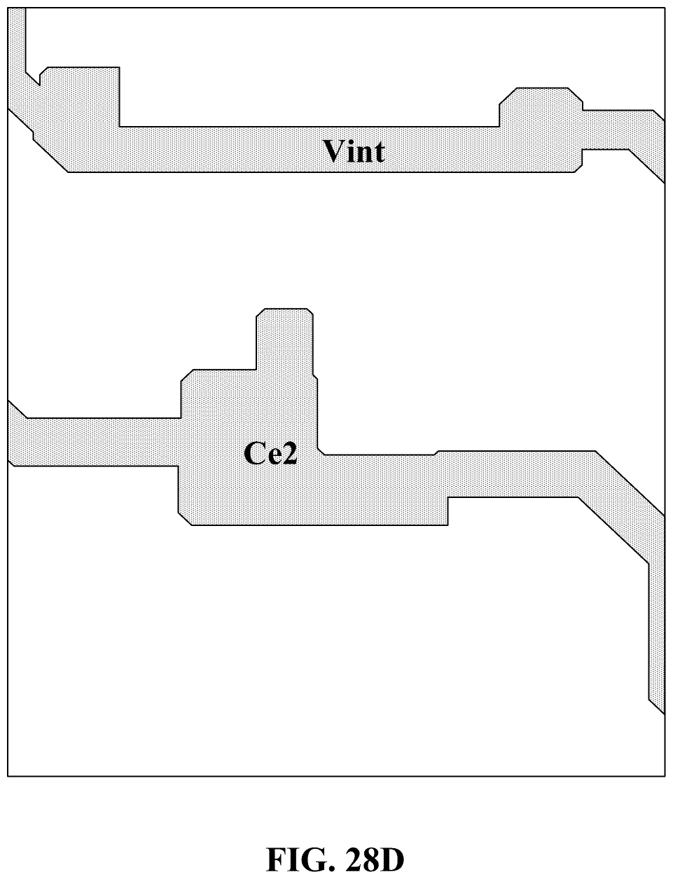

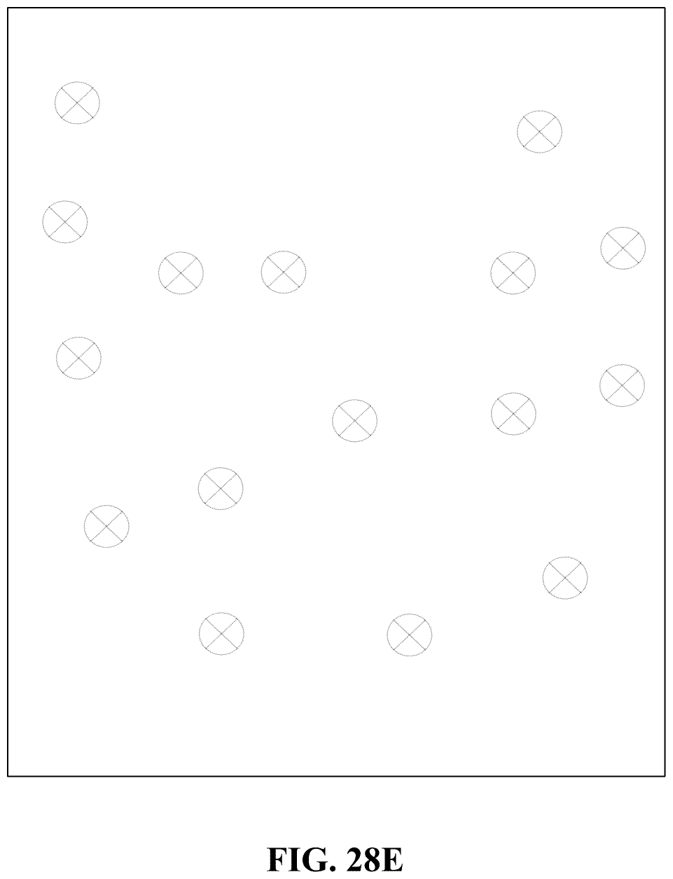

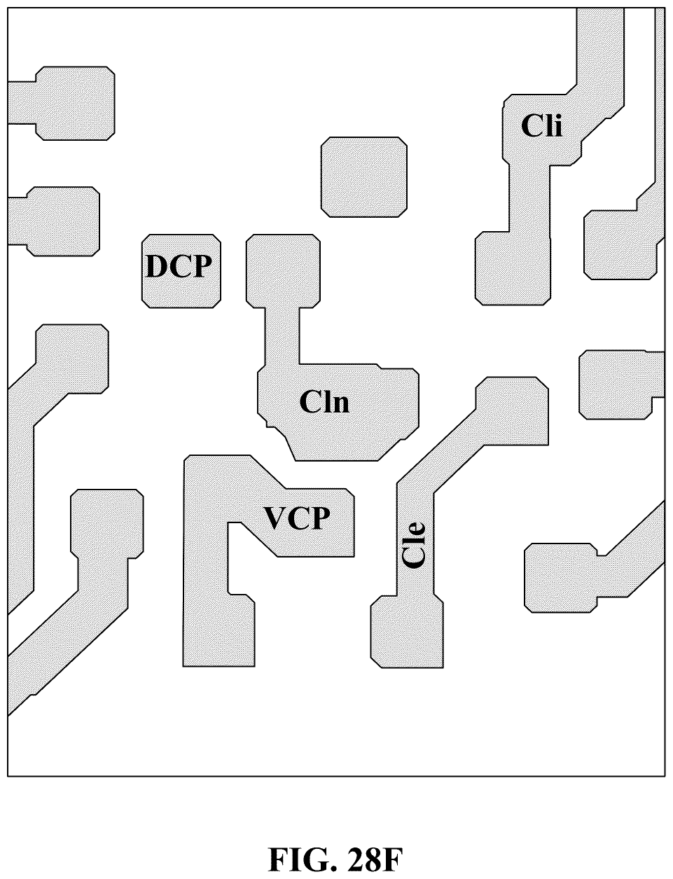

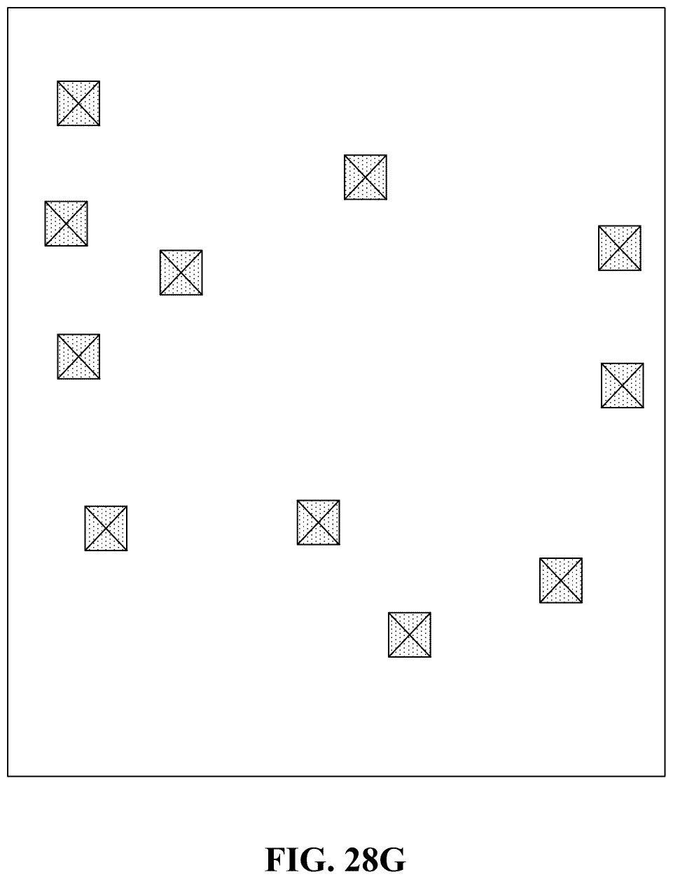

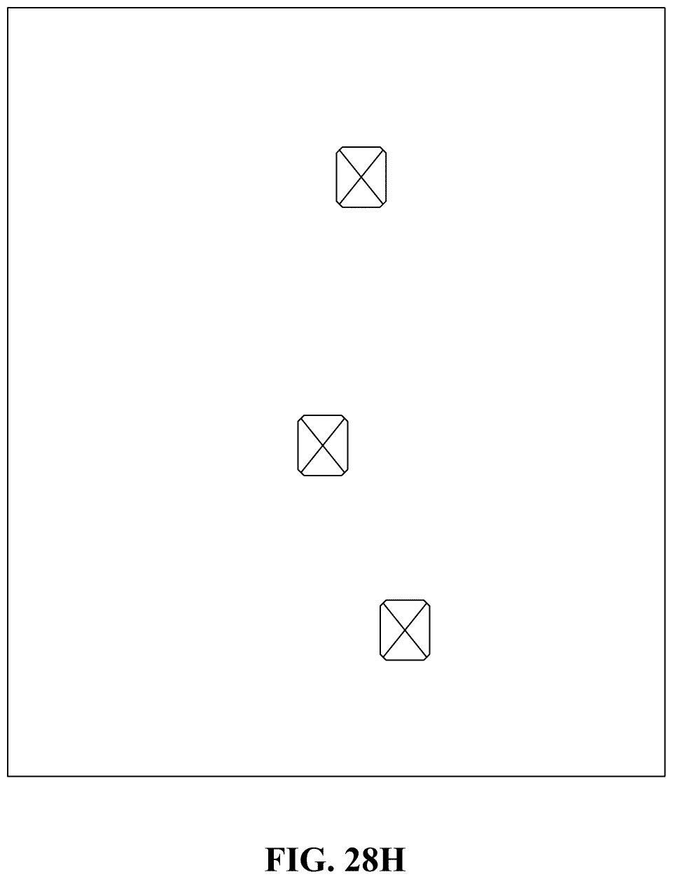

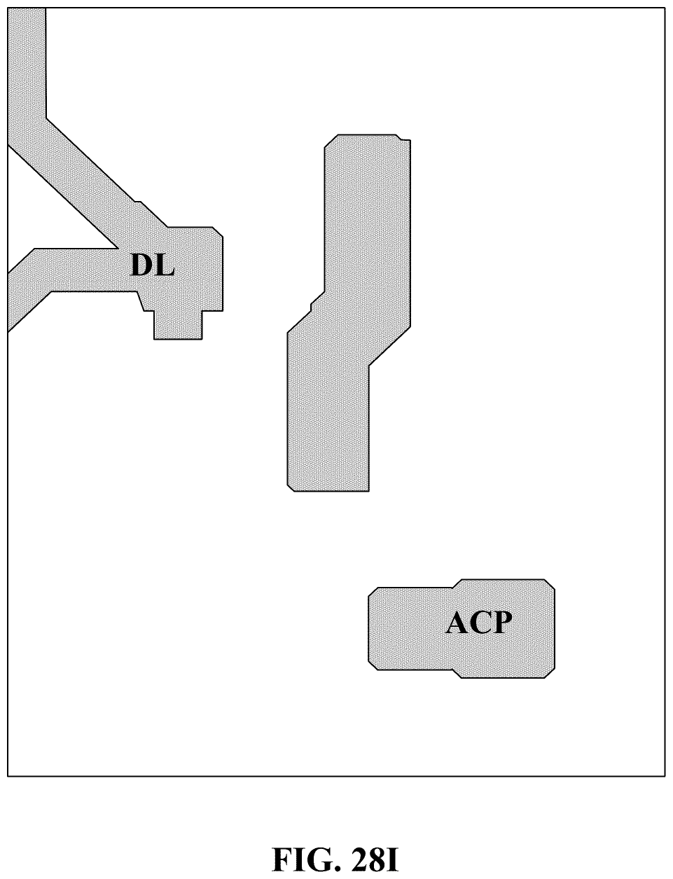

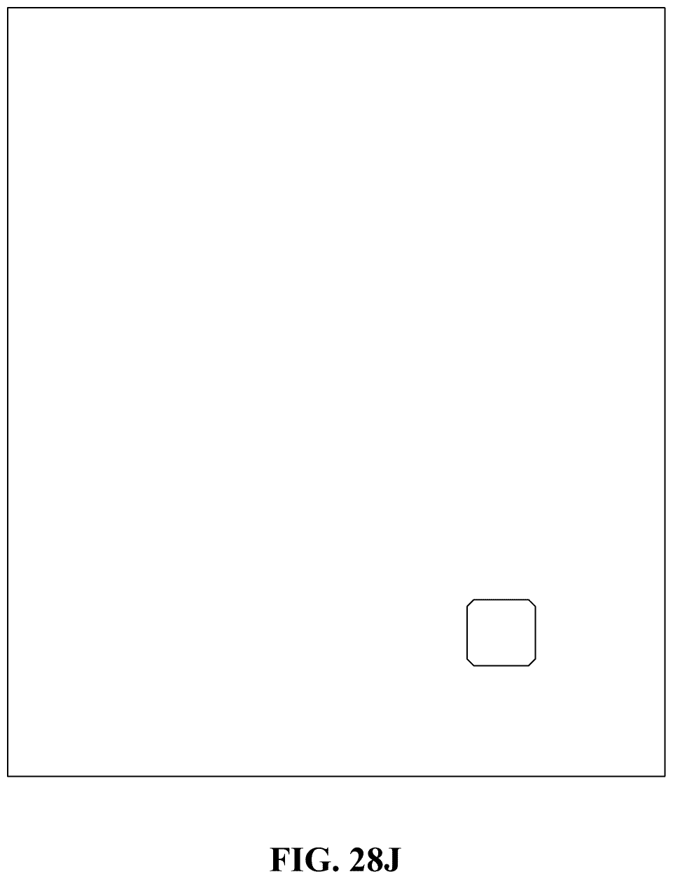

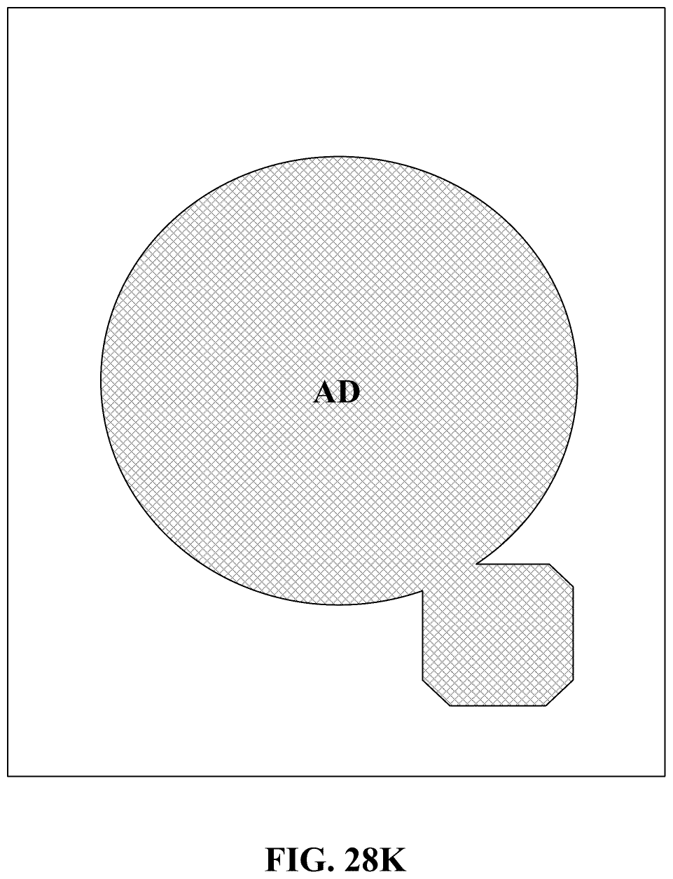

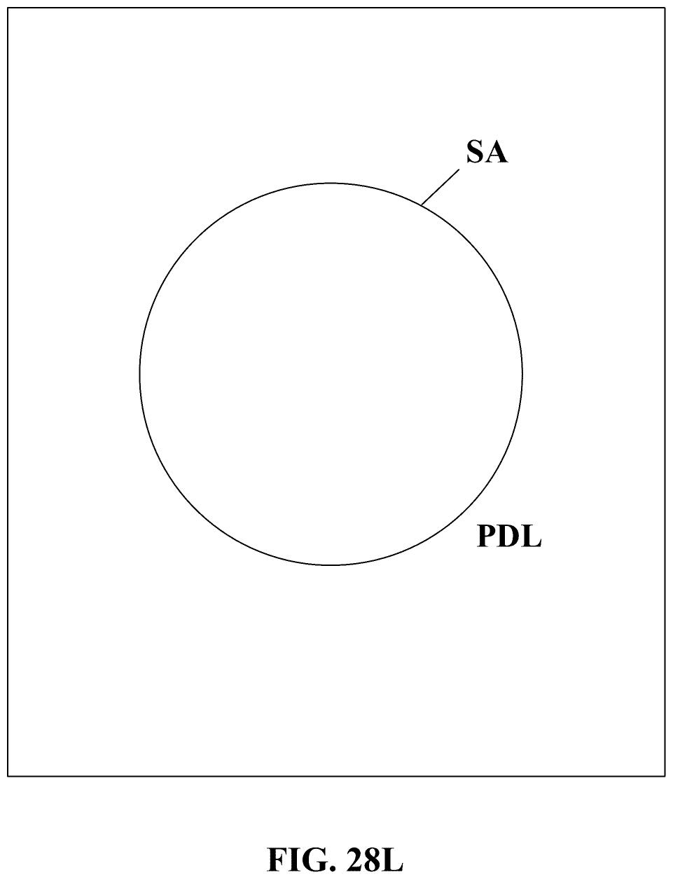

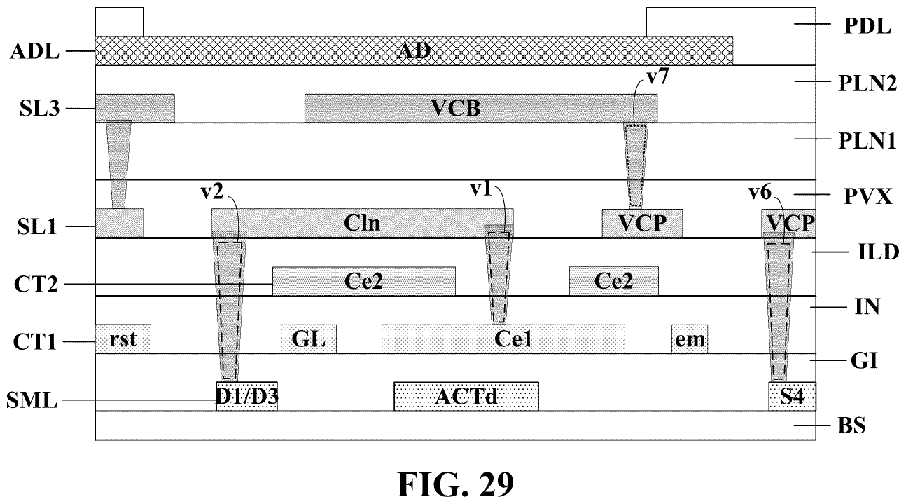

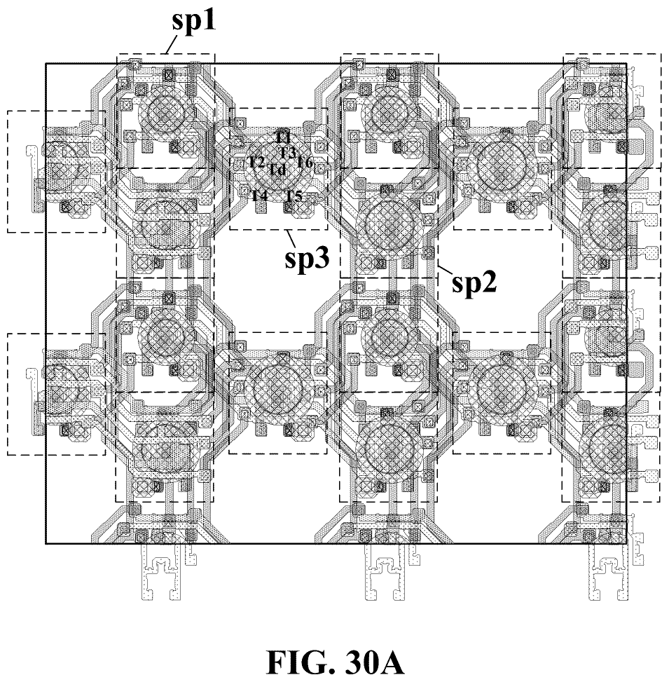

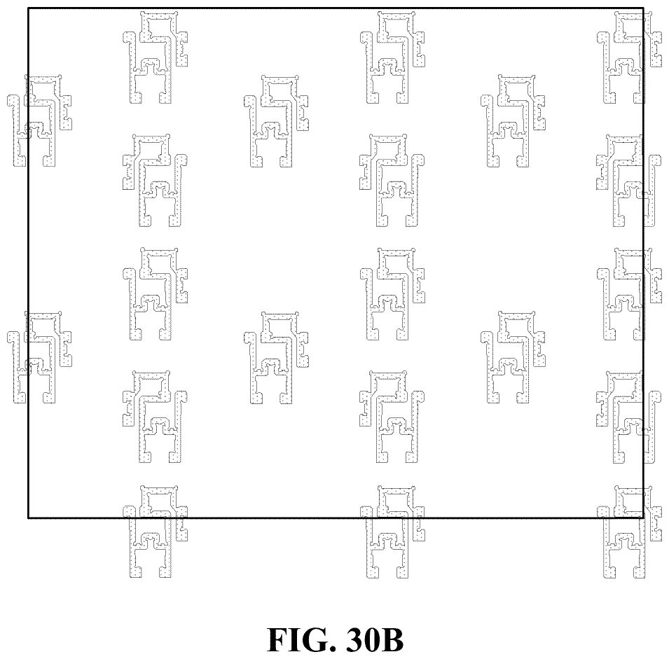

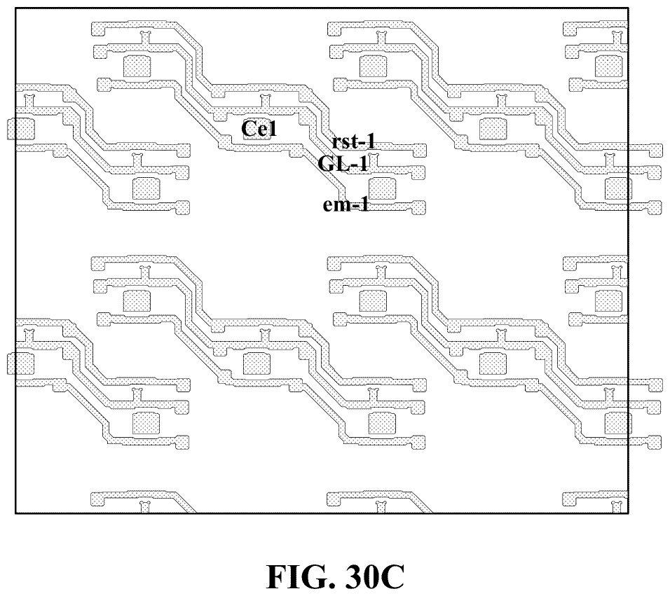

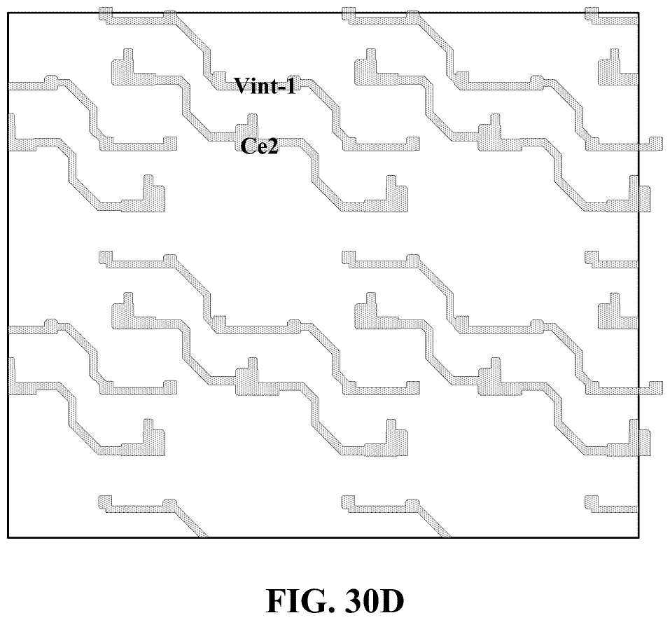

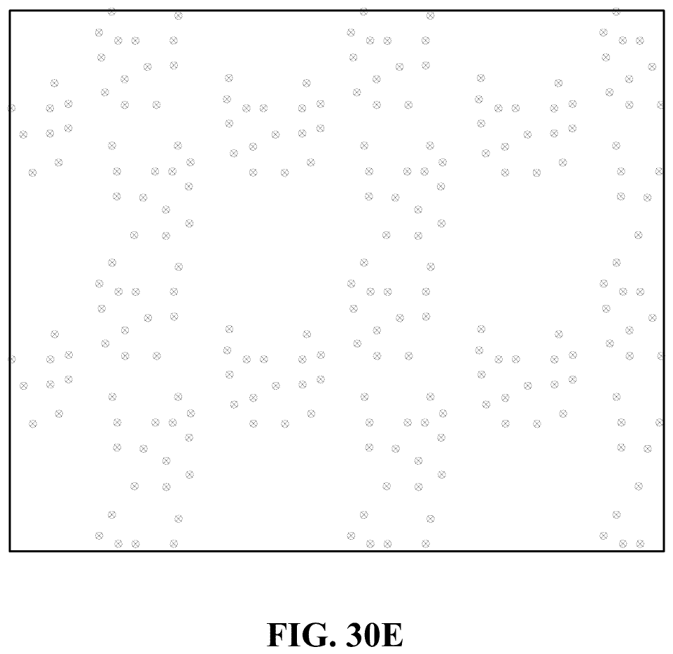

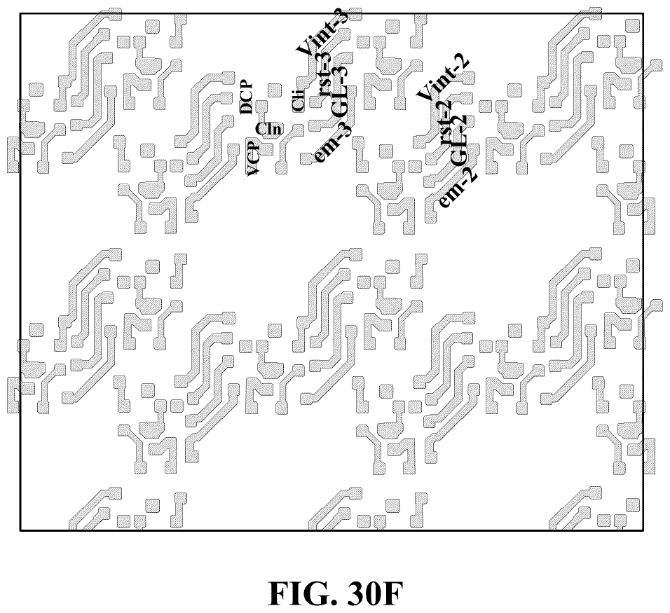

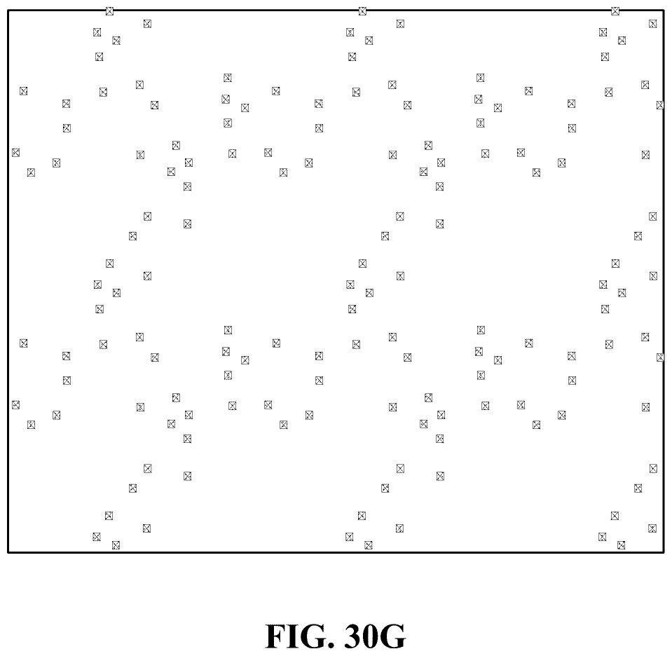

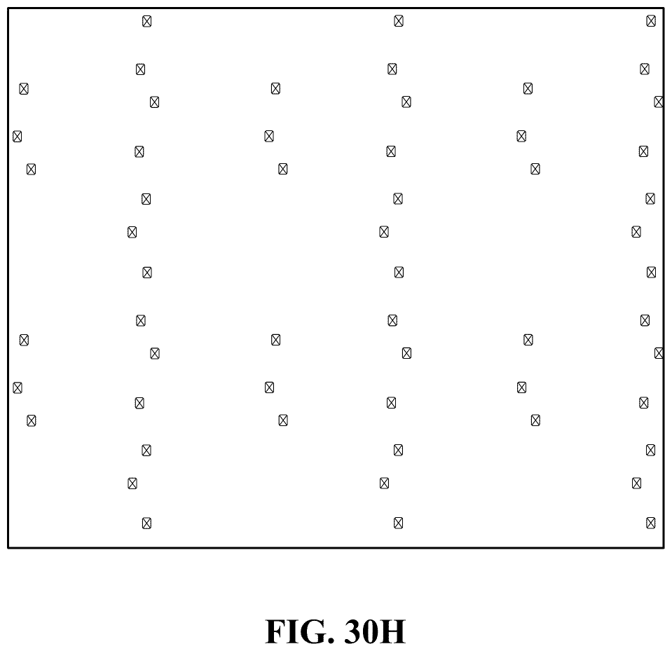

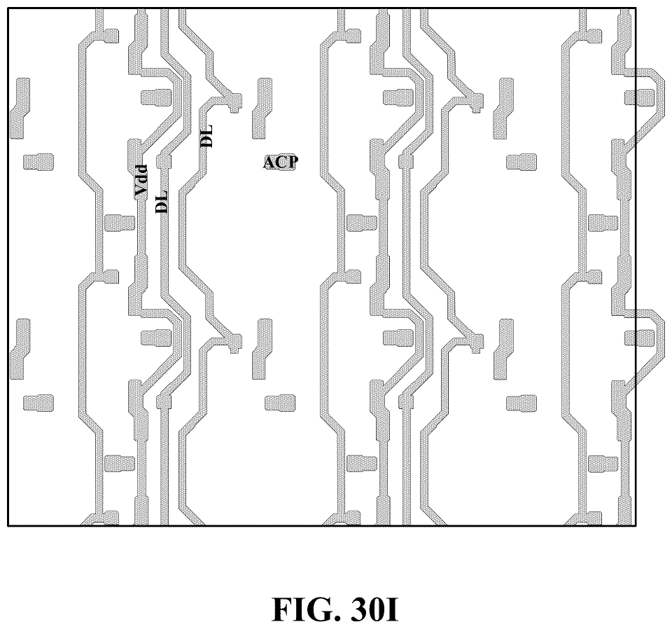

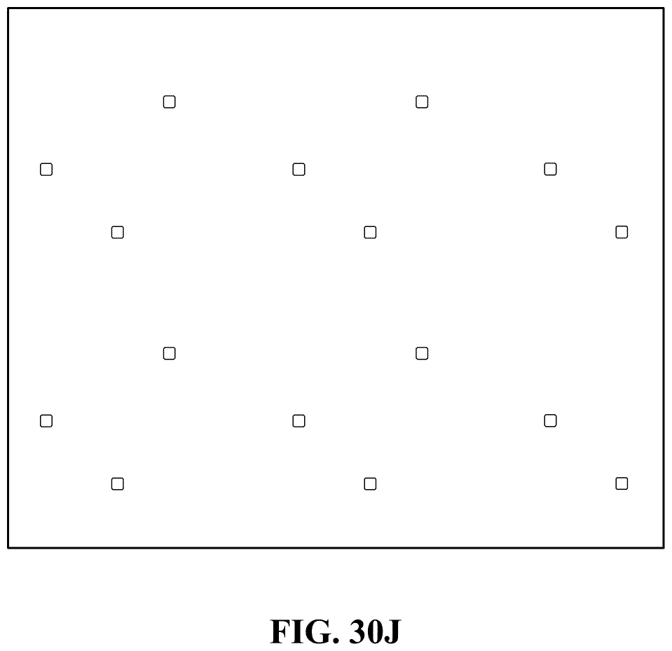

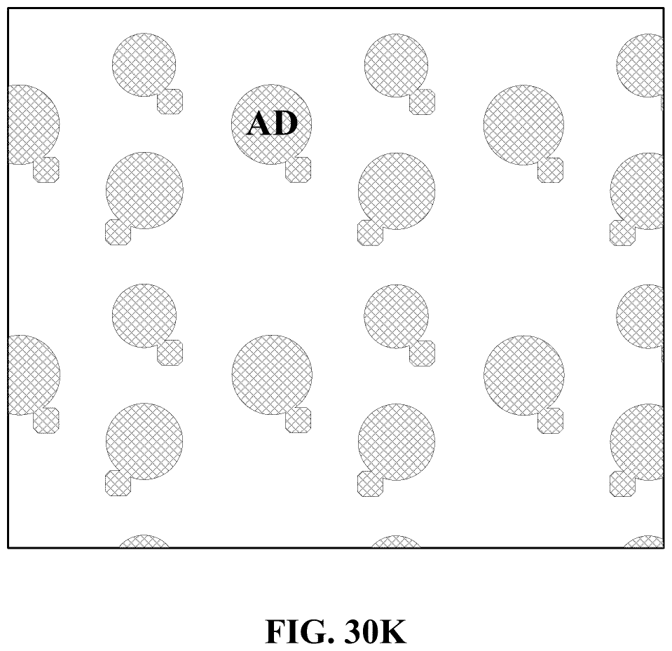

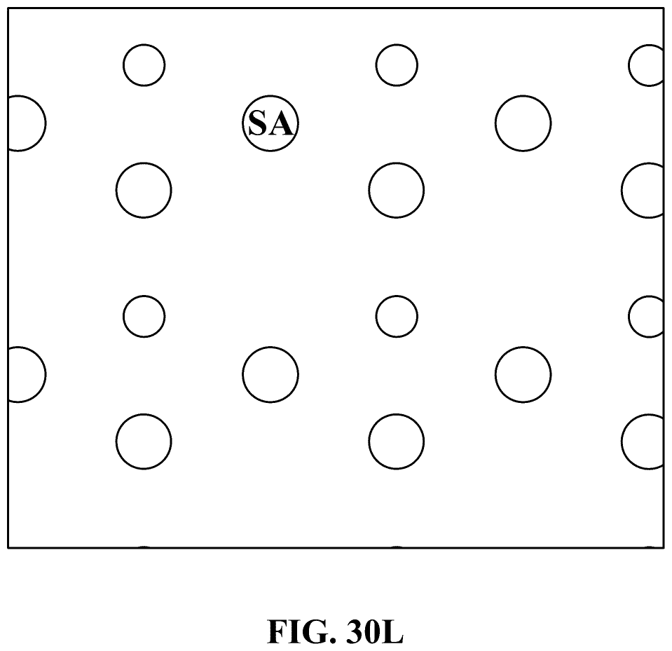

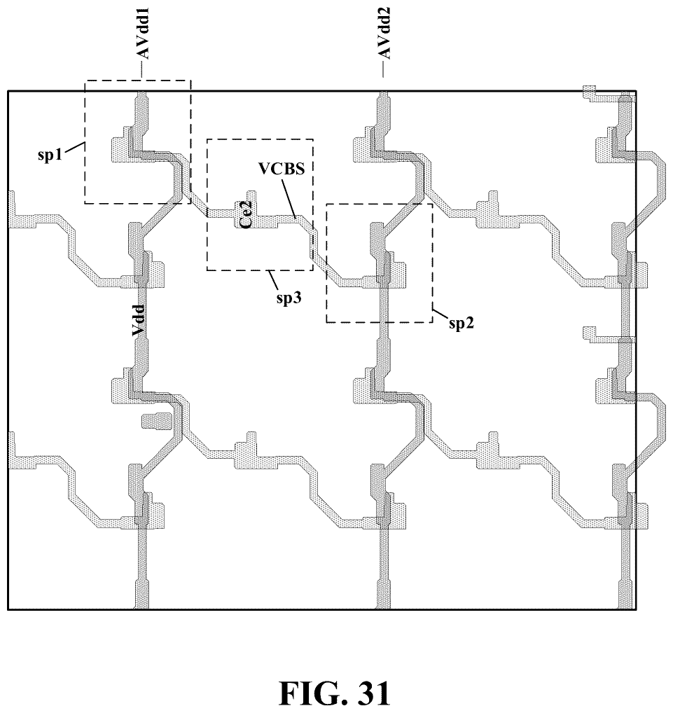

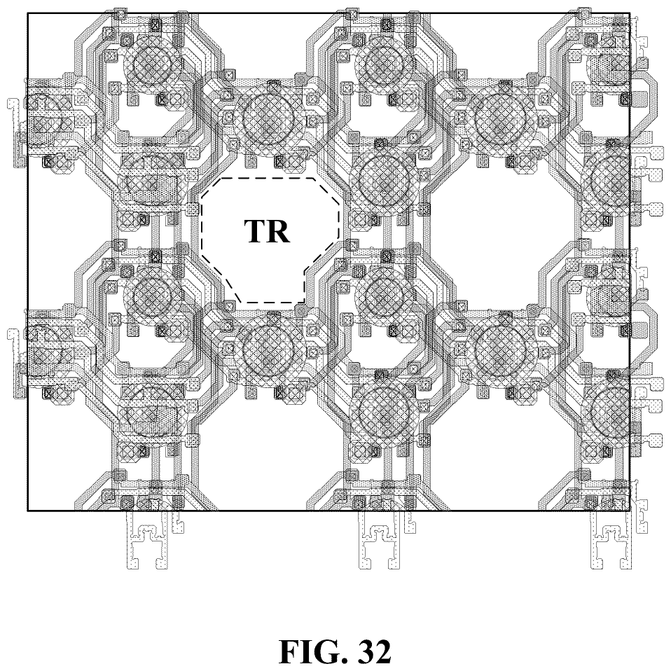

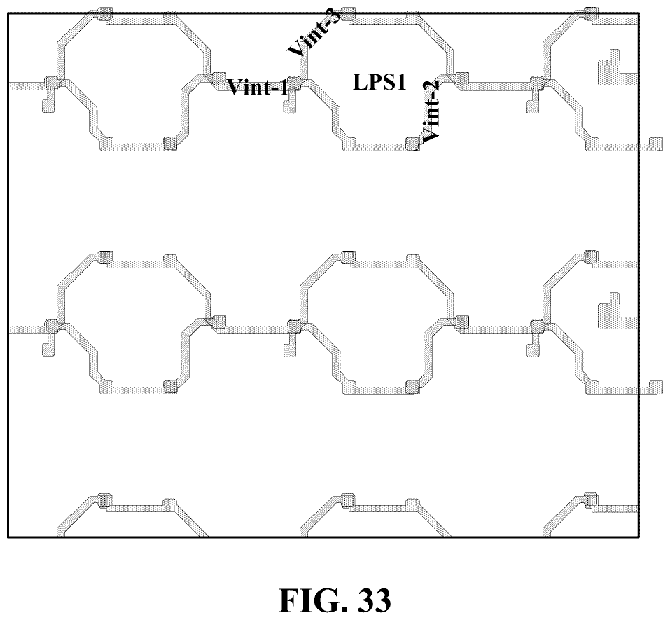

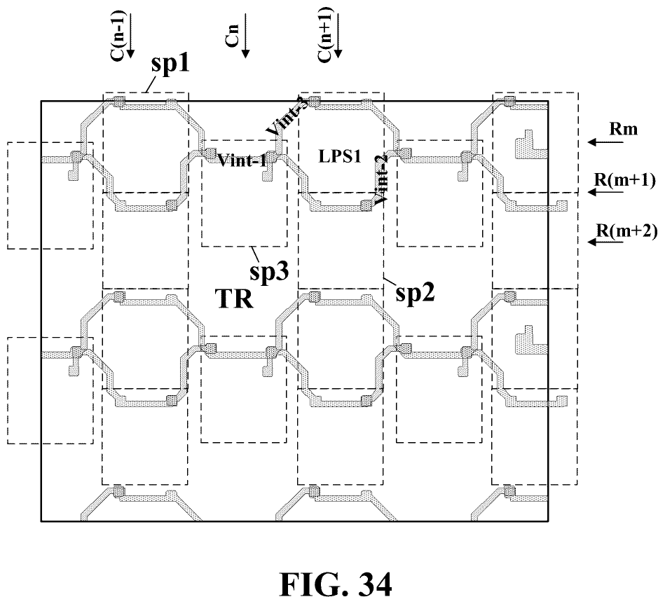

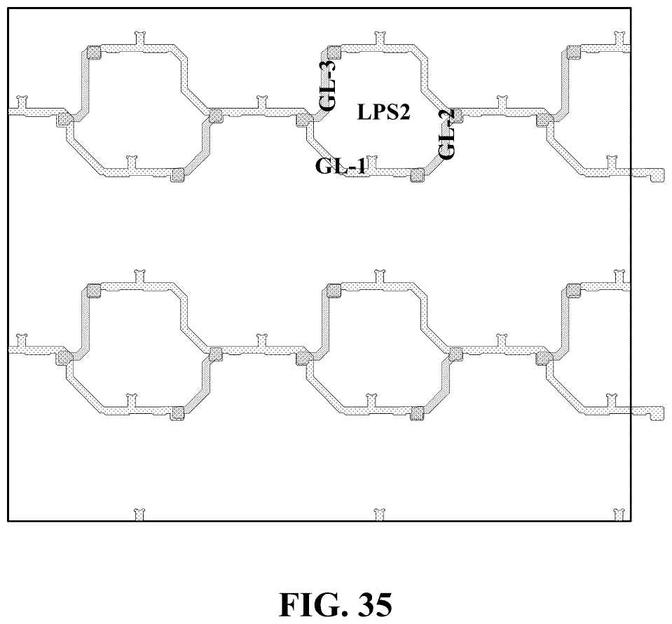

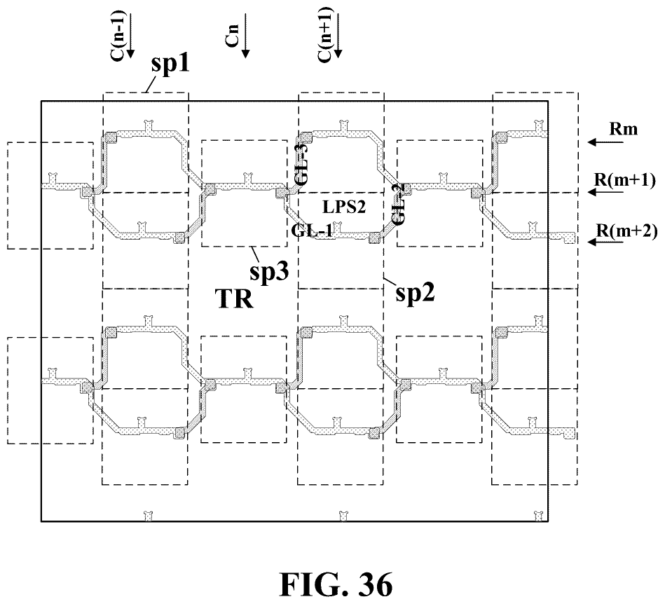

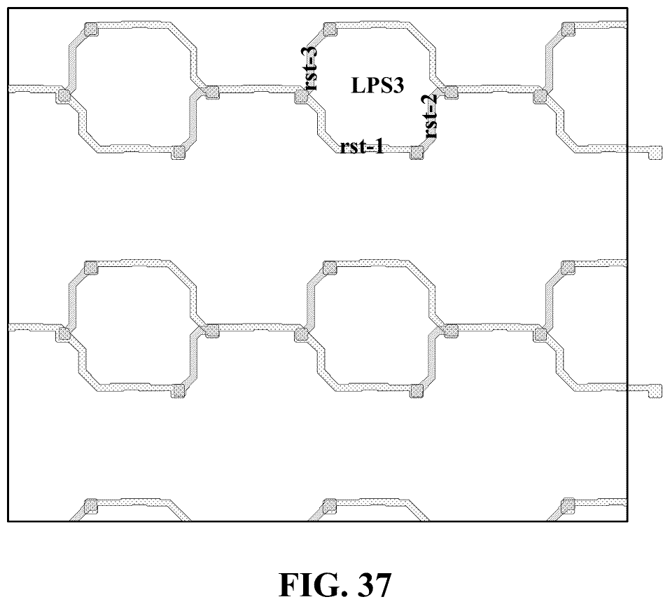

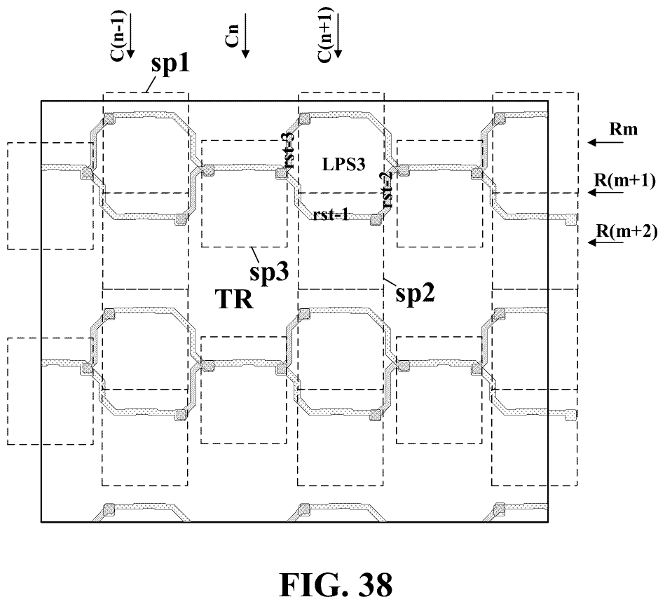

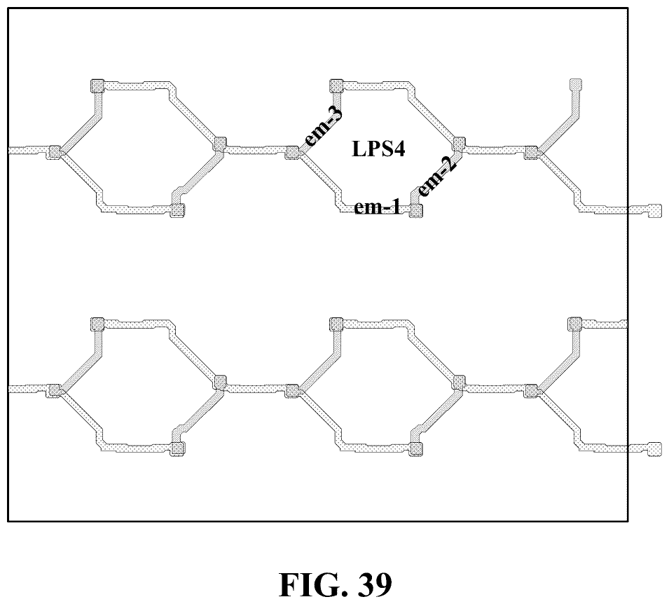

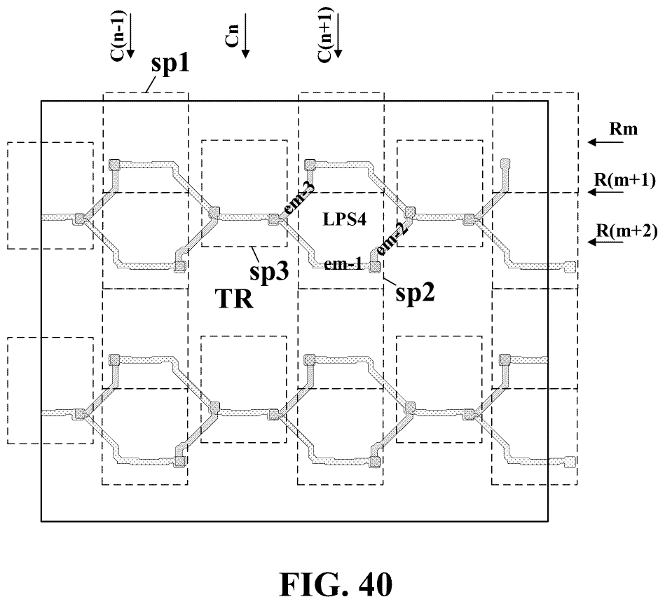

FIG. 10 is a diagram illustrating a gate scanning signal network in a portion of an array substrate in some embodiments according to the present disclosure. Referring to FIG. 5A, FIG. 5C, FIG. 5H, and FIG. 10, a respective gate signal line of the plurality of gate signal lines includes a plurality of first gate signal line portions GL-1 and a plurality of second gate signal line portions GL-2. The plurality of first gate signal line portions GL-1 and the plurality of second gate signal line portions GL-2 are in two different layers. In one example, the plurality of first gate signal line portions GL-1 are in the first conductive layer, and the plurality of second gate signal line portions GL-2 are in the second signal line layer. A respective second gate signal line portion of the plurality of second gate signal line portions GL-2 is connected to two adjacent first gate signal line portions of the plurality of first gate signal line portions GL-1, respectively. Two adjacent first gate signal line portions of the plurality of first gate signal line portions GL-1 are connected by an individual second gate signal line portion of the plurality of second gate signal line portions GL-2.

In some embodiments, a respective gate signal line of the plurality of gate signal lines includes a plurality of first gate signal line portions GL-1 and a plurality of third gate signal line portions GL-3. The plurality of first gate signal line portions GL-1 and the plurality of third gate signal line portions GL-3 are in two different layers. In one example, the plurality of first gate signal line portions GL-1 are in the first conductive layer, and the plurality of third gate signal line portions GL-3 are in the second signal line layer. A respective third gate signal line portion of the plurality of third gate signal line portions GL-3 is connected to two adjacent first gate signal line portions of the plurality of first gate signal line portions GL-1 in the same row, respectively. Two adjacent first gate signal line portions of the plurality of first gate signal line portions GL-1 are connected by an individual third gate signal line portion of the plurality of third gate signal line portions GL-3.

In some embodiments, a respective gate signal line of the plurality of gate signal lines includes a plurality of first gate signal line portions GL-1, a plurality of second gate signal line portions GL-2, and a plurality of third gate signal line portions GL-3. The plurality of first gate signal line portions GL-1 and the plurality of second gate signal line portions GL-2 are in two different layers; and the plurality of first gate signal line portions GL-1 and the plurality of third gate signal line portions GL-3 are in two different layers. Optionally, the plurality of second gate signal line portions GL-2 and the plurality of third gate signal line portions GL-3 are in a same layer. In one example, the plurality of first gate signal line portions GL-1 are in the first conductive layer, the plurality of second gate signal line portions GL-2 are in the second signal line layer, and the plurality of third gate signal line portions GL-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second gate signal line portions GL-2, and the plurality of third gate signal line portions GL-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second gate signal line portion of the plurality of second gate signal line portions GL-2 is connected to two adjacent first gate signal line portions of the plurality of first gate signal line portions GL-1, respectively. A respective third gate signal line portion of the plurality of third gate signal line portions GL-3 is connected to two adjacent first gate signal line portions of the plurality of first gate signal line portions GL-1, respectively. Two adjacent first gate signal line portions of the plurality of first gate signal line portions GL-1 are connected by an individual second gate signal line portion of the plurality of second gate signal line portions GL-2, and connected by an individual third gate signal line portion of the plurality of third gate signal line portions GL-3. The two adjacent first gate signal line portions of the plurality of first gate signal line portions GL-1, the individual second gate signal line portion of the plurality of second gate signal line portions GL-2, and the individual third gate signal line portion of the plurality of third gate signal line portions GL-3 form a second loop substantially surrounding a region having transistors and capacitors of a pixel driving circuit of a subpixel. In one example, the second loop substantially surrounds a region having transistors and capacitors of a respective first subpixel. In another example, the second loop substantially surrounds a region having transistors and capacitors of a subpixel of a first color. In another example, the second loop substantially surrounds a region having transistors and capacitors of a red subpixel.

In some embodiments, the array substrate includes a plurality of second loops LPS2 sequentially arranged in a row. Optionally, the plurality of second loops LPS2 substantially surround regions of pixel driving circuits of subpixels of a same color, respectively. A respective second loop of the plurality of second loops LPS2 substantially surrounds a region of a pixel driving circuit of a subpixel of the same color. In one example, the plurality of second loops LPS2 substantially surround regions of pixel driving circuits of red subpixels.

In some embodiments, the plurality of second loops LPS2 substantially surround regions having anodes of subpixels of a same color, respectively. A respective second loop of the plurality of second loops LPS2 substantially surrounds a region having an anode of a subpixel of the same color. In one example, the plurality of second loops LPS2 substantially surround regions having anodes of red subpixels.

FIG. 11 is a diagram illustrating a gate scanning signal network in a portion of an array substrate in some embodiments according to the present disclosure. In some embodiments, referring to FIG. 11, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the army substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 11.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 3A to FIG. 3M, FIG. 5A to FIG. 5M, and FIG. 11, a first gate signal line portion of the plurality of first gate signal line portions GL-1 in some embodiments is connected to gate electrodes of one or more data write transistors in a pixel driving circuit in a third subpixel in the n-th column of subpixels Cn and the (m+1)-th row of subpixels R(m+1), is connected to gate electrodes of one or more data write transistors in a pixel driving circuit in a first subpixel in the (n−1)-th column of subpixels C(n−1) and the m-th row of subpixels Rm, and is connected to gate electrodes of one or more data write transistors in a pixel driving circuit in a second subpixel in the (n+1)-th column of subpixels C(n+1) and the (m+2)-th row of subpixels R(m+2).

In some embodiments, a second gate signal line portion of the plurality of second gate signal line portions GL-2 connects the first gate signal line portion with a first adjacent first gate signal line portion, the first adjacent first gate signal line portion is connected to gate electrodes of one or more data write transistors in a pixel driving circuit in a second subpixel in the (n−1)-th column of subpixels C(n−1) and the (m+2)-th row of subpixels R(m+2).

In some embodiments, a third gate signal line portion of the plurality of third gate signal line portions GL-3 connects the first gate signal line portion with a second adjacent first gate signal line portion, the second adjacent first gate signal line portion is connected to gate electrodes of one or more data write transistors in a pixel driving circuit in a first subpixel in the (n+1)-th column of subpixels C(n+1) and the m-th row of subpixels Rm.

FIG. 12 is a diagram illustrating a reset control signal network in a portion of an array substrate in some embodiments according to the present disclosure. Referring to FIG. 5A, FIG. 5C, FIG. 5H, and FIG. 12, a respective reset control signal line of the plurality of reset control signal lines includes a plurality of first reset control signal line portions rst-1 and a plurality of second reset control signal line portions rst-2. The plurality of first reset control signal line portions rst-1 and the plurality of second reset control signal line portions rst-2 are in two different layers. In one example, the plurality of first reset control signal line portions rst-1 are in the first conductive layer, and the plurality of second reset control signal line portions rst-2 are in the second signal line layer. A respective second reset control signal line portion of the plurality of second reset control signal line portions rst-2 is connected to two adjacent first reset control signal line portions of the plurality of first reset control signal line portions rst-1, respectively. Two adjacent first reset control signal line portions of the plurality of first reset control signal line portions rst-1 are connected by an individual second reset control signal line portion of the plurality of second reset control signal line portions rst-2.

In some embodiments, a respective reset control signal line of the plurality of reset control signal lines includes a plurality of first reset control signal line portions rst-1 and a plurality of third reset control signal line portions rst-3. The plurality of first reset control signal line portions rst-1 and the plurality of third reset control signal line portions rst-3 are in two different layers. In one example, the plurality of first reset control signal line portions rst-1 are in the first conductive layer, and the plurality of third reset control signal line portions rst-3 are in the second signal line layer. A respective third reset control signal line portion of the plurality of third reset control signal line portions rst-3 is connected to two adjacent first reset control signal line portions of the plurality of first reset control signal line portions rst-1 in the same row, respectively. Two adjacent first reset control signal line portions of the plurality of first reset control signal line portions rst-1 are connected by an individual third reset control signal line portion of the plurality of third reset control signal line portions rst-3.

In some embodiments, a respective reset control signal line of the plurality of reset control signal lines includes a plurality of first reset control signal line portions rst-1, a plurality of second reset control signal line portions rst-2, and a plurality of third reset control signal line portions rst-3. The plurality of first reset control signal line portions rst-1 and the plurality of second reset control signal line portions rst-2 are in two different layers; and the plurality of first reset control signal line portions rst-1 and the plurality of third reset control signal line portions rst-3 are in two different layers. Optionally, the plurality of second reset control signal line portions rst-2 and the plurality of third reset control signal line portions rst-3 are in a same layer. In one example, the plurality of first reset control signal line portions rst-1 are in the first conductive layer, the plurality of second reset control signal line portions rst-2 are in the second signal line layer, and the plurality of third reset control signal line portions rst-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second reset control signal line portions rst-2, and the plurality of third reset control signal line portions rst-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second reset control signal line portion of the plurality of second reset control signal line portions rst-2 is connected to two adjacent first reset control signal line portions of the plurality of first reset control signal line portions rst-1, respectively. A respective third reset control signal line portion of the plurality of third reset control signal line portions rst-3 is connected to two adjacent first reset control signal line portions of the plurality of first reset control signal line portions rst-1, respectively. Two adjacent first reset control signal line portions of the plurality of first reset control signal line portions rst-1 are connected by an individual second reset control signal line portion of the plurality of second reset control signal line portions rst-2, and connected by an individual third reset control signal line portion of the plurality of third reset control signal line portions rst-3. The two adjacent first reset control signal line portions of the plurality of first reset control signal line portions rst-1, the individual second reset control signal line portion of the plurality of second reset control signal line portions rst-2, and the individual third reset control signal line portion of the plurality of third reset control signal line portions rst-3 form a third loop substantially surrounding a region having transistors and capacitors of a pixel driving circuit of a subpixel. In one example, the third loop substantially surrounds a region having transistors and capacitors of a respective first subpixel. In another example, the third loop substantially surrounds a region having transistors and capacitors of a subpixel of a first color. In another example, the third loop substantially surrounds a region having transistors and capacitors of a red subpixel.

In some embodiments, the array substrate includes a plurality of third loops LPS3 sequentially arranged in a row. Optionally, the plurality of third loops LPS3 substantially surround regions of pixel driving circuits of subpixels of a same color, respectively. A respective third loop of the plurality of third loops LPS3 substantially surrounds a region of a pixel driving circuit of a subpixel of the same color. In one example, the plurality of third loops LPS3 substantially surround regions of pixel driving circuits of red subpixels.

In some embodiments, the plurality of third loops LPS3 substantially surround regions having anodes of subpixels of a same color, respectively. A respective third loop of the plurality of third loops LPS3 substantially surrounds a region having an anode of a subpixel of the same color. In one example, the plurality of third loops LPS3 substantially surround regions having anodes of red subpixels.

FIG. 13 is a diagram illustrating a reset control signal network in a portion of an array substrate in some embodiments according to the present disclosure. In some embodiments, referring to FIG. 13, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 13.

In some embodiments, in an n-th column of subpixels Cn, the array substrate includes a column of third subpixels. Ina (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-tb column of subpixels Cn, a respective light transmissive region of the plurality of light transmissive regions TR spaces apart two adjacent third subpixels.

Referring to FIG. 2A, FIG. 2B, FIG. 3A to FIG. 3M, FIG. 5A to FIG. 5M, and FIG. 13, a first reset control signal line portion of the plurality of first reset control signal line portions rst-1 in some embodiments is connected to gate electrodes of one or more reset control transistors in a pixel driving circuit in a third subpixel in the n-th column of subpixels Cn and the (m+1)-th row of subpixels R(m+1), is connected to gate electrodes of one or more reset control transistors in a pixel driving circuit in a first subpixel in the (n−1)-th column of subpixels C(n−1) and the m-th row of subpixels Rm, and is connected to gate electrodes of one or more reset control transistors in a pixel driving circuit in a second subpixel in the (n+1)-th column of subpixels C(n+1) and the (m+2)-th row of subpixels R(m+2).

In some embodiments, a second reset control signal line portion of the plurality of second reset control signal line portions rst-2 connects the first reset control signal line portion with a first adjacent first reset control signal line portion, the first adjacent first reset control signal line portion is connected to gate electrodes of one or more reset control transistors in a pixel driving circuit in a second subpixel in the (n−1)-th column of subpixels C(n−1) and the (m+2)-th row of subpixels R(m+2).

In some embodiments, a third reset control signal line portion of the plurality of third reset control signal line portions rst-3 connects the first reset control signal line portion with a second adjacent first reset control signal line portion, the second adjacent first reset control signal line portion is connected to gate electrodes of one or more reset control transistors in a pixel driving circuit in a first subpixel in the (n+1)-th column of subpixels C(n+1) and the m-th row of subpixels Rm.

FIG. 14 is a diagram illustrating a light emitting control signal network in a portion of an array substrate in some embodiments according to the present disclosure. Referring to FIG. 5A, FIG. 5C, FIG. 5H, and FIG. 14, a respective light emitting control signal line of the plurality of light emitting control signal lines includes a plurality of first light emitting control signal line portions em-1 and a plurality of second light emitting control signal line portions em-2. The plurality of first light emitting control signal line portions em-1 and the plurality of second light emitting control signal line portions em-2 are in two different layers. In one example, the plurality of first light emitting control signal line portions em-1 are in the first conductive layer, and the plurality of second light emitting control signal line portions em-2 are in the second signal line layer. A respective second light emitting control signal line portion of the plurality of second light emitting control signal line portions em-2 is connected to two adjacent first light emitting control signal line portions of the plurality of first light emitting control signal line portions em-1, respectively. Two adjacent first light emitting control signal line portions of the plurality of first light emitting control signal line portions em-1 are connected by an individual second light emitting control signal line portion of the plurality of second light emitting control signal line portions em-2.

In some embodiments, a respective light emitting control signal line of the plurality of light emitting control signal lines includes a plurality of first light emitting control signal line portions em-1 and a plurality of third light emitting control signal line portions em-3. The plurality of first light emitting control signal line portions em-1 and the plurality of third light emitting control signal line portions em-3 are in two different layers. In one example, the plurality of first light emitting control signal line portions em-1 are in the first conductive layer, and the plurality of third light emitting control signal line portions em-3 are in the second signal line layer. A respective third light emitting control signal line portion of the plurality of third light emitting control signal line portions em-3 is connected to two adjacent first light emitting control signal line portions of the plurality of first light emitting control signal line portions em-1 in the same row, respectively. Two adjacent first light emitting control signal line portions of the plurality of first light emitting control signal line portions em-1 are connected by an individual third light emitting control signal line portion of the plurality of third light emitting control signal line portions em-3.

In some embodiments, a respective light emitting control signal line of the plurality of light emitting control signal lines includes a plurality of first light emitting control signal line portions em-1, a plurality of second light emitting control signal line portions em-2, and a plurality of third light emitting control signal line portions em-3. The plurality of first light emitting control signal line portions em-1 and the plurality of second light emitting control signal line portions em-2 are in two different layers; and the plurality of first light emitting control signal line portions em-1 and the plurality of third light emitting control signal line portions em-3 are in two different layers. Optionally, the plurality of second light emitting control signal line portions em-2 and the plurality of third light emitting control signal line portions em-3 are in a same layer. In one example, the plurality of first light emitting control signal line portions em-1 are in the first conductive layer, the plurality of second light emitting control signal line portions em-2 are in the second signal line layer, and the plurality of third light emitting control signal line portions em-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second light emitting control signal line portions em-2, and the plurality of third light emitting control signal line portions em-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second light emitting control signal line portion of the plurality of second light emitting control signal line portions em-2 is connected to two adjacent first light emitting control signal line portions of the plurality of first light emitting control signal line portions em-1, respectively. A respective third light emitting control signal line portion of the plurality of third light emitting control signal line portions em-3 is connected to two adjacent first light emitting control signal line portions of the plurality of first light emitting control signal line portions em-1, respectively. Two adjacent first light emitting control signal line portions of the plurality of first light emitting control signal line portions em-1 are connected by an individual second light emitting control signal line portion of the plurality of second light emitting control signal line portions em-2, and connected by an individual third light emitting control signal line portion of the plurality of third light emitting control signal line portions em-3. The two adjacent first light emitting control signal line portions of the plurality of first light emitting control signal line portions em-1, the individual second light emitting control signal line portion of the plurality of second light emitting control signal line portions em-2, and the individual third light emitting control signal line portion of the plurality of third light emitting control signal line portions em-3 form a fourth loop substantially surrounding a region having transistors and capacitors of a pixel driving circuit of a subpixel. In one example, the fourth loop substantially surrounds a region having transistors and capacitors of a respective first subpixel, in another example, the fourth loop substantially surrounds a region having transistors and capacitors of a subpixel of a first color. In another example, the fourth loop substantially surrounds a region having transistors and capacitors of a red subpixel.

In some embodiments, the array substrate includes a plurality of fourth loops LPS4 sequentially arranged in a row. Optionally, the plurality of fourth loops LPS4 substantially surround regions of pixel driving circuits of subpixels of a same color, respectively. A respective fourth loop of the plurality of fourth loops LPS4 substantially surrounds a region of a pixel driving circuit of a subpixel of the same color. In one example, the plurality of fourth loops LPS4 substantially surround regions of pixel driving circuits of red subpixels.

In some embodiments, the plurality of fourth loops LPS4 substantially surround regions having anodes of subpixels of a same color, respectively. A respective fourth loop of the plurality of fourth loops LPS4 substantially surrounds a region having an anode of a subpixel of the same color. In one example, the plurality of fourth loops LPS4 substantially surround regions having anodes of red subpixels.

FIG. 15 is a diagram illustrating alight emitting control signal network in a portion of an array substrate in some embodiments according to the present disclosure. In some embodiments, referring to FIG. 15, subpixels in the array substrate are arranged in rows and columns. In an m-th row of subpixels Rm, the array substrate includes a row of first subpixels. In a (m+)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 15.

In some embodiments, in an n-th column of subpixels Cn, the army substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 28, FIG. 3A to FIG. 3M, FIG. 5A to FIG. 5M, and FIG. 15, a first light emitting control signal line portion of the plurality of first light emitting control signal line portions em-1 in some embodiments is connected to gate electrodes of one or more light emitting control transistors in a pixel driving circuit in a third subpixel in the n-th column of subpixels Cn and the (m+1)-th row of subpixels R(m+1), is connected to gate electrodes of one or more light emitting control transistors in a pixel driving circuit in a first subpixel in the (n−1)-th column of subpixels C(n−1) and the m-th row of subpixels Rm, and is connected to gate electrodes of one or more light emitting control transistors in a pixel driving circuit in a second subpixel in the (n+1)-th column of subpixels C(n+1) and the (m+2)-th row of subpixels R(m+2).

In some embodiments, a second light emitting control signal line portion of the plurality of second light emitting control signal line portions em-2 connects the first light emitting control signal line portion with a first adjacent first light emitting control signal line portion, the first adjacent first light emitting control signal line portion is connected to gate electrodes of one or more light emitting control transistors in a pixel driving circuit in a second subpixel in the (n−1)-th column of subpixels C(n−1) and the (m+2)-th row of subpixels R(m+2).

In some embodiments, a third light emitting control signal line portion of the plurality of third light emitting control signal line portions em-3 connects the first light emitting control signal line portion with a second adjacent first light emitting control signal line portion, the second adjacent first light emitting control signal line portion is connected to gate electrodes of one or more light emitting control transistors in a pixel driving circuit in a first subpixel in the (n+1)-th column of subpixels C(n+1) and the m-th row of subpixels Rm.

Referring to FIG. 5A, FIG. 5C, FIG. 5H, and FIG. 8 to FIG. 15, the array substrate in some embodiments includes a plurality of signal lines, a respective signal line of the plurality of signal lines includes a plurality of first signal line portions and a plurality of second signal line portions. The plurality of first signal line portions and the plurality of second signal line portions are in two different layers. In one example, the plurality of first signal line portions are in the first conductive layer, and the plurality of second signal line portions are in the second signal line layer. In another example, the plurality of first signal line portions are in the second conductive layer, and the plurality of second signal line portions are in the second signal line layer. A respective second signal line portion of the plurality of second signal line portions is connected to two adjacent first signal line portions of the plurality of first signal line portions, respectively. Two adjacent first signal line portions of the plurality of first signal line portions are connected by an individual second signal line portion of the plurality of second signal line portions.

In some embodiments, a respective signal line of the plurality of signal lines includes a plurality of first signal line portions and a plurality of third signal line portions. The plurality of first signal line portions and the plurality of third signal line portions are in two different layers. In one example, the plurality of first signal line portions are in the first conductive layer, and the plurality of third signal line portions are in the second signal line layer. In another example, the plurality of first signal line portions are in the second conductive layer, and the plurality of third signal line portions are in the second signal line layer. A respective third signal line portion of the plurality of third signal line portions is connected to two adjacent first signal line portions of the plurality of first signal line portions in the same row, respectively. Two adjacent first signal line portions of the plurality of first signal line portions are connected by an individual third signal line portion of the plurality of third signal line portions.

In some embodiments, a respective signal line of the plurality of signal lines includes a plurality of first signal line portions, a plurality of second signal line portions, and a plurality of third signal line portions. The plurality of first signal line portions and the plurality of second signal line portions are in two different layers; and the plurality of first signal line portions and the plurality of third signal line portions are in two different layers. Optionally, the plurality of second signal line portions and the plurality of third signal line portions are in a same layer. In one example, the plurality of first signal line portions are in the first conductive layer, the plurality of second signal line portions are in the second signal line layer, and the plurality of third signal line portions are in the second signal line layer. In one example, the plurality of first signal line portions are in the second conductive layer, the plurality of second signal line portions are in the second signal line layer, and the plurality of third signal line portions are in the second signal line layer. In some embodiments, signal lines in the second signal line layer are made of a substantially transparent conductive material. In the plurality of light transmissive regions TR, signal lines of the second signal line layer are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second signal line portion of the plurality of second signal line portions is connected to two adjacent first signal line portions of the plurality of first signal line portions, respectively. A respective third signal line portion of the plurality of third signal line portions is connected to two adjacent first signal line portions of the plurality of first signal line portions, respectively. Two adjacent first signal line portions of the plurality of first signal line portions are connected by an individual second signal line portion of the plurality of second signal line portions, and connected by an individual third signal line portion of the plurality of third signal line portions. The two adjacent first signal line portions of the plurality of first signal line portions, the individual second signal line portion of the plurality of second signal line portions, and the individual third signal line portion of the plurality of third signal line portions form a loop substantially surrounding a region having transistors and capacitors of a pixel driving circuit of a subpixel. In one example, the loop substantially surrounds a region having transistors and capacitors of a respective first subpixel. In another example, the loop substantially surrounds a region having transistors and capacitors of a subpixel of a first color. In another example, the loop substantially surrounds a region having transistors and capacitors of a red subpixel.

In some embodiments, the array substrate includes a plurality of loops sequentially arranged in a row. Optionally, the plurality of loops substantially surround regions of pixel driving circuits of subpixels of a same color, respectively. A respective loop of the plurality of loops substantially surrounds a region of a pixel driving circuit of a subpixel of the same color. In one example, the plurality of loops substantially surround regions of pixel driving circuits of red subpixels.

In some embodiments, the plurality of loops substantially surround regions having anodes of subpixels of a same color, respectively. A respective loop of the plurality of loops substantially surrounds a region having an anode of a subpixel of the same color. In one example, the plurality of loops substantially surround regions having anodes of red subpixels.

In some embodiments, subpixels in the array substrate are arranged in rows and columns, in an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. The first color, the second color, and the third color are three different colors. In one example, the first color is a red color, the second color is green color, and the third color is a blue color.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 3A to FIG. 3M. FIG. 5A to FIG. 5M, and FIG. 8 to FIG. 15, a first signal line portion of the plurality of first signal line portions in some embodiments is connected to one or more transistors in a pixel driving circuit in a third subpixel in the n-th column of subpixels Cn and the (m+1)-th row of subpixels R(m+1), is connected to one or more transistors in a pixel driving circuit in a first subpixel in the (n−1)-th column of subpixels C(n−1) and the m-th row of subpixels Rm, and is connected to one or more transistors in a pixel driving circuit in a second subpixel in the (n+1)-th column of subpixels C(n+1) and the (m+2)-th row of subpixels R(m+2).

In some embodiments, a second signal line portion of the plurality of second signal line portions connects the first signal line portion with a first adjacent first signal line portion, the first adjacent first signal line portion is connected to one or more transistors in a pixel driving circuit in a second subpixel in the (n−1)-th column of subpixels C(n−1) and the (m+2)-th row of subpixels R(m+2).

In some embodiments, a third signal line portion of the plurality of third signal line portions connects the first signal line portion with a second adjacent first signal line portion, the second adjacent first signal line portion is connected to one or more transistors in a pixel driving circuit in a first subpixel in the (n+1)-th column of subpixels C(n+1) and the m-th row of subpixels Rm.

FIG. 16A is a diagram illustrating the structure of a portion of an array substrate in some embodiments according to the present disclosure. FIG. 16B is a diagram illustrating the structure of a semiconductor material layer in the portion of the array substrate depicted in FIG. 16A. FIG. 16C is a diagram illustrating the structure of a first conductive layer in the portion of the array substrate depicted in FIG. 16A. FIG. 16D is a diagram illustrating the structure of a second conductive layer in the portion of the array substrate depicted in FIG. 16A. FIG. 16E is a diagram illustrating the structure of an inter-layer dielectric layer in the portion of the array substrate depicted in FIG. 16A. FIG. 16F is a diagram illustrating the structure of a first signal line layer in the portion of the array substrate depicted in FIG. 16A. FIG. 16G is a diagram illustrating the structure of a passivation layer in the portion of the array substrate depicted in FIG. 16A. FIG. 16H is a diagram illustrating the structure of a second signal line layer in the portion of the array substrate depicted in FIG. 16A. FIG. 16I is a diagram illustrating the structure of a first planarization layer in the portion of the array substrate depicted in FIG. 16A. FIG. 16J is a diagram illustrating the structure of a third signal line layer in the portion of the array substrate depicted in FIG. 16A. FIG. 16K is a diagram illustrating the structure of a second planarization layer in the portion of the array substrate depicted in FIG. 16A. FIG. 16L is a diagram illustrating the structure of an anode layer in the portion of the array substrate depicted in FIG. 16A, FIG. 16M is a diagram illustrating the structure of a pixel definition layer in the portion of the array substrate depicted in FIG. 16A.

FIG. 17A is a diagram illustrating the structure of a portion of an array substrate in some embodiments according to the present disclosure. FIG. 17B is a diagram illustrating the structure of a semiconductor material layer in the portion of the array substrate depicted in FIG. 17A. FIG. 17C is a diagram illustrating the structure of a first conductive layer in the portion of the array substrate depicted in FIG. 17A. FIG. 17D is a diagram illustrating the structure of a second conductive layer in the portion of the array substrate depicted in FIG. 17A. FIG. 17E is a diagram illustrating the structure of an inter-layer dielectric layer in the portion of the array substrate depicted in FIG. 17A. FIG. 17F is a diagram illustrating the structure of a first signal line layer in the portion of the array substrate depicted in FIG. 17A. FIG. 17G is a diagram illustrating the structure of a passivation layer in the portion of the array substrate depicted in FIG. 17A. FIG. 171H is a diagram illustrating the structure of a second signal line layer in the portion of the array substrate depicted in FIG. 17A. FIG. 17I is a diagram illustrating the structure of a first planarization layer in the portion of the array substrate depicted in FIG. 17A. FIG. 17J is a diagram illustrating the structure of a third signal line layer in the portion of the array substrate depicted in FIG. 17A. FIG. 17K is a diagram illustrating the structure of a second planarization layer in the portion of the array substrate depicted in FIG. 17A. FIG. 17L is a diagram illustrating the structure of an anode layer in the portion of the array substrate depicted in FIG. 17A. FIG. 17M is a diagram illustrating the structure of a pixel definition layer in the portion of the array substrate depicted in FIG. 17A.

The array substrate depicted in FIG. 16A to FIG. 16M, and FIG. 17A to FIG. 17M differs from the array substrate depicted in FIG. 3A to FIG. 3M, and FIG. 5A to FIG. 5M in that the plurality of initialization signal lines, the plurality of reset control signal lines, the plurality of gate signal lines, and the plurality of light emitting control signal lines in the array substrate depicted in FIG. 16A to FIG. 16M, and FIG. 17A to FIG. 17M have different extension directions from the plurality of initialization signal lines, the plurality of reset control signal lines, the plurality of gate signal lines, and the plurality of light emitting control signal lines in the array substrate depicted in FIG. 3A to FIG. 3M, and FIG. 5A to FIG. 5M.

Referring to FIG. 2A, FIG. 2B, FIG. 16A, and FIG. 16B, a respective pixel driving circuit is annotated with labels indicating regions corresponding to the plurality of transistors in the respective pixel driving circuit, including the first transistor T1, the second transistor T2, the third transistor T3, the fourth transistor T4, the fifth transistor T5, the sixth transistor T6, and the driving transistor Td. The respective pixel driving circuit is further annotated with labels indicating components of each of the plurality of transistors in the pixel driving circuit. For example, the first transistor T1 includes an active layer ACT1, a first electrode S1, and a second electrode DL. The second transistor T2 includes an active layer ACT2, a first electrode S2, and a second electrode D2. The third transistor T3 includes an active layer ACT3, a first electrode S3, and a second electrode D3. The fourth transistor T4 includes an active layer ACT4, a first electrode S4, and a second electrode D4. The fifth transistor T5 includes an active layer ACT5, a first electrode S5, and a second electrode D5. The sixth transistor T6 includes an active layer ACT6, a first electrode S6, and a second electrode D6. The driving transistor Td includes an active layer ACTd, a first electrode Sd, and a second electrode Dd.

Referring to FIG. 2A, FIG. 2B, FIG. 16A, and FIG. 16C, the first conductive layer in some embodiments includes a plurality of reset control signal lines rst, a plurality of light emitting control signal lines em, a plurality of gate signal lines GL, and a first capacitor electrode Ce1 of the storage capacitor Cst.

Referring to FIG. 2A, FIG. 2B, FIG. 16A, and FIG. 16D, the second conductive layer in some embodiments includes a plurality of initialization signal lines Vint and a second capacitor electrode Ce2 of the storage capacitor Cst.

Vias extending through the inter-layer dielectric layer ILD are depicted in FIG. 16E.

Referring to FIG. 2A, FIG. 28, FIG. 16A, and FIG. 16F, the first signal line layer in some embodiments includes a node connecting line Cn, a voltage connecting pad VCP, a data signal connecting pad DCP, an electrode connecting line Cle, and a reset signal connecting line Cli.

The node connecting line Cin connects the first capacitor electrode Ce1 with the second electrode of the third transistor T3 and/or the second electrode of the first transistor T1 in a respective pixel driving circuit, respectively. The data signal connecting pad DCP connects a respective data line of the plurality of data lines with a first electrode of the second transistor T2. The reset signal connecting line Cli connects a respective initialization signal line of the plurality of initialization signal lines with first electrodes of the first transistor T1 and the sixth transistor T6. The voltage connecting pad VCP connects a respective voltage supply line of the plurality of voltage supply lines with a first electrode of the fourth transistor T4, and connects the respective voltage supply line of the plurality of voltage supply lines with the second capacitor electrode of the storage capacitor. The electrode connecting line Cle is connected to second electrodes of the fifth transistor T5 and the sixth transistor T6, respectively.

Vias extending through the passivation layer PVX are depicted in FIG. 16G.

Referring to FIG. 2A, FIG. 2B, FIG. 16A, and FIG. 16H, the second signal line layer in some embodiments includes a plurality of voltage supply lines Vdd and a plurality of data line DL. A respective voltage supply line of the plurality of voltage supply lines Vdd includes a plurality of first voltage supply line portions Vdd-1 and a plurality of second voltage supply line portions Vdd-2 alternately arranged. A respective first voltage supply line portion of the plurality of first voltage supply line portions Vdd-1 and a respective second voltage supply line portion of the plurality of second voltage supply line portions Vdd-2 are connected by a voltage connecting bridge in the third signal line layer. A respective data line of the plurality of data lines is electrically connected to a first electrode of the second transistor T2 through a data signal connecting pad in the first signal line layer.

Vias extending through the first planarization layer PLN1 are depicted in FIG. 16I.

Referring to FIG. 2A, FIG. 2B, FIG. 16A, and FIG. 16J, the third signal line layer in some embodiments includes a voltage connecting bridge VCB and an anode connecting pad ACP. The voltage connecting bridge VCB connects the first voltage supply line portion in the second signal line layer with the second voltage supply line portion in the second signal line layer. The anode connecting pad ACP is connected to the fourth node N4 and a respective anode in a respective subpixel, respectively. The anode connecting pad ACP is connected to second electrodes of the fifth transistor T5 and the sixth transistor T6, and the respective anode in the respective subpixel is connected to the anode connecting pad ACP.

Vias extending through the second planarization layer PLN2 are depicted in FIG. 16K.

Referring to FIG. 2A, FIG. 2B, FIG. 16A, and FIG. 16L, the anode layer in some embodiments includes an anode of the respective light emitting elements. The anode connects to the anode connecting pad in the third signal line layer, the anode connecting pad connects to second electrodes of the fifth transistor T5 and the sixth transistor T6.

Vias extending through the pixel definition layer PDL are depicted in FIG. 16M. Referring to FIG. 16M, the array substrate includes a subpixel aperture SA configured to receive a light emitting material.

In some embodiments, referring to FIG. 17A, a minimum repeating unit of the plurality of subpixels of the array substrate includes a respective first subpixel sp1, a respective second subpixel sp2, and a respective third subpixel sp3. The portion of the array substrate depicted in FIG. 16A corresponds to a portion of the respective third subpixel sp3 depicted in FIG. 17A.

In some embodiments, each of the respective first subpixel sp1, the respective second subpixel sp2, and the respective third subpixel sp3, includes the first transistor T1, the second transistor T2, the third transistor T3, the fourth transistor T4, the fifth transistor T5, the sixth transistor T6, the driving transistor Td, and the storage capacitor Cst.

In some embodiments, the respective first subpixel sp1 is a subpixel of a first color (e.g., a red color), the respective second subpixel sp2 is a subpixel of a second color (e.g., a green color), and the respective third subpixel sp3 is a subpixel of a third color (e.g., a blue color). In some embodiments, the respective first subpixel sp1, the respective second subpixel sp2, and the respective third subpixel sp3 are three subpixels of a pixel in the array substrate.

Referring to FIG. 17A, FIG. 17H, and FIG. 17J, in some embodiments, a respective voltage supply line of the plurality of voltage supply lines Vdd includes a plurality of first voltage supply line portions Vdd-1 and a plurality of second voltage supply line portions Vdd-2 alternately arranged in the second signal line layer. A respective first voltage supply line portion of the plurality of first voltage supply line portions Vdd-1 and a respective second voltage supply line portion of the plurality of second voltage supply line portions Vdd-2 are connected by a voltage connecting bridge VCB in the third signal line layer.

FIG. 18 is a diagram illustrating a voltage supply network in a portion of an array substrate in some embodiments according to the present disclosure. Referring to FIG. 17A, FIG. 17H, FIG. 17J, and FIG. 18, the array substrate in some embodiments includes a plurality of voltage connecting bridges VCBS. Optionally, the plurality of voltage connecting bridges VCBS are arranged in an array of rows and columns. The plurality of voltage supply lines Vdd includes a first adjacent voltage supply line AVdd1, a second adjacent voltage supply line AVdd2, and a third adjacent voltage supply line AVdd3. Optionally, the first adjacent voltage supply line AVdd1 is configured to provide a voltage supply signal to a first pixel driving circuit in the respective first subpixel Sp1, the second adjacent voltage supply line AVdd2 is configured to provide a voltage supply signal to a second pixel driving circuit in the respective second subpixel Sp2, and the third adjacent voltage supply line AVdd3 is configured to provide a voltage supply signal to a third pixel driving circuit in the respective third subpixel Sp3.

In some embodiments, a respective voltage connecting bridge of the plurality of voltage connecting bridges VCBS is connected to the first adjacent voltage supply line AVdd1, the second adjacent voltage supply line AVdd2, and the third adjacent voltage supply line AVdd3, respectively.

In some embodiments, each of the first adjacent voltage supply line AVdd1, the second adjacent voltage supply line AVdd2, and the third adjacent voltage supply line AVdd3 includes a plurality of first voltage supply line portions Vdd-1 and a plurality of second voltage supply line portions Vdd-2 alternately arranged in the second signal line layer. In some embodiments, the respective voltage connecting bridge of the plurality of voltage connecting bridges VCBS is connected to a first adjacent voltage supply line portion AVdd-1 and a second adjacent voltage supply line portion AVdd-2 of the first adjacent voltage supply line AVdd1, respectively, is connected to a first adjacent voltage supply line portion AVdd-1 and a second adjacent voltage supply line portion AVdd-2 of the second adjacent voltage supply line AVdd2, respectively, and is connected to a first adjacent voltage supply line portion AVdd-1 and a second adjacent voltage supply line portion AVdd-2 of third adjacent voltage supply line AVdd3, respectively.

In some embodiments, the plurality of voltage supply lines (including the first adjacent voltage supply line AVdd1, the second adjacent voltage supply line AVdd2, and the third adjacent voltage supply line AVdd3) are in the second signal line layer, and the plurality of voltage connecting bridges VCBS are in the third signal line layer.

In some embodiments, signal lines in the second signal line layer are made of a substantially transparent conductive material, allowing the presence of a plurality of light transmissive regions in the array substrate. FIG. 19 is a diagram illustrating the structure of a portion of an array substrate in some embodiments according to the present disclosure. Referring to FIG. 19, the array substrate in some embodiments includes a plurality of light transmissive regions TR allowing light transmit therethrough. In the plurality of light transmissive regions TR, signal lines of the second signal line layer (e.g., the plurality of data lines, the plurality of first voltage supply line portions, and the plurality of second voltage supply line portions) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, two adjacent voltage connecting bridges of the plurality of voltage connecting bridges VCBS in a same pixel row are connected to a same voltage supply line of the plurality of voltage supply lines, as shown in FIG. 18. Referring to FIG. 9, a pixel row in some embodiments includes an m-th row of subpixels Rm, a (m+1)-th row of subpixels R(m+1), and a (m+2)-th row of subpixels R(m+2).

In some embodiments, voltage connecting bridges of the plurality of voltage connecting bridges VCBS in a same pixel column are connected to the same three adjacent voltage supply lines of the plurality of voltage supply lines. Referring to FIG. 9, a pixel column in some embodiments includes a (n−1)-th column of subpixels C(n−1), an n-th column of subpixels Cn, and a (n+1)-th column of subpixels C(n+1).

In some embodiments, the array substrate is a full display with camera (FDC) array substrate, wherein the array substrate further includes photosensors in the plurality of light transmissive regions TR configured to detect light.

FIG. 20 is a diagram illustrating a reset signal network in a portion of an array substrate in some embodiments according to the present disclosure. Referring to FIG. 17A, FIG. 17D, FIG. 17H, and FIG. 20, a respective initialization signal line of the plurality of initialization signal lines includes a plurality of first initialization signal line portions Vint-1 and a plurality of second initialization signal line portions Vint-2. The plurality of first initialization signal line portions Vint-1 and the plurality of second initialization signal line portions Vint-2 are in two different layers. In one example, the plurality of first initialization signal line portions Vint-1 are in the second conductive layer, and the plurality of second initialization signal line portions Vint-2 are in the second signal line layer. A respective second initialization signal line portion of the plurality of second initialization signal line portions Vint-2 is connected to two adjacent first initialization signal line portions of the plurality of first initialization signal line portions Vint-1, respectively. Two adjacent first initialization signal line portions of the plurality of first initialization signal line portions Vint-1 are connected by an individual second initialization signal line portion of the plurality of second initialization signal line portions Vint-2.

In some embodiments, a respective initialization signal line of the plurality of initialization signal lines includes a plurality of first initialization signal line portions Vint-1 and a plurality of third initialization signal line portions Vint-3. The plurality of first initialization signal line portions Vint-1 and the plurality of third initialization signal line portions Vint-3 are in two different layers. In one example, the plurality of first initialization signal line portions Vint-1 are in the second conductive layer, and the plurality of third initialization signal line portions Vint-3 are in the second signal line layer. A respective third initialization signal line portion of the plurality of third initialization signal line portions Vint-3 is connected to two adjacent first initialization signal line portions of the plurality of first initialization signal line portions Vint-1 in the same row, respectively. Two adjacent first initialization signal line portions of the plurality of first initialization signal line portions Vint-1 are connected by an individual third initialization signal line portion of the plurality of third initialization signal line portions Vint-3.

In some embodiments, a respective initialization signal line of the plurality of initialization signal lines includes a plurality of first initialization signal line portions Vint-1, a plurality of second initialization signal line portions Vint-2, and a plurality of third initialization signal line portions Vint-3. The plurality of first initialization signal line portions Vint-1 and the plurality of second initialization signal line portions Vint-2 are in two different layers; and the plurality of first initialization signal line portions Vint-1 and the plurality of third initialization signal line portions Vint-3 are in two different layers. Optionally, the plurality of second initialization signal line portions Vint-2 and the plurality of third initialization signal line portions Vint-3 are in a same layer. In one example, the plurality of first initialization signal line portions Vint-1 are in the second conductive layer, the plurality of second initialization signal line portions Vint-2 are in the second signal line layer, and the plurality of third initialization signal line portions Vint-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second initialization signal line portions Vint-2, and the plurality of third initialization signal line portions Vint-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second initialization signal line portion of the plurality of second initialization signal line portions Vint-2 is connected to two adjacent first initialization signal line portions of the plurality of first initialization signal line portions Vint-1, respectively. A respective third initialization signal line portion of the plurality of third initialization signal line portions Vint-3 is connected to two adjacent first initialization signal line portions of the plurality of first initialization signal line portions Vint-1, respectively. Two adjacent first initialization signal line portions of the plurality of first initialization signal line portions Vim-1 are connected by an individual second initialization signal line portion of the plurality of second initialization signal line portions Vint-2, and connected by an individual third initialization signal line portion of the plurality of third initialization signal line portions Vint-3. The two adjacent first initialization signal line portions of the plurality of first initialization signal line portions Vint-1, the individual second initialization signal line portion of the plurality of second initialization signal line portions Vint-2, and the individual third initialization signal line portion of the plurality of third initialization signal line portions Vint-3 form a first loop substantially surrounding a region having transistors and capacitors of a pixel driving circuit of a subpixel. In one example, the first loop substantially surrounds a region having transistors and capacitors of a respective first subpixel. In another example, the first loop substantially surrounds a region having transistors and capacitors of a subpixel of a first color. In another example, the first loop substantially surrounds a region having transistors and capacitors of a red subpixel.

In some embodiments, the array substrate includes a plurality of first loops LPS1 sequentially arranged in a row. Optionally, the plurality of first loops LPS1 substantially surround regions of pixel driving circuits of subpixels of a same color, respectively. A respective first loop of the plurality of first loops LPS1 substantially surrounds a region of a pixel driving circuit of a subpixel of the same color. In one example, the plurality of first loops LPS1 substantially surround regions of pixel driving circuits of red subpixels.

In some embodiments, the plurality of first loops LPS1 substantially surround regions having anodes of subpixels of a same color, respectively. A respective first loop of the plurality of first loops LPS1 substantially surrounds a region having an anode of a subpixel of the same color. In one example, the plurality of first loops LPS1 substantially surround regions having anodes of red subpixels.

FIG. 21 is a diagram illustrating a reset signal network in a portion of an army substrate in some embodiments according to the present disclosure. In some embodiments, referring to FIG. 21, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 21.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 28, FIG. 16A to FIG. 16M, FIG. 17A to FIG. 17M, and FIG. 21, a first initialization signal line portion of the plurality of first initialization signal line portions Vint-1 in some embodiments is connected to first electrodes of one or more reset transistors in a pixel driving circuit in a third subpixel in the n-th column of subpixels Cn and the (m+1)-th row of subpixels R(m+1), is connected to first electrodes of one or more reset transistors in a pixel driving circuit in a second subpixel in the (n−1)-th column of subpixels C(n−1) and the (m+2)-th row of subpixels Rm, and is connected to first electrodes of one or more reset transistors in a pixel driving circuit in a first subpixel in the (n+1)-th column of subpixels C(n+1) and the m-th row of subpixels Rm.

In some embodiments, a second initialization signal line portion of the plurality of second initialization signal line portions Vint-2 connects the first initialization signal line portion with a first adjacent first initialization signal line portion, the first adjacent first initialization signal line portion is connected to first electrodes of one or more reset transistors in a pixel driving circuit in a first subpixel in the (n−1)-th column of subpixels C(n−1) and the m-th row of subpixels Rm.

In some embodiments, a third initialization signal line portion of the plurality of third initialization signal line portions Vint-3 connects the first initialization signal line portion with a second adjacent first initialization signal line portion, the second adjacent first initialization signal line portion is connected to first electrodes of one or more reset transistors in a pixel driving circuit in a second subpixel in the (n+1)-th column of subpixels C(n+1) and the (m+2)-th row of subpixels R(m+2).

FIG. 22 is a diagram illustrating a gate scanning signal network in a portion of an array substrate in some embodiments according to the present disclosure. Referring to FIG. 17A, FIG. 17C, FIG. 17H, and FIG. 22, a respective gate signal line of the plurality of gate signal lines includes a plurality of first gate signal line portions GL-1 and a plurality of second gate signal line portions GL-2. The plurality of first gate signal line portions GL-1 and the plurality of second gate signal line portions GL-2 are in two different layers, to one example, the plurality of first gate signal line portions GL-1 are in the first conductive layer, and the plurality of second gate signal line portions GL-2 are in the second signal line layer. A respective second gate signal line portion of the plurality of second gate signal line portions GL-2 is connected to two adjacent first gate signal line portions of the plurality of first gate signal line portions GL-1, respectively. Two adjacent first gate signal line portions of the plurality of first gate signal line portions GL-1 are connected by an individual second gate signal line portion of the plurality of second gate signal line portions GL-2.

In some embodiments, a respective gate signal line of the plurality of gate signal lines includes a plurality of first gate signal line portions GL-1 and a plurality of third gate signal line portions GL-3. The plurality of first gate signal line portions GL-1 and the plurality of third gate signal line portions GL-3 are in two different layers. In one example, the plurality of first gate signal line portions GL-A are in the first conductive layer, and the plurality of third gate signal line portions GL-3 are in the second signal line layer. A respective third gate signal line portion of the plurality of third gate signal line portions GL-3 is connected to two adjacent first gate signal line portions of the plurality of first gate signal line portions GL-1 in the same row, respectively. Two adjacent first gate signal line portions of the plurality of first gate signal line portions GL-1 are connected by an individual third gate signal line portion of the plurality of third gate signal line portions GL-3.

In some embodiments, a respective gate signal line of the plurality of gate signal lines includes a plurality of first gate signal line portions GL-1, a plurality of second gate signal line portions GL-2, and a plurality of third gate signal line portions GL-3. The plurality of first gate signal line portions GL-1 and the plurality of second gate signal line portions GL-2 are in two different layers; and the plurality of first gate signal line portions GL-1 and the plurality of third gate signal line portions GL-3 are in two different layers. Optionally, the plurality of second gate signal line portions GL-2 and the plurality of third gate signal line portions GL-3 are in a same layer. In one example, the plurality of first gate signal line portions GL-1 are in the first conductive layer, the plurality of second gate signal line portions GL-2 are in the second signal line layer, and the plurality of third gate signal line portions GL-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second gate signal line portions GL-2, and the plurality of third gate signal line portions GL-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second gate signal line portion of the plurality of second gate signal line portions GL-2 is connected to two adjacent first gate signal line portions of the plurality of first gate signal line portions GL-1, respectively. A respective third gate signal line portion of the plurality of third gate signal line portions GL-3 is connected to two adjacent first gate signal line portions of the plurality of first gate signal line portions GL-1, respectively. Two adjacent first gate signal line portions of the plurality of first gate signal line portions GL-1 are connected by an individual second gate signal line portion of the plurality of second gate signal line portions GL-2, and connected by an individual third gate signal line portion of the plurality of third gate signal line portions GIL-3. The two adjacent first gate signal line portions of the plurality of first gate signal line portions GL-1, the individual second gate signal line portion of the plurality of second gate signal line portions GL-2, and the individual third gate signal line portion of the plurality of third gate signal line portions G1-3 form a second loop substantially surrounding a region having transistors and capacitors of a pixel driving circuit of a subpixel. In one example, the second loop substantially surrounds a region having transistors and capacitors of a respective first subpixel. In another example, the second loop substantially surrounds a region having transistors and capacitors of a subpixel of a first color. In another example, the second loop substantially surrounds a region having transistors and capacitors of a red subpixel.

In some embodiments, the array substrate includes a plurality of second loops LPS2 sequentially arranged in a row. Optionally, the plurality of second loops LPS2 substantially surround regions of pixel driving circuits of subpixels of a same color, respectively. A respective second loop of the plurality of second loops LPS2 substantially surrounds a region of a pixel driving circuit of a subpixel of the same color. In one example, the plurality of second loops LPS2 substantially surround regions of pixel driving circuits of red subpixels.

In some embodiments, the plurality of second loops LPS2 substantially surround regions having anodes of subpixels of a same color, respectively. A respective second loop of the plurality of second loops LPS2 substantially surrounds a region having an anode of a subpixel of the same color. In one example, the plurality of second loops LPS2 substantially surround regions having anodes of red subpixels.

FIG. 23 is a diagram illustrating a gate scanning signal network in a portion of an array substrate in some embodiments according to the present disclosure. In some embodiments, referring to FIG. 23, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 23.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 16A to FIG. 16M, FIG. 17A to FIG. 17M, and FIG. 23, a first gate signal line portion of the plurality of first gate signal line portions GL-1 in some embodiments is connected to gate electrodes of one or more data write transistors in a pixel driving circuit in a third subpixel in the n-th column of subpixels Cn and the (m+1)-th row of subpixels R(m+1), is connected to gate electrodes of one or more data write transistors in a pixel driving circuit in a second subpixel in the (n−1)-th column of subpixels C(n−1) and the (m+2)-th row of subpixels R(m+2), and is connected to gate electrodes of one or more data write transistors in a pixel driving circuit in a first subpixel in the (n+1)-th column of subpixels C(n+1) and the m-th row of subpixels Rm.

In some embodiments, a second gate signal line portion of the plurality of second gate signal line portions GL-2 connects the first gate signal line portion with a first adjacent first gate signal line portion, the first adjacent first gate signal line portion is connected to gate electrodes of one or more data write transistors in a pixel driving circuit in a first subpixel in the (n−1)-th column of subpixels C(n−1) and the m-th row of subpixels Rm.

In some embodiments, a third gate signal line portion of the plurality of third gate signal line portions GL-3 connects the first gate signal line portion with a second adjacent first gate signal line portion, the second adjacent first gate signal line portion is connected to gate electrodes of one or more data write transistors in a pixel driving circuit in a second subpixel in the (n+1)-th column of subpixels C(n+1) and the (m+2)-th row of subpixels R(m+2).

FIG. 24 is a diagram illustrating a reset control signal network in a portion of an array substrate in some embodiments according to the present disclosure. Referring to FIG. 17A, FIG. 17C, FIG. 17H, and FIG. 24, a respective reset control signal line of the plurality of reset control signal lines includes a plurality of first reset control signal line portions rst-1 and a plurality of second reset control signal line portions rst-2. The plurality of first reset control signal line portions rst-1 and the plurality of second reset control signal line portions rst-2 are in two different layers. In one example, the plurality of first reset control signal line portions rst-1 are in the first conductive layer, and the plurality of second reset control signal line portions rst-2 are in the second signal line layer. A respective second reset control signal line portion of the plurality of second reset control signal line portions rst-2 is connected to two adjacent first reset control signal line portions of the plurality of first reset control signal line portions rst-1, respectively. Two adjacent first reset control signal line portions of the plurality of first reset control signal line portions rst-1 are connected by an individual second reset control signal line portion of the plurality of second reset control signal line portions rst-2.

In some embodiments, a respective reset control signal line of the plurality of reset control signal lines includes a plurality of first reset control signal line portions rst-1 and a plurality of third reset control signal line portions rst-3. The plurality of first reset control signal line portions rst-1 and the plurality of third reset control signal line portions rst-3 are in two different layers. In one example, the plurality of first reset control signal line portions rst-1 are in the fast conductive layer, and the plurality of third reset control signal line portions rst-3 are in the second signal line layer. A respective third reset control signal line portion of the plurality of third reset control signal line portions rst-3 is connected to two adjacent first reset control signal line portions of the plurality of first reset control signal line portions rst-1 in the same row, respectively. Two adjacent first reset control signal line portions of the plurality of first reset control signal line portions rst-1 are connected by an individual third reset control signal line portion of the plurality of third reset control signal line portions rst-3.

In some embodiments, a respective reset control signal line of the plurality of reset control signal lines includes a plurality of first reset control signal line portions rst-1, a plurality of second reset control signal line portions rst-2, and a plurality of third reset control signal line portions rst-3. The plurality of first reset control signal line portions rst-1 and the plurality of second reset control signal line portions rst-2 are in two different layers; and the plurality of first reset control signal line portions rst-1 and the plurality of third reset control signal line portions rst-3 are in two different layers. Optionally, the plurality of second reset control signal line portions rst-2 and the plurality of third reset control signal line portions rst-3 are in a same layer. In one example, the plurality of first reset control signal line portions rst-1 are in the first conductive layer, the plurality of second reset control signal line portions rst-2 are in the second signal line layer, and the plurality of third reset control signal line portions rst-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second reset control signal line portions rst-2, and the plurality of third reset control signal line portions rst-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second reset control signal line portion of the plurality of second reset control signal line portions rst-2 is connected to two adjacent first reset control signal line portions of the plurality of first reset control signal line portions rst-1, respectively. A respective third reset control signal line portion of the plurality of third reset control signal line portions rst-3 is connected to two adjacent first reset control signal line portions of the plurality of first reset control signal line portions rst-1, respectively. Two adjacent first reset control signal line portions of the plurality of first reset control signal line portions rst-1 are connected by an individual second reset control signal line portion of the plurality of second reset control signal line portions rst-2, and connected by an individual third reset control signal line portion of the plurality of third reset control signal line portions rst-3. The two adjacent first reset control signal line portions of the plurality of first reset control signal line portions rst-1, the individual second reset control signal line portion of the plurality of second reset control signal line portions rst-2, and the individual third reset control signal line portion of the plurality of third reset control signal line portions rst-3 form a third loop substantially surrounding a region having transistors and capacitors of a pixel driving circuit of a subpixel. In one example, the third loop substantially surrounds a region having transistors and capacitors of a respective first subpixel. In another example, the third loop substantially surrounds a region having transistors and capacitors of a subpixel of a first color. In another example, the third loop substantially surrounds a region having transistors and capacitors of a red subpixel.

In some embodiments, the array substrate includes a plurality of third loops LPS3 sequentially arranged in a row. Optionally, the plurality of third loops LPS3 substantially surround regions of pixel driving circuits of subpixels of a same color, respectively. A respective third loop of the plurality of third loops LPS3 substantially surrounds a region of a pixel driving circuit of a subpixel of the same color. In one example, the plurality of third loops LPS3 substantially surround regions of pixel driving circuits of red subpixels.

In some embodiments, the plurality of third loops LPS3 substantially surround regions having anodes of subpixels of a same color, respectively. A respective third loop of the plurality of third loops LPS3 substantially surrounds a region having an anode of a subpixel of the same color. In one example, the plurality of third loops LPS3 substantially surround regions having anodes of red subpixels.

FIG. 25 is a diagram illustrating a reset control signal network in a portion of an array substrate in some embodiments according to the present disclosure. In some embodiments, referring to FIG. 25, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 25.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 16A to FIG. 16M, FIG. 17A to FIG. 17M, and FIG. 25, a first reset control signal line portion of the plurality of first reset control signal line portions rst-1 in some embodiments is connected to gate electrodes of one or more reset control transistors in a pixel driving circuit in a third subpixel in the n-th column of subpixels Cn and the (m+1)-th row of subpixels R(m+1), is connected to gate electrodes of one or more reset control transistors in a pixel driving circuit in a second subpixel in the (n−1)-th column of subpixels C(n−1) and the (m+2)-th row of subpixels R(m+2), and is connected to gate electrodes of one or more reset control transistors in a pixel driving circuit in a first subpixel in the (n+1)-th column of subpixels C(n+1) and the m-th row of subpixels Rm.

In some embodiments, a second reset control signal line portion of the plurality of second reset control signal line portions rst-2 connects the first reset control signal line portion with a first adjacent first reset control signal line portion, the first adjacent first reset control signal line portion is connected to gate electrodes of one or more reset control transistors in a pixel driving circuit in a first subpixel in the (n−1)-th column of subpixels C(n−1) and the m-th row of subpixels Rm.

In some embodiments, a third reset control signal line portion of the plurality of third reset control signal line portions rst-3 connects the first reset control signal line portion with a second adjacent first reset control signal line portion, the second adjacent first reset control signal line portion is connected to gate electrodes of one or more reset control transistors in a pixel driving circuit in a second subpixel in the (n+1)-th column of subpixels C(n+1) and the (m+2)-th row of subpixels R(m+2).

FIG. 26 is a diagram illustrating a light emitting control signal network in a portion of an array substrate in some embodiments according to the present disclosure. Referring to FIG. 17A, FIG. 17C, FIG. 17H, and FIG. 26, a respective light emitting control signal line of the plurality of light emitting control signal lines includes a plurality of first light emitting control signal line portions em-1 and a plurality of second light emitting control signal line portions em-2. The plurality of first light emitting control signal line portions em-1 and the plurality of second light emitting control signal line portions em-2 are in two different layers. In one example, the plurality of first light emitting control signal line portions em-1 are in the first conductive layer, and the plurality of second light emitting control signal line portions em-2 are in the second signal line layer. A respective second light emitting control signal line portion of the plurality of second light emitting control signal line portions em-2 is connected to two adjacent first light emitting control signal line portions of the plurality of first light emitting control signal line portions em-1, respectively. Two adjacent first light emitting control signal line portions of the plurality of first light emitting control signal line portions em-1 are connected by an individual second light emitting control signal line portion of the plurality of second light emitting control signal line portions em-2.

In some embodiments, a respective light emitting control signal line of the plurality of light emitting control signal lines includes a plurality of first light emitting control signal line portions em-1 and a plurality of third light emitting control signal line portions em-3. The plurality of first light emitting control signal line portions em-1 and the plurality of third light emitting control signal line portions em-3 are in two different layers. In one example, the plurality of first light emitting control signal line portions em-1 are in the first conductive layer, and the plurality of third light emitting control signal line portions em-3 are in the second signal line layer. A respective third light emitting control signal line portion of the plurality of third light emitting control signal line portions em-3 is connected to two adjacent first light emitting control signal line portions of the plurality of first light emitting control signal line portions em-1 in the same row, respectively. Two adjacent first light emitting control signal line portions of the plurality of first light emitting control signal line portions em-1 are connected by an individual third light emitting control signal line portion of the plurality of third light emitting control signal line portions em-3.

In some embodiments, a respective light emitting control signal line of the plurality of light emitting control signal lines includes a plurality of first light emitting control signal line portions em-1, a plurality of second light emitting control signal line portions em-2, and a plurality of third light emitting control signal line portions em-3. The plurality of first light emitting control signal line portions em-1 and the plurality of second light emitting control signal line portions em-2 are in two different layers; and the plurality of first light emitting control signal line portions em-1 and the plurality of third light emitting control signal line portions em-3 are in two different layers. Optionally, the plurality of second light emitting control signal line portions em-2 and the plurality of third light emitting control signal line portions em-3 are in a same layer. In one example, the plurality of first light emitting control signal line portions em-1 are in the first conductive layer, the plurality of second light emitting control signal line portions em-2 are in the second signal line layer, and the plurality of third light emitting control signal line portions em-3 are in the second signal line layer. In some embodiments, signal lines in the second signal line layer are made of a substantially transparent conductive material. In the plurality of light transmissive regions TR, signal lines of the second signal line layer (e.g., the plurality of data lines, the plurality of first voltage supply line portions, the plurality of second voltage supply line portions, the plurality of second light emitting control signal line portions em-2, and the plurality of third light emitting control signal line portions em-3) are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second light emitting control signal line portion of the plurality of second light emitting control signal line portions em-2 is connected to two adjacent first light emitting control signal line portions of the plurality of first light emitting control signal line portions em-1, respectively. A respective third light emitting control signal line portion of the plurality of third light emitting control signal line portions em-3 is connected to two adjacent first light emitting control signal line portions of the plurality of first light emitting control signal line portions em-1, respectively. Two adjacent first light emitting control signal line portions of the plurality of first light emitting control signal line portions em-1 are connected by an individual second light emitting control signal line portion of the plurality of second light emitting control signal line portions em-2, and connected by an individual third light emitting control signal line portion of the plurality of third light emitting control signal line portions em-3. The two adjacent first light emitting control signal line portions of the plurality of first light emitting control signal line portions em-1, the individual second light emitting control signal line portion of the plurality of second light emitting control signal line portions em-2, and the individual third light emitting control signal line portion of the plurality of third light emitting control signal line portions em-3 form a fourth loop substantially surrounding a region having transistors and capacitors of a pixel driving circuit of a subpixel. In one example, the fourth loop substantially surrounds a region having transistors and capacitors of a respective first subpixel. In another example, the fourth loop substantially surrounds a region having transistors and capacitors of a subpixel of a first color. In another example, the fourth loop substantially surrounds a region having transistors and capacitors of a red subpixel.

In some embodiments, the array substrate includes a plurality of fourth loops LPS4 sequentially arranged in a row. Optionally, the plurality of fourth loops LPS4 substantially surround regions of pixel driving circuits of subpixels of a same color, respectively. A respective fourth loop of the plurality of fourth loops LPS4 substantially surrounds a region of a pixel driving circuit of a subpixel of the same color. In one example, the plurality of fourth loops LPS4 substantially surround regions of pixel driving circuits of red subpixels.

In some embodiments, the plurality of fourth loops LPS4 substantially surround regions having anodes of subpixels of a same color, respectively. A respective fourth loop of the plurality of fourth loops LPS4 substantially surrounds a region having an anode of a subpixel of the same color. In one example, the plurality of fourth loops LPS4 substantially surround regions having anodes of red subpixels.

FIG. 27 is a diagram illustrating a light emitting control signal network in a portion of an array substrate in some embodiments according to the present disclosure. In some embodiments, referring to FIG. 27, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 27.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 16A to FIG. 16M, FIG. 17A to FIG. 17M, and FIG. 27, a first light emitting control signal line portion of the plurality of first light emitting control signal line portions em-1 in some embodiments is connected to gate electrodes of one or more light emitting control transistors in a pixel driving circuit in a third subpixel in the n-th column of subpixels Cn and the (m+1)-th row of subpixels R(m+1), is connected to gate electrodes of one or more light emitting control transistors in a pixel driving circuit in a second subpixel in the (n−1)-th column of subpixels C(n−1) and the (m+2)-th row of subpixels R(m+2), and is connected to gate electrodes of one or more light emitting control transistors in a pixel driving circuit in a first subpixel in the (n+1)-th column of subpixels C(n+1) and the m-th row of subpixels Rm.

In some embodiments, a second light emitting control signal line portion of the plurality of second light emitting control signal line portions em-2 connects the first light emitting control signal line portion with a first adjacent first light emitting control signal line portion, the first adjacent first light emitting control signal line portion is connected to gate electrodes of one or more light emitting control transistors in a pixel driving circuit in a first subpixel in the (n−1)-th column of subpixels C(n−1) and the m-th row of subpixels Rm.

In some embodiments, a third light emitting control signal line portion of the plurality of third light emitting control signal line portions em-3 connects the first light emitting control signal line portion with a second adjacent first light emitting control signal line portion, the second adjacent first light emitting control signal line portion is connected to gate electrodes of one or more light emitting control transistors in a pixel driving circuit in a second subpixel in the (n+1)-th column of subpixels C(n+1) and the (m+2)-th row of subpixels R(m+2).

Referring to FIG. 17A, FIG. 17C, FIG. 17H, and FIG. 20 to FIG. 27, the array substrate in some embodiments includes a plurality of signal lines, a respective signal line of the plurality of signal lines includes a plurality of first signal line portions and a plurality of second signal line portions. The plurality of first signal line portions and the plurality of second signal line portions are in two different layers. In one example, the plurality of first signal line portions are in the first conductive layer, and the plurality of second signal line portions are in the second signal line layer. In another example, the plurality of first signal line portions are in the second conductive layer, and the plurality of second signal line portions are in the second signal line layer. A respective second signal line portion of the plurality of second signal line portions is connected to two adjacent first signal line portions of the plurality of first signal line portions, respectively. Two adjacent first signal line portions of the plurality of first signal line portions are connected by an individual second signal line portion of the plurality of second signal line portions.

In some embodiments, a respective signal line of the plurality of signal lines includes a plurality of first signal line portions and a plurality of third signal line portions. The plurality of first signal line portions and the plurality of third signal line portions are in two different layers. In one example, the plurality of first signal line portions are in the first conductive layer, and the plurality of third signal line portions are in the second signal line layer. In another example, the plurality of first signal line portions are in the second conductive layer, and the plurality of third signal line portions are in the second signal line layer. A respective third signal line portion of the plurality of third signal line portions is connected to two adjacent first signal line portions of the plurality of first signal line portions in the same row, respectively. Two adjacent first signal line portions of the plurality of first signal line portions are connected by an individual third signal line portion of the plurality of third signal line portions.

In some embodiments, a respective signal line of the plurality of signal lines includes a plurality of first signal line portions, a plurality of second signal line portions, and a plurality of third signal line portions. The plurality of first signal line portions and the plurality of second signal line portions are in two different layers; and the plurality of first signal line portions and the plurality of third signal line portions are in two different layers. Optionally, the plurality of second signal line portions and the plurality of third signal line portions are in a same layer. In one example, the plurality of first signal line portions are in the first conductive layer, the plurality of second signal line portions are in the second signal line layer, and the plurality of third signal line portions are in the second signal line layer. In one example, the plurality of first signal line portions are in the second conductive layer, the plurality of second signal line portions are in the second signal line layer, and the plurality of third signal line portions are in the second signal line layer. In some embodiments, signal lines in the second signal line layer are made of a substantially transparent conductive material. In the plurality of light transmissive regions TR, signal lines of the second signal line layer are present, whereas signal lines and electrodes of the first conductive layer, the second conductive layer, the first signal line layer, the third signal line layer, and the anode layer are absent. Because the signal lines of the second signal line layer are made of a substantially transparent conductive material, light can transmit through the plurality of light transmissive regions TR.

In some embodiments, a respective second signal line portion of the plurality of second signal line portions is connected to two adjacent first signal line portions of the plurality of first signal line portions, respectively. A respective third signal line portion of the plurality of third signal line portions is connected to two adjacent first signal line portions of the plurality of first signal line portions, respectively. Two adjacent first signal line portions of the plurality of first signal line portions are connected by an individual second signal line portion of the plurality of second signal line portions, and connected by an individual third signal line portion of the plurality of third signal line portions. The two adjacent first signal line portions of the plurality of first signal line portions, the individual second signal line portion of the plurality of second signal line portions, and the individual third signal line portion of the plurality of third signal line portions form a loop substantially surrounding a region having transistors and capacitors of a pixel driving circuit of a subpixel. In one example, the loop substantially surrounds a region having transistors and capacitors of a respective first subpixel. In another example, the loop substantially surrounds a region having transistors and capacitors of a subpixel of a first color. In another example, the loop substantially surrounds a region having transistors and capacitors of a red subpixel.

In some embodiments, the array substrate includes a plurality of loops sequentially arranged in a row. Optionally, the plurality of loops substantially surround regions of pixel driving circuits of subpixels of a same color, respectively. A respective loop of the plurality of loops substantially surrounds a region of a pixel driving circuit of a subpixel of the same color. In one example, the plurality of loops substantially surround regions of pixel driving circuits of red subpixels.

In some embodiments, the plurality of loops substantially surround regions having anodes of subpixels of a same color, respectively. A respective loop of the plurality of loops substantially surrounds a region having an anode of a subpixel of the same color. In one example, the plurality of loops substantially surround regions having anodes of red subpixels.

In some embodiments, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. The first color, the second color, and the third color are three different colors. In one example, the first color is a red color, the second color is green color, and the third color is a blue color.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 16A to FIG. 16M. FIG. 17A to FIG. 17M, and FIG. 20 to FIG. 27, a first signal line portion of the plurality of first signal line portions in some embodiments is connected to one or more transistors in a pixel driving circuit in a third subpixel in the n-th column of subpixels Cn and the (m+1)-th row of subpixels R(m+1), is connected to one or more transistors in a pixel driving circuit in a second subpixel in the (n−1)-th column of subpixels C(n−1) and the (m+2)-th row of subpixels R(m+2), and is connected to one or more transistors in a pixel driving circuit in a first subpixel in the (n+1)-th column of subpixels C(n+1) and the m-th row of subpixels Rm.

In some embodiments, a second signal line portion of the plurality of second signal line portions connects the first signal line portion with a first adjacent first signal line portion, the first adjacent first signal line portion is connected to one or more transistors in a pixel driving circuit in a first subpixel in the (n−1)-th column of subpixels C(n−1) and the m-th row of subpixels Rm.

In some embodiments, a third signal line portion of the plurality of third signal line portions connects the first signal line portion with a second adjacent first signal line portion, the second adjacent first signal line portion is connected to one or more transistors in a pixel driving circuit in a second subpixel in the (n+1)-th column of subpixels C(n+1) and the (m+2)-th row of subpixels R(m+2).

FIG. 28A is a diagram illustrating the structure of a portion of an array substrate in some embodiments according to the present disclosure. FIG. 28B is a diagram illustrating the structure of a semiconductor material layer in the portion of the array substrate depicted in FIG. 28A. FIG. 28C is a diagram illustrating the structure of a first conductive layer in the portion of the array substrate depicted in FIG. 28A. FIG. 28D is a diagram illustrating the structure of a second conductive layer in the portion of the array substrate depicted in FIG. 28A. FIG. 28E is a diagram illustrating the structure of an inter-layer dielectric layer in the portion of the array substrate depicted in FIG. 28A. FIG. 28F is a diagram illustrating the structure of a first signal line layer in the portion of the array substrate depicted in FIG. 28A. FIG. 28G is a diagram illustrating the structure of a passivation layer in the portion of the array substrate depicted in FIG. 28A. FIG. 28H is a diagram illustrating the structure of a first planarization layer in the portion of the array substrate depicted in FIG. 28A. FIG. 28I is a diagram illustrating the structure of a third signal line layer in the portion of the array substrate depicted in FIG. 28A. FIG. 28J is a diagram illustrating the structure of a second planarization layer in the portion of the array substrate depicted in FIG. 28A. FIG. 28K is a diagram illustrating the structure of an anode layer in the portion of the array substrate depicted in FIG. 28A. FIG. 28L is a diagram illustrating the structure of a pixel definition layer in the portion of the array substrate depicted in FIG. 28A. FIG. 29 is a cross-sectional view along a B-B′ line in FIG. 28A.

The array substrate depicted in FIG. 28A to FIG. 28M, and FIG. 29 differs from the array substrate depicted in FIG. 3A to FIG. 3M, and FIG. 4 in that the array substrate depicted in FIG. 28A to FIG. 28M, and FIG. 29 does not include a second signal line layer.

Referring to FIG. 28A to FIG. 28M, and FIG. 29, in some embodiments, the array substrate includes a base substrate BS, a semiconductor material layer SML on the base substrate BS, a gate insulating layer G1 on a side of the semiconductor material layer SML away from the base substrate BS, a first conductive layer CT1 on a side of the gate insulating layer G1 away from the semiconductor material layer SML, an insulating layer IN on a side of the first conductive layer CT1 away from the gate insulating layer G1, a second conductive layer CT2 on a side of the insulating layer IN away from the first conductive layer CT1, an inter-layer dielectric layer ILD on a side of the second conductive layer CT2 away from the insulating layer IN, a first signal line layer SL1 on a side of the inter-layer dielectric layer ILD away from the second conductive layer CT2, a passivation layer PVX on a side of the first signal line layer SL1 away from the inter-layer dielectric layer ILD, a first planarization layer PLN1 on a side of the passivation layer PVX away from the first signal line layer SL1, a third signal line layer SL3 on a side of the first planarization layer PLN1 away from the passivation layer PVX, a second planarization layer PLN2 on a side of the third signal line layer SL3 away from the first planarization layer PLN1, an anode layer ADL on a side of the second planarization layer PLN2 away from the third signal line layer SL3, and a pixel definition layer PDL on a side of the anode layer ADL away from the second planarization layer PLN2.

Referring to FIG. 2A, FIG. 2B, FIG. 28A, and FIG. 28B, a respective pixel driving circuit is annotated with labels indicating regions corresponding to the plurality of transistors in the respective pixel driving circuit, including the first transistor T1, the second transistor T2, the third transistor T3, the fourth transistor T4, the fifth transistor T5, the sixth transistor T6, and the driving transistor Td. The respective pixel driving circuit is further annotated with labels indicating components of each of the plurality of transistors in the pixel driving circuit. For example, the first transistor T1 includes an active layer ACT1, a first electrode S1, and a second electrode D1. The second transistor T2 includes an active layer ACT2, a first electrode S2, and a second electrode D2. The third transistor T3 includes an active layer ACT3, a first electrode S3, and a second electrode D3. The fourth transistor T4 includes an active layer ACT4, a first electrode S4, and a second electrode D4. The fifth transistor T5 includes an active layer ACT5, a first electrode S5, and a second electrode D5. The sixth transistor T6 includes an active layer ACT6, a first electrode S6, and a second electrode D6. The driving transistor Td includes an active layer ACTd, a first electrode Sd, and a second electrode Dd. In one example, the active layers (ACT1, ACT2, ACT3, ACT4, ACT5, ACT6, and ACTd) of the transistors (T1, T2, T3, T4, T5, T6, and Td) in the respective pixel driving circuit are pans of a unitary structure. In another example, the active layers (ACT1, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) in the respective pixel driving circuit are parts of a unitary structure. In another example, the active layers (ACT1, ACT2, ACT3, ACT4, ACT5, ACT6, and ACTd) of the transistors (T1, T2, T3, T4, T5, T6, and Td) are in a same layer. In another example, the active layers (ACT1, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) are in a same layer.

Referring to FIG. 2A, FIG. 2B, FIG. 28A, and FIG. 28C, the first conductive layer in some embodiments includes a plurality of reset control signal lines rst, a plurality of light emitting control signal lines em, a plurality of gate signal lines GL, and a first capacitor electrode Ce1 of the storage capacitor Cst. Various appropriate electrode materials and various appropriate fabricating methods may be used to make the first conductive layer. For example, a conductive material may be deposited on the substrate by a plasma-enhanced chemical vapor deposition (PECVD) process and patterned. Examples of appropriate conductive materials for making the first conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of reset control signal lines rst, the plurality of light emitting control signal lines em, the plurality of gate signal lines GL, and the first capacitor electrode Ce1 of the storage capacitor Cst are in a same layer.

Referring to FIG. 2A, FIG. 2B, FIG. 28A, and FIG. 28D, the second conductive layer in some embodiments includes a plurality of initialization signal lines Vint and a second capacitor electrode Ce2 of the storage capacitor Cst. Various appropriate conductive materials and various appropriate fabricating methods may be used to make the second conductive layer. For example, a conductive material may be deposited on the substrate by a plasma-enhanced chemical vapor deposition (PECVD) process and patterned. Examples of appropriate conductive materials for making the second conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of initialization signal lines Vint and the second capacitor electrode Ce2 of the storage capacitor Cst are in a same layer.

In some embodiments, second capacitor electrodes of a row of pixel driving circuits are interconnected, forming a line transmitting a voltage supply signal.

Vias extending through the inter-layer dielectric layer ILD are depicted in FIG. 28E.

Referring to FIG. 2A, FIG. 28, FIG. 28A, and FIG. 28F, the first signal line layer in some embodiments includes a node connecting line C1n, a voltage connecting pad VCP, a data signal connecting pad DCP, an electrode connecting line Cie, and a reset signal connecting line Cli. Various appropriate conductive materials and various appropriate fabricating methods may be used to make the first signal line layer. For example, a conductive material may be deposited on the substrate by a plasma-enhanced chemical vapor deposition (PECVD) process and patterned. Examples of appropriate conductive materials for making the first signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first signal line layer includes a plurality of sub-layers stacked together. In one example, the first signal line layer includes a stacked titanium/aluminum/titanium multi-layer structure. In another example, the first signal line layer includes a stacked molybdenum/aluminum/molybdenum multi-layer structure. Optionally, the node connecting line C1n, the voltage connecting pad VCP, the data signal connecting pad DCP, the electrode connecting line Cle, and the reset signal connecting line Cli are in a same layer.

The node connecting line C1n is connected to the first capacitor electrode Ce1, and is connected to the second electrode of the third transistor T3 and/or the second electrode of the first transistor T1 in a respective pixel driving circuit. The data signal connecting pad DCP connects a respective data line of the plurality of data lines with a first electrode of the second transistor T2. The reset signal connecting line Cli connects a respective initialization signal line of the plurality of initialization signal lines with first electrodes of the first transistor T1 and the sixth transistor T6. The voltage connecting pad VCP connects a respective voltage supply line of the plurality of voltage supply lines with a first electrode of the fourth transistor T4, and connects the respective voltage supply line of the plurality of voltage supply lines with the second capacitor electrode of the storage capacitor. The electrode connecting line Cie is connected to second electrodes of the fifth transistor T5 and the sixth transistor T6, respectively.

Vias extending through the passivation layer PVX are depicted in FIG. 28G.

Vias extending through the first planarization layer PLN1 are depicted in FIG. 28H.

Referring to FIG. 2A, FIG. 213, FIG. 28A, and FIG. 28I, the third signal line layer in some embodiments includes a plurality of data lines DL and an anode connecting pad ACP. The anode connecting pad ACP is connected to the fourth node N4 and a respective anode in a respective subpixel, respectively. The anode connecting pad ACP is connected to second electrodes of the fifth transistor T5 and the sixth transistor T6, and the respective anode in the respective subpixel is connected to the anode connecting pad ACP.

Various appropriate conductive materials and various appropriate fabricating methods may be used to make the third signal line layer. For example, a conductive material may be deposited on the substrate by a plasma-enhanced chemical vapor deposition (PECVD) process and patterned. Examples of appropriate conductive materials for making the third signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the second signal line layer includes a plurality of sub-layers stacked together. In one example, the second signal line layer includes a stacked titanium/aluminum/titanium multi-layer structure. In another example, the second signal line layer includes a stacked molybdenum/aluminum/molybdenum multi-layer structure. Optionally, the plurality of data lines DL, the voltage connecting bridge VCB and the anode connecting pad ACP are in a same layer.

Vias extending through the second planarization layer PLN2 are depicted in FIG. 28J.

Referring to FIG. 2A, FIG. 2B, FIG. 28A, and FIG. 28K, the anode layer in some embodiments includes an anode of the respective light emitting elements. The anode connects to the anode connecting pad in the third signal line layer, the anode connecting pad connects to second electrodes of the fifth transistor T5 and the sixth transistor T6.

Vias extending through the pixel definition layer PDL are depicted in FIG. 28L. Referring to FIG. 28L, the array substrate includes a subpixel aperture SA configured to receive a light emitting material.

Referring to FIG. 2A, FIG. 2B, FIG. 28A to FIG. 28L, and FIG. 29, in some embodiments, the first capacitor electrode Ce1 is on a side of the gate insulating layer G1 away from the base substrate BS. In some embodiments, the array substrate further includes a first via v1 and a second via v2. The first via v1 extends through the inter-layer dielectric layer ILD and the insulating layer IN. The second via v2 extends through the inter-layer dielectric layer ILD, the insulating layer IN, and the gate insulating layer G. Optionally, the node connecting line Cin is connected to the first capacitor electrode Ce1 through the first via v1, and the node connecting line Cin is connected to the semiconductor material layer SML through the second via v2. Optionally, the node connecting line Cin is connected to the second electrode D3 of third transistor and/or the second electrode D1 of the first transistor, as depicted in FIG. 29.

In some embodiments, the array substrate further includes a sixth via v6. The voltage connecting pad VCP is connected to a first electrode S4 of the fourth transistor T4 through the sixth via v6, thereby providing a voltage supply signal to the first electrode S4 of the fourth transistor T4. In one example, the sixth via v6 extends through the inter-layer dielectric layer ILD, the insulating layer IN, and the gate insulating layer G1.

In some embodiments, the array substrate further includes a seventh via v7. The voltage connecting bridge VCB is connected to the voltage connecting pad VCP through the seventh via v7. In one example, the seventh via v7 extends through the first planarization layer PLN1 and the passivation layer PVX.

FIG. 30A is a diagram illustrating the structure of a portion of an array substrate in some embodiments according to the present disclosure. FIG. 30B is a diagram illustrating the structure of a semiconductor material layer in the portion of the array substrate depicted in FIG. 30A. FIG. 30C is a diagram illustrating the structure of a first conductive layer in the portion of the array substrate depicted in FIG. 30A. FIG. 30D is a diagram illustrating the structure of a second conductive layer in the portion of the array substrate depicted in FIG. 30A. FIG. 30E is a diagram illustrating the structure of an inter-layer dielectric layer in the portion of the array substrate depicted in FIG. 30A. FIG. 30F is a diagram illustrating the structure of a first signal line layer in the portion of the array substrate depicted in FIG. 30A. FIG. 30G is a diagram illustrating the structure of a passivation layer in the portion of the array substrate depicted in FIG. 30A. FIG. 30H is a diagram illustrating the structure of a first planarization layer in the portion of the array substrate depicted in FIG. 30A. FIG. 30I is a diagram illustrating the structure of a third signal line layer in the portion of the array substrate depicted in FIG. 30A. FIG. 30J is a diagram illustrating the structure of a second planarization layer in the portion of the array substrate depicted in FIG. 30A. FIG. 30K is a diagram illustrating the structure of an anode layer in the portion of the array substrate depicted in FIG. 30A. FIG. 30L is a diagram illustrating the structure of a pixel definition layer in the portion of the array substrate depicted in FIG. 30A.

In some embodiments, referring to FIG. 30A, a minimum repeating unit of the plurality of subpixels of the array substrate includes a respective first subpixel sp1, a respective second subpixel sp2, and a respective third subpixel sp3. The portion of the array substrate depicted in FIG. 28A corresponds to a portion of the respective third subpixel sp3 depicted in FIG. 30A.

In some embodiments, each of the respective first subpixel sp1, the respective second subpixel sp2, and the respective third subpixel sp3, includes the first transistor T1, the second transistor T2, the third transistor T3, the fourth transistor T4, the fifth transistor T5, the sixth transistor T6, the driving transistor Td, and the storage capacitor Cst.

In some embodiments, the respective first subpixel sp1 is a subpixel of a first color (e.g., a red color), the respective second subpixel sp2 is a subpixel of a second color (e.g., a green color), and the respective third subpixel sp3 is a subpixel of a third color (e.g., a blue color). In some embodiments, the respective first subpixel sp1, the respective second subpixel sp2, and the respective third subpixel sp3 are three subpixels of a pixel in the array substrate.

FIG. 31 is a diagram illustrating a voltage supply network in a portion of an array substrate in some embodiments according to the present disclosure. Referring to FIG. 30A, FIG. 30H, FIG. 30J, and FIG. 31, the array substrate in some embodiments a plurality of voltage connecting bridges VCBS. Optionally, the plurality of voltage connecting bridges VCBS are arranged in an array of rows and columns.

In some embodiments, a respective voltage connecting bridge of the plurality of voltage connecting bridges VCBS includes second capacitor electrodes of multiple pixel driving circuits. Optionally, the respective voltage connecting bridge of the plurality of voltage connecting bridges VCBS includes second capacitor electrodes of pixel driving circuits of the respective first subpixel sp1, the respective second subpixel sp2, and the respective third subpixel sp3. Optionally, the respective voltage connecting bridge of the plurality of voltage connecting bridges VCBS is configured to provide voltage supply signals to first electrodes of fourth transistors of pixel driving circuits of the respective first subpixel sp1, the respective second subpixel sp2, and the respective third subpixel sp3.

In some embodiments, a respective voltage supply line of the plurality of voltage supply lines Vdd is connected to two adjacent columns of voltage connecting bridges of the plurality of voltage connecting bridges VCBS. In some embodiments, a respective voltage connecting bridge of the plurality of voltage connecting bridges VCBS is connected to two adjacent voltage supply lines of the plurality of voltage supply lines Vdd, respectively. In some embodiments, the plurality of voltage supply lines Vdd includes a first adjacent voltage supply line AVdd1 and a second adjacent voltage supply line AVdd2. The respective voltage connecting bridge of the plurality of voltage connecting bridges VCBS is connected to the first adjacent voltage supply line AVdd1, and is connected to the second adjacent voltage supply line AVdd2.

In some embodiments, the plurality of voltage supply lines (including the first adjacent voltage supply line AVdd1 and the second adjacent voltage supply line AVdd2) are in the second conductive layer, and the plurality of voltage connecting bridges VCBS are in the second conductive layer CT2.

In some embodiments, two adjacent voltage connecting bridges of the plurality of voltage connecting bridges VCBS in a same pixel row are connected to a same voltage supply line of the plurality of voltage supply lines, as shown in FIG. 31. Referring to FIG. 9, a pixel row in some embodiments includes an m-th row of subpixels Rm, a (m+1)-th row of subpixels R(m+1), and a (m+2)-th row of subpixels R(m+2).

In some embodiments, voltage connecting bridges of the plurality of voltage connecting bridges VCBS in a same pixel column are connected to the same two adjacent voltage supply lines of the plurality of voltage supply lines. Referring to FIG. 9, a pixel column in some embodiments includes a (n−1)-th column of subpixels C(n−1), an n-th column of subpixels Cn, and a (n+1)-th column of subpixels C(n+1).

FIG. 32 is a diagram illustrating the structure of a portion of an array substrate in some embodiments according to the present disclosure. Referring to FIG. 32, the array substrate in some embodiments includes a plurality of light transmissive regions TR allowing light transmit therethrough. In the plurality of light transmissive regions TR, signal lines and electrodes of the first conductive layer, the second conductive layer, the first signal line layer, the third signal line layer, and the anode layer are absent.

In some embodiments, the array substrate is a full display with camera (FDC) array substrate, wherein the array substrate further includes photosensors in the plurality of light transmissive regions TR configured to detect light.

FIG. 33 is a diagram illustrating a reset signal network in a portion of an array substrate in some embodiments according to the present disclosure. Referring to FIG. 30A, FIG. 30D, FIG. 30H, and FIG. 33, a respective initialization signal line of the plurality of initialization signal lines includes a plurality of first initialization signal line portions Vint-1 and a plurality of second initialization signal line portions Vint-2. The plurality of first initialization signal line portions Vint-1 and the plurality of second initialization signal line portions Vint-2 are in two different layers. In one example, the plurality of first initialization signal line portions Vint-1 are in the second conductive layer, and the plurality of second initialization signal line portions Vint-2 are in the first signal line layer. A respective second initialization signal line portion of the plurality of second initialization signal line portions Vint-2 is connected to two adjacent first initialization signal line portions of the plurality of first initialization signal line portions Vint-1, respectively. Two adjacent first initialization signal line portions of the plurality of first initialization signal line portions Vint-1 are connected by an individual second initialization signal line portion of the plurality of second initialization signal line portions Vint-2.

In some embodiments, a respective initialization signal line of the plurality of initialization signal lines includes a plurality of first initialization signal line portions Vint-1 and a plurality of third initialization signal line portions Vint-3. The plurality of first initialization signal line portions Vint-1 and the plurality of third initialization signal line portions Vint-3 are in two different layers. In one example, the plurality of first initialization signal line portions Vint-1 are in the second conductive layer, and the plurality of third initialization signal line portions Vint-3 are in the first signal line layer. A respective third initialization signal line portion of the plurality of third initialization signal line portions Vint-3 is connected to two adjacent first initialization signal line portions of the plurality of first initialization signal line portions Vint-1 in the same row, respectively. Two adjacent first initialization signal line portions of the plurality of first initialization signal line portions Vint-1 are connected by an individual third initialization signal line portion of the plurality of third initialization signal line portions Vint-3.

In some embodiments, a respective initialization signal line of the plurality of initialization signal lines includes a plurality of first initialization signal line portions Vint-1, a plurality of second initialization signal line portions Vint-2, and a plurality of third initialization signal line portions Vint-3. The plurality of first initialization signal line portions Vint-1 and the plurality of second initialization signal line portions Vint-2 are in two different layers; and the plurality of first initialization signal line portions Vint-1 and the plurality of third initialization signal line portions Vint-3 are in two different layers. Optionally, the plurality of second initialization signal line portions Vint-2 and the plurality of third initialization signal line portions Vint-3 are in a same layer. In one example, the plurality of first initialization signal line portions Vint-1 are in the second conductive layer, the plurality of second initialization signal line portions Vint-2 are in the first signal line layer, and the plurality of third initialization signal line portions Vint-3 are in the first signal line layer. In the plurality of light transmissive regions TR, signal lines and electrodes of the first conductive layer, the second conductive layer, the first signal line layer, the third signal line layer, and the anode layer are absent.

In some embodiments, a respective second initialization signal line portion of the plurality of second initialization signal line portions Vint-2 is connected to two adjacent first initialization signal line portions of the plurality of first initialization signal line portions Vint-1, respectively. A respective third initialization signal line portion of the plurality of third initialization signal line portions Vint-3 is connected to two adjacent first initialization signal line portions of the plurality of first initialization signal line portions Vint-, respectively. Two adjacent first initialization signal line portions of the plurality of first initialization signal line portions Vint-1 are connected by an individual second initialization signal line portion of the plurality of second initialization signal line portions Vint-2, and connected by an individual third initialization signal line portion of the plurality of third initialization signal line portions Vint-3. The two adjacent first initialization signal line portions of the plurality of first initialization signal line portions Vint-1, the individual second initialization signal line portion of the plurality of second initialization signal line portions Vint-2, and the individual third initialization signal line portion of the plurality of third initialization signal line portions Vint-3 form a first loop substantially surrounding a region having transistors and capacitors of a pixel driving circuit of a subpixel. In one example, the first loop substantially surrounds a region having transistors and capacitors of a respective first subpixel. In another example, the first loop substantially surrounds a region having transistors and capacitors of a subpixel of a first color. In another example, the first loop substantially surrounds a region having transistors and capacitors of a red subpixel.

In some embodiments, the array substrate includes a plurality of first loops LPS1 sequentially arranged in a row. Optionally, the plurality of first loops LPS1 substantially surround regions of pixel driving circuits of subpixels of a same color, respectively. A respective first loop of the plurality of first loops LPS1 substantially surrounds a region of a pixel driving circuit of a subpixel of the same color. In one example, the plurality of first loops LPS1 substantially surround regions of pixel driving circuits of red subpixels.

In some embodiments, the plurality of first loops LPS1 substantially surround regions having anodes of subpixels of a same color, respectively. A respective first loop of the plurality of first loops LPS1 substantially surrounds a region having an anode of a subpixel of the same color. In one example, the plurality of first loops LPS) substantially surround regions having anodes of red subpixels.

FIG. 34 is a diagram illustrating a reset signal network in a portion of an array substrate in some embodiments according to the present disclosure. In some embodiments, referring to FIG. 34, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 34.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 28, FIG. 3A to FIG. 3M, FIG. 30A to FIG. 30L, and FIG. 34, a first initialization signal line portion of the plurality of first initialization signal line portions Vint-1 in some embodiments is connected to first electrodes of one or more reset transistors in a pixel driving circuit in a third subpixel in the n-th column of subpixels Cn and the (m+1)-th row of subpixels R(m+1), is connected to first electrodes of one or more reset transistors in a pixel driving circuit in a first subpixel in the (n−1)-th column of subpixels C(n−1) and the m-th row of subpixels Rm, and is connected to first electrodes of one or more reset transistors in a pixel driving circuit in a second subpixel in the (n+1)-th column of subpixels C(n+1) and the (m+2)-th row of subpixels R(m+2).

In some embodiments, a second initialization signal line portion of the plurality of second initialization signal line portions Vint-2 connects the first initialization signal line portion with a first adjacent first initialization signal line portion, the first adjacent first initialization signal line portion is connected to first electrodes of one or more reset transistors in a pixel driving circuit in a second subpixel in the (n−1)-th column of subpixels C(n−1) and the (m+2)-th row of subpixels R(m+2).

In some embodiments, a third initialization signal line portion of the plurality of third initialization signal line portions Vint-3 connects the first initialization signal line portion with a second adjacent first initialization signal line portion, the second adjacent first initialization signal line portion is connected to first electrodes of one or more reset transistors in a pixel driving circuit in a first subpixel in the (n+1l)-th column of subpixels C(n+1) and the n-th row of subpixels Rm.

FIG. 35 is a diagram illustrating a gate scanning signal network in a portion of an array substrate in some embodiments according to the present disclosure. Referring to FIG. 30A, FIG. 30C, FIG. 30H, and FIG. 35, a respective gate signal line of the plurality of gate signal lines includes a plurality of first gate signal line portions GL-1 and a plurality of second gate signal line portions GL-2. The plurality of first gate signal line portions GL-1 and the plurality of second gate signal line portions GL-2 are in two different layers. In one example, the plurality of first gate signal line portions GL-1 are in the first conductive layer, and the plurality of second gate signal line portions GL-2 are in the first signal line layer. A respective second gate signal line portion of the plurality of second gate signal line portions GL-2 is connected to two adjacent first gate signal line portions of the plurality of first gate signal line portions GL-1, respectively. Two adjacent first gate signal line portions of the plurality of first gate signal line portions GL-1 are connected by an individual second gate signal line portion of the plurality of second gate signal line portions GL-2.

In some embodiments, a respective gate signal line of the plurality of gate signal lines includes a plurality of first gate signal line portions GL-1 and a plurality of third gate signal line portions GL-3. The plurality of first gate signal line portions GL-1 and the plurality of third gate signal line portions GL-3 are in two different layers. In one example, the plurality of first gate signal line portions GL-1 are in the first conductive layer, and the plurality of third gate signal line portions GL-3 are in the first signal line layer. A respective third gate signal line portion of the plurality of third gate signal line portions GL-3 is connected to two adjacent first gate signal line portions of the plurality of first gate signal line portions GL-1 in the same row, respectively. Two adjacent first gate signal line portions of the plurality of first gate signal line portions GL-1 are connected by an individual third gate signal line portion of the plurality of third gate signal line portions GL-3.

In some embodiments, a respective gate signal line of the plurality of gate signal lines includes a plurality of first gate signal line portions GL-1, a plurality of second gate signal line portions GL-2, and a plurality of third gate signal line portions GL-3. The plurality of first gate signal line portions GL-1 and the plurality of second gate signal line portions GL-2 are in two different layers; and the plurality of first gate signal line portions GL-1 and the plurality of third gate signal line portions GL-3 are in two different layers. Optionally, the plurality of second gate signal line portions GL-2 and the plurality of third gate signal line portions GL-3 are in a same layer. In one example, the plurality of first gate signal line portions GL-1 are in the first conductive layer, the plurality of second gate signal line portions GL-2 are in the first signal line layer, and the plurality of third gate signal line portions GL-3 are in the first signal line layer. In the plurality of light transmissive regions TR, signal lines and electrodes of the first conductive layer, the second conductive layer, the first signal line layer, the third signal line layer, and the anode layer are absent.

In some embodiments, a respective second gate signal line portion of the plurality of second gate signal line portions GL-2 is connected to two adjacent first gate signal line portions of the plurality of first gate signal line portions GL-1, respectively. A respective third gate signal line portion of the plurality of third gate signal line portions GL-3 is connected to two adjacent first gate signal line portions of the plurality of first gate signal line portions GL-1, respectively. Two adjacent first gate signal line portions of the plurality of first gate signal line portions GL-1 are connected by an individual second gate signal line portion of the plurality of second gate signal line portions GL-2, and connected by an individual third gate signal line portion of the plurality of third gate signal line portions GL-3. The two adjacent first gate signal line portions of the plurality of first gate signal line portions GL-1, the individual second gate signal line portion of the plurality of second gate signal line portions GL-2, and the individual third gate signal line portion of the plurality of third gate signal line portions GL-3 form a second loop substantially surrounding a region having transistors and capacitors of a pixel driving circuit of a subpixel. In one example, the second loop substantially surrounds a region having transistors and capacitors of a respective first subpixel. In another example, the second loop substantially surrounds a region having transistors and capacitors of a subpixel of a first color. In another example, the second loop substantially surrounds a region having transistors and capacitors of a red subpixel.

In some embodiments, the array substrate includes a plurality of second loops LPS2 sequentially arranged in a row. Optionally, the plurality of second loops LPS2 substantially surround regions of pixel driving circuits of subpixels of a same color, respectively. A respective second loop of the plurality of second loops LPS2 substantially surrounds a region of a pixel driving circuit of a subpixel of the same color. In one example, the plurality of second loops LPS2 substantially surround regions of pixel driving circuits of red subpixels.

In some embodiments, the plurality of second loops LPS2 substantially surround regions having anodes of subpixels of a same color, respectively. A respective second loop of the plurality of second loops LPS2 substantially surrounds a region having an anode of a subpixel of the same color. In one example, the plurality of second loops LPS2 substantially surround regions having anodes of red subpixels.

FIG. 36 is a diagram illustrating a gate scanning signal network in a portion of an array substrate in some embodiments according to the present disclosure. In some embodiments, referring to FIG. 36, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 36.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 3A to FIG. 3M, FIG. 30A to FIG. 30L, and FIG. 36, a first gate signal line portion of the plurality of first gate signal line portions GL-1 in some embodiments is connected to gate electrodes of one or more data write transistors in a pixel driving circuit in a third subpixel in the n-th column of subpixels Cn and the (m+1)-th row of subpixels R(m+1), is connected to gate electrodes of one or more data write transistors in a pixel driving circuit in a first subpixel in the (n−1)-th column of subpixels C(n−1) and the m-th row of subpixels Rm, and is connected to gate electrodes of one or more data write transistors in a pixel driving circuit in a second subpixel in the (n+1)-th column of subpixels C(n+1) and the (m+2)-th row of subpixels R(m+2).

In some embodiments, a second gate signal line portion of the plurality of second gate signal line portions GL-2 connects the first gate signal line portion with a first adjacent first gate signal line portion, the first adjacent first gate signal line portion is connected to gate electrodes of one or more data write transistors in a pixel driving circuit in a second subpixel in the (n−1)-th column of subpixels C(n−1) and the (m+2)-th row of subpixels R(m+2).

In some embodiments, a third gate signal line portion of the plurality of third gate signal line portions G-3 connects the first gate signal line portion with a second adjacent first gate signal line portion, the second adjacent first gate signal line portion is connected to gate electrodes of one or more data write transistors in a pixel driving circuit in a first subpixel in the (n+1)-th column of subpixels C(+1) and the m-th row of subpixels Rm.

FIG. 37 is a diagram illustrating a reset control signal network in a portion of an array substrate in some embodiments according to the present disclosure. Referring to FIG. 30A, FIG. 30C, FIG. 30H, and FIG. 37, a respective reset control signal line of the plurality of reset control signal lines includes a plurality of first reset control signal line portions rst-1 and a plurality of second reset control signal line portions rst-2. The plurality of first reset control signal line portions rst-1 and the plurality of second reset control signal line portions rst-2 are in two different layers. In one example, the plurality of first reset control signal line portions rst-1 are in the first conductive layer, and the plurality of second reset control signal line portions rst-2 are in the first signal line layer. A respective second reset control signal line portion of the plurality of second reset control signal line portions rst-2 is connected to two adjacent first reset control signal line portions of the plurality of first reset control signal line portions rst-1, respectively. Two adjacent first reset control signal line portions of the plurality of first reset control signal line portions rst-1 are connected by an individual second reset control signal line portion of the plurality of second reset control signal line portions rst-2.

In some embodiments, a respective reset control signal line of the plurality of reset control signal lines includes a plurality of first reset control signal line portions rst-1 and a plurality of third reset control signal line portions rst-3. The plurality of first reset control signal line portions rst-1 and the plurality of third reset control signal line portions rst-3 are in two different layers. In one example, the plurality of first reset control signal line portions rst-1 are in the rust conductive layer, and the plurality of third reset control signal line portions rst-3 are in the fast signal line layer. A respective third reset control signal line portion of the plurality of third reset control signal line portions rst-3 is connected to two adjacent first reset control signal line portions of the plurality of first reset control signal line portions rst-1 in the same row, respectively. Two adjacent first reset control signal line portions of the plurality of first reset control signal line portions rst-1 are connected by an individual third reset control signal line portion of the plurality of third reset control signal line portions rst-3.

In some embodiments, a respective reset control signal line of the plurality of reset control signal lines includes a plurality of first reset control signal line portions rst-1, a plurality of second reset control signal line portions rst-2, and a plurality of third reset control signal line portions rst-3. The plurality of first reset control signal line portions rst-1 and the plurality of second reset control signal line portions rst-2 are in two different layers; and the plurality of first reset control signal line portions rat-1 and the plurality of third reset control signal line portions rst-3 are in two different layers. Optionally, the plurality of second reset control signal line portions rst-2 and the plurality of third reset control signal line portions rst-3 are in a same layer. In one example, the plurality of first reset control signal line portions rst-1 are in the first conductive layer, the plurality of second reset control signal line portions rst-2 are in the first signal line layer, and the plurality of third reset control signal line portions rst-3 are in the first signal line layer. In the plurality of light transmissive regions TR, signal lines and electrodes of the first conductive layer, the second conductive layer, the first signal line layer, the third signal line layer, and the anode layer are absent.

In some embodiments, a respective second reset control signal line portion of the plurality of second reset control signal line portions rst-2 is connected to two adjacent first reset control signal line portions of the plurality of first reset control signal line portions rst-1, respectively. A respective third reset control signal line portion of the plurality of third reset control signal line portions rst-3 is connected to two adjacent first reset control signal line portions of the plurality of first reset control signal line portions rst-1, respectively. Two adjacent first reset control signal line portions of the plurality of first reset control signal line portions rst-1 are connected by an individual second reset control signal line portion of the plurality of second reset control signal line portions rst-2, and connected by an individual third reset control signal line portion of the plurality of third reset control signal line portions rst-3. The two adjacent first reset control signal line portions of the plurality of first reset control signal line portions rst-1, the individual second reset control signal line portion of the plurality of second reset control signal line portions rst-2, and the individual third reset control signal line portion of the plurality of third reset control signal line portions rst-3 form a third loop substantially surrounding a region having transistors and capacitors of a pixel driving circuit of a subpixel. In one example, the third loop substantially surrounds a region having transistors and capacitors of a respective first subpixel. In another example, the third loop substantially surrounds a region having transistors and capacitors of a subpixel of a first color. In another example, the third loop substantially surrounds a region having transistors and capacitors of a red subpixel.

In some embodiments, the array substrate includes a plurality of third loops LPS3 sequentially arranged in a row. Optionally, the plurality of third loops LPS3 substantially surround regions of pixel driving circuits of subpixels of a same color, respectively. A respective third loop of the plurality of third loops LPS3 substantially surrounds a region of a pixel driving circuit of a subpixel of the same color. In one example, the plurality of third loops LPS3 substantially surround regions of pixel driving circuits of red subpixels.

In some embodiments, the plurality of third loops LPS3 substantially surround regions having anodes of subpixels of a same color, respectively. A respective third loop of the plurality of third loops LPS3 substantially surrounds a region having an anode of a subpixel of the same color. In one example, the plurality of third loops LPS3 substantially surround regions having anodes of red subpixels.

FIG. 38 is a diagram illustrating a reset control signal network in a portion of an array substrate in some embodiments according to the present disclosure. In some embodiments, referring to FIG. 38, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 38.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 3A to FIG. 3M, FIG. 30A to FIG. 30L, and FIG. 38, a first reset control signal line portion of the plurality of first reset control signal line portions rst-1 in some embodiments is connected to gate electrodes of one or more reset control transistors in a pixel driving circuit in a third subpixel in the n-th column of subpixels Cn and the (m+1)-th row of subpixels R(m+1), is connected to gate electrodes of one or more reset control transistors in a pixel driving circuit in a first subpixel in the (n−1)-th column of subpixels C(n−1) and the m-th row of subpixels Rm, and is connected to gate electrodes of one or more reset control transistors in a pixel driving circuit in a second subpixel in the (n+1)-th column of subpixels C(n+1) and the (m+2)-th row of subpixels R(m+2).

In some embodiments, a second reset control signal line portion of the plurality of second reset control signal line portions rst-2 connects the first reset control signal line portion with a first adjacent first reset control signal line portion, the first adjacent first reset control signal line portion is connected to gate electrodes of one or more reset control transistors in a pixel driving circuit in a second subpixel in the (n−1)-th column of subpixels C(n−1) and the (m+2)-th row of subpixels R(m+2).

In some embodiments, a third reset control signal line portion of the plurality of third reset control signal line portions rst-3 connects the first reset control signal line portion with a second adjacent first reset control signal line portion, the second adjacent first reset control signal line portion is connected to gate electrodes of one or more reset control transistors in a pixel driving circuit in a first subpixel in the (n+1)-th column of subpixels C(n+1) and the m-th row of subpixels Rm.

FIG. 39 is a diagram illustrating a light emitting control signal network in a portion of an array substrate in some embodiments according to the present disclosure. Referring to FIG. 30A, FIG. 30C, FIG. 30H, and FIG. 39, a respective light emitting control signal line of the plurality of light emitting control signal lines includes a plurality of first light emitting control signal line portions em-1 and a plurality of second light emitting control signal line portions em-2. The plurality of first light emitting control signal line portions em-1 and the plurality of second light emitting control signal line portions em-2 are in two different layers. In one example, the plurality of first light emitting control signal line portions em-1 are in the first conductive layer, and the plurality of second light emitting control signal line portions em-2 are in the first signal line layer. A respective second light emitting control signal line portion of the plurality of second light emitting control signal line portions em-2 is connected to two adjacent first light emitting control signal line portions of the plurality of first light emitting control signal line portions em-1, respectively. Two adjacent first light emitting control signal line portions of the plurality of first light emitting control signal line portions em-1 are connected by an individual second light emitting control signal line portion of the plurality of second light emitting control signal line portions em-2.

In some embodiments, a respective light emitting control signal line of the plurality of light emitting control signal lines includes a plurality of first light emitting control signal line portions em-1 and a plurality of third light emitting control signal line portions em-3. The plurality of first light emitting control signal line portions em-1 and the plurality of third light emitting control signal line portions em-3 are in two different layers. In one example, the plurality of first light emitting control signal line portions em-1 are in the first conductive layer, and the plurality of third light emitting control signal line portions em-3 are in the first signal line layer. A respective third light emitting control signal line portion of the plurality of third light emitting control signal line portions em-3 is connected to two adjacent first light emitting control signal line portions of the plurality of first light emitting control signal line portions em-1 in the same row, respectively. Two adjacent first light emitting control signal line portions of the plurality of first light emitting control signal line portions em-1 are connected by an individual third light emitting control signal line portion of the plurality of third light emitting control signal line portions em-3.

In some embodiments, a respective light emitting control signal line of the plurality of light emitting control signal lines includes a plurality of first light emitting control signal line portions em-1, a plurality of second light emitting control signal line portions em-2, and a plurality of third light emitting control signal line portions em-3. The plurality of first light emitting control signal line portions em-1 and the plurality of second light emitting control signal line portions em-2 are in two different layers; and the plurality of first light emitting control signal line portions em-1 and the plurality of third light emitting control signal line portions em-3 are in two different layers. Optionally, the plurality of second light emitting control signal line portions em-2 and the plurality of third light emitting control signal line portions em-3 are in a same layer. In one example, the plurality of first light emitting control signal line portions em-1 are in the first conductive layer, the plurality of second light emitting control signal line portions em-2 are in the first signal line layer, and the plurality of third light emitting control signal line portions em-3 are in the first signal line layer. In the plurality of light transmissive regions TR, signal lines and electrodes of the first conductive layer, the second conductive layer, the first signal line layer, the third signal line layer, and the anode layer are absent.

In some embodiments, a respective second light emitting control signal line portion of the plurality of second light emitting control signal line portions em-2 is connected to two adjacent first light emitting control signal line portions of the plurality of first light emitting control signal line portions em-1, respectively. A respective third light emitting control signal line portion of the plurality of third light emitting control signal line portions em-3 is connected to two adjacent first light emitting control signal line portions of the plurality of first light emitting control signal line portions em-1, respectively. Two adjacent first light emitting control signal line portions of the plurality of first light emitting control signal line portions em-1 are connected by an individual second light emitting control signal line portion of the plurality of second light emitting control signal line portions em-2, and connected by an individual third light emitting control signal line portion of the plurality of third light emitting control signal line portions em-3. The two adjacent first light emitting control signal line portions of the plurality of first light emitting control signal line portions em-1, the individual second light emitting control signal line portion of the plurality of second light emitting control signal line portions em-2, and the individual third light emitting control signal line portion of the plurality of third light emitting control signal line portions em-3 form a fourth loop substantially surrounding a region having transistors and capacitors of a pixel driving circuit of a subpixel. In one example, the fourth loop substantially surrounds a region having transistors and capacitors of a respective first subpixel. In another example, the fourth loop substantially surrounds a region having transistors and capacitors of a subpixel of a first color. In another example, the fourth loop substantially surrounds a region having transistors and capacitors of a red subpixel.

In some embodiments, the array substrate includes a plurality of fourth loops LPS4 sequentially arranged in a row. Optionally, the plurality of fourth loops LPS4 substantially surround regions of pixel driving circuits of subpixels of a same color, respectively. A respective fourth loop of the plurality of fourth loops LPS4 substantially surrounds a region of a pixel driving circuit of a subpixel of the same color. In one example, the plurality of fourth loops LPS4 substantially surround regions of pixel driving circuits of red subpixels.

In some embodiments, the plurality of fourth loops LPS4 substantially surround regions having anodes of subpixels of a same color, respectively. A respective fourth loop of the plurality of fourth loops LPS4 substantially surrounds a region having an anode of a subpixel of the same color. In one example, the plurality of fourth loops LPS4 substantially surround regions having anodes of red subpixels.

FIG. 40 is a diagram illustrating a light emitting control signal network in a portion of an array substrate in some embodiments according to the present disclosure. In some embodiments, referring to FIG. 40, subpixels in the array substrate are arranged in rows and columns. In an m-th row of subpixels Rm, the army substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. A respective first subpixel sp1, a respective second subpixel sp2, and a respective third subpixel sp3 are denoted in FIG. 40.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cu, a respective light transmissive region of the plurality of light transmissive regions TR spaces apart two adjacent third subpixels.

Referring to FIG. 2A, FIG. 2B, FIG. 3A to FIG. 3M, FIG. 30A to FIG. 30L, and FIG. 40, a first light emitting control signal line portion of the plurality of first light emitting control signal line portions em-1 in some embodiments is connected to gate electrodes of one or more light emitting control transistors in a pixel driving circuit in a third subpixel in the n-th column of subpixels Cn and the (m+1)-th row of subpixels R(m+1), is connected to gate electrodes of one or more light emitting control transistors in a pixel driving circuit in a first subpixel in the (n−1)-th column of subpixels C(n−1) and the m-th row of subpixels Rm. and is connected to gate electrodes of one or more light emitting control transistors in a pixel driving circuit in a second subpixel in the (n+1)-th column of subpixels C(n+)) and the (m+2)-th row of subpixels R(m+2).

In some embodiments, a second light emitting control signal line portion of the plurality of second light emitting control signal line portions em-2 connects the first light emitting control signal line portion with a first adjacent first light emitting control signal line portion, the first adjacent first light emitting control signal line portion is connected to gate electrodes of one or more light emitting control transistors in a pixel driving circuit in a second subpixel in the (n−1)-th column of subpixels C(n−1) and the (m+2)-th row of subpixels R(m+2).

In some embodiments, a third light emitting control signal line portion of the plurality of third light emitting control signal line portions em-3 connects the first light emitting control signal line portion with a second adjacent first light emitting control signal line portion, the second adjacent first light emitting control signal line portion is connected to gate electrodes of one or more light emitting control transistors in a pixel driving circuit in a first subpixel in the (n+1)-th column of subpixels C(n+1) and the m-th row of subpixels Rm.

Referring to FIG. 30A, FIG. 30C, FIG. 30H, and FIG. 33 to FIG. 40, the array substrate in some embodiments includes a plurality of signal lines, a respective signal line of the plurality of signal lines includes a plurality of first signal line portions and a plurality of second signal line portions. The plurality of first signal line portions and the plurality of second signal line portions are in two different layers. In one example, the plurality of first signal line portions are in the first conductive layer, and the plurality of second signal line portions are in the first signal line layer. In another example, the plurality of first signal line portions are in the second conductive layer, and the plurality of second signal line portions are in the first signal line layer. A respective second signal line portion of the plurality of second signal line portions is connected to two adjacent first signal line portions of the plurality of first signal line portions, respectively. Two adjacent first signal line portions of the plurality of first signal line portions are connected by an individual second signal line portion of the plurality of second signal line portions.

In some embodiments, a respective signal line of the plurality of signal lines includes a plurality of first signal line portions and a plurality of third signal line portions. The plurality of first signal line portions and the plurality of third signal line portions are in two different layers. In one example, the plurality of first signal line portions are in the first conductive layer, and the plurality of third signal line portions are in the fast signal line layer. In another example, the plurality of first signal line portions are in the second conductive layer, and the plurality of third signal line portions are in the first signal line layer. A respective third signal line portion of the plurality of third signal line portions is connected to two adjacent first signal line portions of the plurality of first signal line portions in the same row, respectively. Two adjacent first signal line portions of the plurality of first signal line portions are connected by an individual third signal line portion of the plurality of third signal line portions.

In some embodiments, a respective signal line of the plurality of signal lines includes a plurality of first signal line portions, a plurality of second signal line portions, and a plurality of third signal line portions. The plurality of first signal line portions and the plurality of second signal line portions are in two different layers; and the plurality of first signal line portions and the plurality of third signal line portions are in two different layers. Optionally, the plurality of second signal line portions and the plurality of third signal line portions are in a same layer. In one example, the plurality of first signal line portions are in the first conductive layer, the plurality of second signal line portions are in the first signal line layer, and the plurality of third signal line portions are in the first signal line layer. In one example, the plurality of first signal line portions am in the second conductive layer, the plurality of second signal line portions are in the first signal line layer, and the plurality of third signal line portions are in the first signal line layer. In the plurality of light transmissive regions TR, signal lines and electrodes of the first conductive layer, the second conductive layer, the first signal line layer, the third signal line layer, and the anode layer are absent.

In some embodiments, a respective second signal line portion of the plurality of second signal line portions is connected to two adjacent first signal line portions of the plurality of first signal line portions, respectively. A respective third signal line portion of the plurality of third signal line portions is connected to two adjacent first signal line portions of the plurality of first signal line portions, respectively. Two adjacent first signal line portions of the plurality of first signal line portions are connected by an individual second signal line portion of the plurality of second signal line portions, and connected by an individual third signal line portion of the plurality of third signal line portions. The two adjacent first signal line portions of the plurality of first signal line portions, the individual second signal line portion of the plurality of second signal line portions, and the individual third signal line portion of the plurality of third signal line portions form a loop substantially surrounding a region having transistors and capacitors of a pixel driving circuit of a subpixel. In one example, the loop substantially surrounds a region having transistors and capacitors of a respective first subpixel. In another example, the loop substantially surrounds a region having transistors and capacitors of a subpixel of a first color. In another example, the loop substantially surrounds a region having transistors and capacitors of a red subpixel.

In some embodiments, the array substrate includes a plurality of loops sequentially arranged in a row. Optionally, the plurality of loops substantially surround regions of pixel driving circuits of subpixels of a same color, respectively. A respective loop of the plurality of loops substantially surrounds a region of a pixel driving circuit of a subpixel of the same color. In one example, the plurality of loops substantially surround regions of pixel driving circuits of red subpixels.

In some embodiments, the plurality of loops substantially surround regions having anodes of subpixels of a same color, respectively. A respective loop of the plurality of loops substantially surrounds a region having an anode of a subpixel of the same color. In one example, the plurality of loops substantially surround regions having anodes of red subpixels.

In some embodiments, subpixels in the array substrate are arranged in rows and columns. In an m-th row of subpixels Rm, the array substrate includes a row of first subpixels. In a (m+1)-th row of subpixels R(m+1), the array substrate includes a row of third subpixels. In a (m+2)-th row of subpixels R(m+2), the array substrate includes a row of second subpixels. Optionally, the row of first subpixels is a row of subpixels of a first color, the row of second subpixels is a row of subpixels of a second color, and the row of third subpixels is a row of subpixels of a third color. The first color, the second color, and the third color are three different colors. In one example, the first color is a red color, the second color is green color, and the third color is a blue color.

In some embodiments, in an n-th column of subpixels Cn, the array substrate includes a column of third subpixels. In a (n−1)-th column of subpixels C(n−1), the array substrate includes a column of first subpixels and second subpixels alternately arranged. In a (n+1)-th column of subpixels C(n+1), the array substrate includes a column of first subpixels and second subpixels alternately arranged. Optionally, the column of third subpixels is a column of subpixels of a third color, the column of first subpixels and second subpixels alternately arranged is a column of subpixels of a first color and subpixels of a second color alternately arranged. Optionally, in the n-th column of subpixels Cn, a respective light transmissive region of the plurality of light transmissive regions TR spaces apart two adjacent third subpixels.

Referring to FIG. 2A, FIG. 2B, FIG. 3A to FIG. 3M. FIG. 30A to FIG. 30L, and FIG. 33 to FIG. 40, a first signal line portion of the plurality of first signal line portions in some embodiments is connected to one or more transistors in a pixel driving circuit in a third subpixel in the n-th column of subpixels Cn and the (m+1)-th row of subpixels R(m+1), is connected to one or more transistors in a pixel driving circuit in a first subpixel in the (n−1)-th column of subpixels C(n−1) and the m-th row of subpixels Rm, and is connected to one or more transistors in a pixel driving circuit in a second subpixel in the (n+1)-th column of subpixels C(n+1) and the (m+2)-th row of subpixels R(m+2).

In some embodiments, a second signal line portion of the plurality of second signal line portions connects the first signal line portion with a first adjacent first signal line portion, the first adjacent first signal line portion is connected to one or more transistors in a pixel driving circuit in a second subpixel in the (n−1)-th column of subpixels C(n−1) and the (m+2)-th row of subpixels R(m+2).

In some embodiments, a third signal line portion of the plurality of third signal line portions connects the first signal line portion with a second adjacent first signal line portion, the second adjacent first signal line portion is connected to one or more transistors in a pixel driving circuit in a first subpixel in the (n+1)-th column of subpixels C(n+1) and the m-th row of subpixels Rm.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a plurality of signal lines. Optionally, forming a respective signal line of the plurality of signal lines comprises forming a plurality of first signal line portions, forming a plurality of second signal line portions, and forming a plurality of third signal line portions. Optionally, the plurality of first signal line portions and the plurality of second signal line portions are formed in two different layers. Optionally, the plurality of first signal line portions and the plurality of third signal line portions are in two different layers. Optionally, a respective second signal line portion of the plurality of second signal line portions is connected to two adjacent first signal line portions of the plurality of first signal line portions, respectively. Optionally, a respective third signal line portion of the plurality of third signal line portions is connected to two adjacent first signal line portions of the plurality of first signal line portions, respectively. Optionally, two individual first signal line portions of the plurality of first signal line portions, an individual second signal line portion of the plurality of second signal line portions, and an individual third signal line portion of the plurality of third signal line portions form a loop substantially surrounding a region having transistors and capacitors of a pixel driving circuit of a subpixel. Optionally, the two individual first signal line portions are connected by the individual second signal line portion, and connected by the individual third signal line portion.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising a plurality of signal lines;
wherein a respective signal line of the plurality of signal lines comprises a plurality of first signal line portions, a plurality of second signal line portions, and a plurality of third signal line portions;
the plurality of first signal line portions and the plurality of second signal line portions are in two different layers;
the plurality of first signal line portions and the plurality of third signal line portions are in two different layers;
a respective second signal line portion of the plurality of second signal line portions is connected to two adjacent first signal line portions of the plurality of first signal line portions, respectively;
a respective third signal line portion of the plurality of third signal line portions is connected to two adjacent first signal line portions of the plurality of first signal line portions, respectively;
two individual first signal line portions of the plurality of first signal line portions, an individual second signal line portion of the plurality of second signal line portions, and an individual third signal line portion of the plurality of third signal line portions form a loop substantially surrounding a region having transistors and capacitors of a pixel driving circuit of a subpixel; and
the two individual first signal line portions are connected by the individual second signal line portion, and connected by the individual third signal line portion.

2. The array substrate of claim 1, comprising a plurality of loops sequentially arranged in a row;
wherein the plurality of loops substantially surround regions of pixel driving circuits of subpixels of a same color, respectively; and
a respective loop of the plurality of loops substantially surrounds a region of a pixel driving circuit of a subpixel of the same color.

3. The array substrate of claim 1, comprising a plurality of loops sequentially arranged in a row;
wherein the plurality of loops substantially surround regions having anodes of subpixels of a same color, respectively; and
a respective loop of the plurality of loops substantially surrounds a region having an anode of a subpixel of the same color.

4. The array substrate of claim 1, wherein subpixels are arranged in rows and columns;
in an m-th row of subpixels, the array substrate comprises a row of first subpixels of a first color;
in a (m+1)-th row of subpixels, the array substrate comprises a row of third subpixels of a third color;
in a (m+2)-th row of subpixels, the array substrate comprises a row of second subpixels of a second color;
in an n-th column of subpixels, the array substrate comprises a column of third subpixels of the third color,
in a (n−1)-th column of subpixels, the array substrate comprises a column of first subpixels of the first color and second subpixels of the second color alternately arranged;
in a (n+1)-th column of subpixels, the array substrate comprises a column of first subpixels of the first color and second subpixels of the second color alternately arranged;
a first signal line portion of the plurality of first signal line portions is connected to one or more transistors in a pixel driving circuit in a third subpixel in the n-th column of subpixels and the (m+1)-th row of subpixels, is connected to one or more transistors in a pixel driving circuit in a first subpixel in the (n−1)-th column of subpixels and the m-th row of subpixels, and is connected to one or more transistors in a pixel driving circuit in a second subpixel in the (n+1)-th column of subpixels and the (m+2)-th row of subpixels.

5. The array substrate of claim 4, wherein a second signal line portion of the plurality of second signal line portions connects the first signal line portion with a first adjacent first signal line portion, the first adjacent first signal line portion is connected to one or more transistors in a pixel driving circuit in a second subpixel in the (n−1)-th column of subpixels and the (m+2)-th row of subpixels.

6. The array substrate of claim 4, wherein a third signal line portion of the plurality of third signal line portions connects the first signal line portion with a second adjacent first signal line portion, the second adjacent first signal line portion is connected to one or more transistors in a pixel driving circuit in a first subpixel in the (n+1)-th column of subpixels and the m-th row of subpixels.

7. The array substrate of claim 4, further comprising a plurality of light transmissive regions;
wherein, in the n-th column of subpixels, a respective light transmissive region of the plurality of light transmissive regions spaces apart two adjacent third subpixels.

8. The array substrate of claim 1, wherein the plurality of signal lines comprise a plurality of initialization signal lines;
the plurality of first signal line portions comprise a plurality of first initialization signal line portions;
the plurality of second signal line portions comprise a plurality of second initialization signal line portions; and
the plurality of third signal line portions comprise a plurality of third initialization signal line portions.

9. The array substrate of claim 1, wherein the plurality of signal lines comprise a plurality of gate signal lines;
the plurality of first signal line portions comprise a plurality of first gate signal line portions;
the plurality of second signal line portions comprise a plurality of second gate signal line portions; and
the plurality of third signal line portions comprise a plurality of third gate signal line portions.

10. The array substrate of claim 1, wherein the plurality of signal lines comprise a plurality of reset control signal lines;
the plurality of first signal line portions comprise a plurality of first reset control signal line portions;
the plurality of second signal line portions comprise a plurality of second reset control signal line portions; and
the plurality of third signal line portions comprise a plurality of third reset control signal line portions.

11. The array substrate of claim 1, wherein the plurality of signal lines comprise a plurality of light emitting control signal lines;
the plurality of first signal line portions comprise a plurality of first light emitting control signal line portions;
the plurality of second signal line portions comprise a plurality of second light emitting control signal line portions; and
the plurality of third signal line portions comprise a plurality of third light emitting control signal line portions.

12. The array substrate of claim 1, further comprising a plurality of light transmissive regions;
wherein the array substrate comprises a first conductive layer, a second conductive layer, a first signal line layer, a third signal line layer, and an anode layer,
signal lines and electrodes of the first conductive layer, the second conductive layer, the first signal line layer, the third signal line layer, and the anode layer are absent in the plurality of light transmissive regions.

13. The array substrate of claim 12, further comprising a second signal line layer;
wherein signal lines in the second signal line layer comprise a substantially transparent conductive material; and
the signal lines of the second signal line layer are present in the plurality of light transmissive regions.

14. The array substrate of claim 13, wherein the plurality of second signal line portions and the plurality of third signal line portions are in the second signal line layer, and
the plurality of first signal line portions are in the first conductive layer or in the second conductive layer.

15. The array substrate of claim 1, further comprising a plurality of voltage supply lines and a plurality of voltage connecting bridges in two different layers;
the plurality of voltage connecting bridges are arranged in an array of rows and columns;
two adjacent voltage connecting bridges of the plurality of voltage connecting bridges in a same pixel row are connected to a same voltage supply line of the plurality of voltage supply lines; and
voltage connecting bridges of the plurality of voltage connecting bridges in a same pixel column are connected to same adjacent voltage supply lines of the plurality of voltage supply lines.

16. The array substrate of claim 15, wherein the plurality of voltage supply lines comprise a first adjacent voltage supply line, a second adjacent voltage supply line, and a third adjacent voltage supply line;
the first adjacent voltage supply line is configured to provide a voltage supply signal to a first pixel driving circuit in a respective first subpixel, the second adjacent voltage supply line is configured to provide a voltage supply signal to a second pixel driving circuit in a respective second subpixel, and the third adjacent voltage supply line is configured to provide a voltage supply signal to a third pixel driving circuit in a respective third subpixel; and
a respective voltage connecting bridge of the plurality of voltage connecting bridges is connected to the first adjacent voltage supply line, the second adjacent voltage supply line, and the third adjacent voltage supply line, respectively.

17. The array substrate of claim 16, wherein each of the first adjacent voltage supply line, the second adjacent voltage supply line, and the third adjacent voltage supply line comprises a plurality of first voltage supply line portions and a plurality of second voltage supply line portions alternately arranged;
a respective voltage connecting bridge of the plurality of voltage connecting bridges is connected to a first adjacent voltage supply line portion and a second adjacent voltage supply line portion of the first adjacent voltage supply line, respectively, is connected to a first adjacent voltage supply line portion and a second adjacent voltage supply line portion of the second adjacent voltage supply line, respectively, and is connected to a first adjacent voltage supply line portion and a second adjacent voltage supply line portion of the third adjacent voltage supply line, respectively.

18. The array substrate of claim 15, wherein the plurality of voltage supply lines comprise a first adjacent voltage supply line and a second adjacent voltage supply line;
a respective voltage supply line of the plurality of voltage supply lines is connected to two adjacent columns of voltage connecting bridges of the plurality of voltage connecting bridges; and
a respective voltage connecting bridge of the plurality of voltage connecting bridges is connected to the first adjacent voltage supply line and is connected to the second adjacent voltage supply line.

19. (canceled)

20. A display apparatus, comprising the array substrate of claim 1, and one or more integrated circuits connected to the array substrate.

21. An array substrate, comprising a plurality of voltage supply lines and a plurality of voltage connecting bridges in two different layers;
wherein the plurality of voltage connecting bridges are arranged in an array of rows and columns;
two adjacent voltage connecting bridges of the plurality of voltage connecting bridges in a same pixel row are connected to a same voltage supply line of the plurality of voltage supply lines; and
voltage connecting bridges of the plurality of voltage connecting bridges in a same pixel column are connected to same adjacent voltage supply lines of the plurality of voltage supply lines.

22-40. (canceled)
